(19) United States
(12) Patent Application Publication
(10) Pub. No.: US 2025/0040264 A1
(43) Pub. Date: Jan. 30, 2025

(54) PHOTODETECTION ELEMENT, PHOTODETECTOR, AND ELECTRONIC DEVICE

(71) Applicant: TRUPIXEL INC., Daejeon (KR)

(72) Inventor: Myung-Jae LEE, Seoul (KR)

(21) Appl. No.: 18/784,650

(22) Filed: Jul. 25, 2024

(30) Foreign Application Priority Data
Jul. 25, 2023 (KR) 10-2023-0096675
Jun. 6, 2024 (KR) 10-2024-0074097

(51) Int. Cl. H01L 31/107; H01L 31/0232

(52) U.S. Cl. CPC H01L 31/107; H01L 31/02327

(57) ABSTRACT

A photodetection element comprises a substrate having a first surface and a second surface opposite to each other, a first node region within the substrate and having a first conductivity type, a second node region within the substrate spaced apart from the first node region and having a second conductivity type different from the first conductivity type, and an avalanche multiplication region formed between the first node region and the second node region. The first node region, the avalanche multiplication region, and the second node region are arranged along a first direction parallel to the first surface.

### CROSS-REFERENCE TO RELATED APPLICATIONS

The application claims benefit of priority under 35 U.S.C. § 119 to Korean Patent Application Nos. 10-2023-0096675 filed on Jul. 25, 2023, and 10-2024-0074097 filed on Jun. 6, 2024, in the Korean Intellectual Property Office, the disclosures of which are incorporated by reference herein in their entireties.

### BACKGROUND

The present disclosure relates generally to photodetection elements, photodetectors, and electronic devices.

An avalanche photodiode (APD) is a solid-state photodetector in which a high bias voltage is applied to a p-n junction to provide a high gain from an avalanche multiplication. When an incident photon with energy higher than the band gap in a semiconductor reaches a photodiode, electron-hole pairs (EHPs) are generated. A high electric field accelerates photo-generated electrons quickly toward an anode, and the additional electron-hole pairs are generated in succession by impact ionization by such accelerated electrons, and then those of the electrons accelerate toward the anode. Similarly, the high electric field accelerates photo-generated holes quickly towards a cathode, and then causes the same phenomenon. This process repeats the process leading to the avalanche multiplication of the photo-generated electrons and holes. Thus, the APD is a semiconductor-based device that operates similarly to photomultiplier tubes. The linear-mode APD is an effective amplifier that can control the bias voltage to set the gain and obtain tens to thousands of the gains in linear mode.

A single photon avalanche diode (SPAD) is an APD in which a p-n junction is biased above the breakdown voltage to operate in Geiger mode. An incident single photon can trigger the avalanche phenomenon, generating a very large current, and as a result, obtain a pulse signal that can be easily measured. That is, the SPAD operates as a device that generates a large pulse signal compared to the linear-mode APD. After triggering an avalanche, a quenching resistor or a circuit is used to reduce a bias voltage under the breakdown voltage in order to quench an avalanche process. Once the avalanche process is quenched, the bias voltage is increased again over the breakdown voltage so that the SPAD is reset for a detection of another photon.

The SPADs can be configured with the quenching resistor or the circuit as well as a recharge circuit, a memory, a gate circuit, a counter, and a time-digital converter, and the like. SPAD pixels can be easily configured into arrays, since the SPAD pixels consist of semiconductors.

### SUMMARY

Embodiments of the present disclosure provide miniaturized photodetection devices, photodetectors, and electronic devices with improved light detection efficiency, wide light detection wavelength range, improved fill factor, and enhanced efficiency.

According to example embodiments, a photodetection element comprises a substrate having a first surface and a second surface opposite to each other, a first node region within the substrate and having a first conductivity type, a second node region within the substrate spaced apart from the first node region and having a second conductivity type different from the first conductivity type, and an avalanche multiplication region formed between the first node region and the second node region. The first node region, the avalanche multiplication region, and the second node region are arranged along a first direction parallel to the first surface.

According to further aspects of the invention, the second node region is configured to surround the first node region.

According to further aspects of the invention, the first node region and the second node region extend along a second direction intersecting the first direction.

According to further aspects of the invention, the first node region includes a first contact region, and a first well provided between the first contact region and the second surface and having a doping concentration lower than that of the first contact region.

According to further aspects of the invention, in the first node region extending along a second direction intersecting the first direction, a central portion of the first contact region and a central portion of the first well are arranged to overlap.

According to further aspects of the invention, in the first node region extending along a second direction intersecting the first direction, the first well surrounds the first contact region and extends along the second direction.

According to further aspects of the invention, the first node region further includes a first deep well provided between the first well and the second surface and having a doping concentration lower than that of the first contact region.

According to further aspects of the invention, in the first node region extending along a second direction intersecting the first direction, a central portion of the first contact region and a central portion of the first deep well are arranged to overlap.

According to further aspects of the invention, in the first node region extending along a second direction intersecting the first direction, the first deep well surrounds the first contact region and extends along the second direction.

According to further aspects of the invention, the second node region includes a second contact region, and a second well provided between the second contact region and the second surface and having a doping concentration lower than that of the second contact region.

According to further aspects of the invention, the second node region further includes a second deep well provided between the second well and the second surface and having a doping concentration lower than that of the second contact region.

According to further aspects of the invention, the photodetection element further comprises a buried well provided between the first node region and the second surface and between the second node region and the second surface, extending along the first direction, and having the second conductivity type and an additional avalanche multiplication region formed between the first node region and the buried well.

According to further aspects of the invention, the second node region and the buried well are in contact with each other.

According to further aspects of the invention, the photodetection element further comprises a buried insulating layer provided between the first node region and the second surface and between the second node region and the second surface, extending along the first direction, and including an electrical insulating material.

According to example embodiments, a photodetector comprises a photodetection element, a connection layer and an optical element layer that transmits incident light to the photodetection element. The photodetection element includes, a substrate having a first surface and a second surface on opposite sides of each other, a first node region provided in the substrate and having a first conductivity type, a second node region spaced apart from the first node region in the substrate and having a second conductivity type different from the first conductivity type, and an avalanche multiplication region formed between the first node region and the second node region. The first node region, the avalanche multiplication region, and the second node region are arranged along a first direction parallel to the first surface. The connection layer includes conductive lines electrically connected to at least one of the first node region and the second node region.

According to example embodiments, the optical element layer includes a plurality of lenses, optical axes of the plurality of lenses are located within the avalanche multiplication region.

According to example embodiments, the optical element layer includes a plurality of optical patterns. The plurality of the optical patterns diffracts or scatters incident light and transmits the incident light to the avalanche multiplication region.

According to example embodiments, the connection layer and the optical element layer are sequentially disposed on the first surface.

According to example embodiments, the connection layer is provided on the first surface. The optical element layer is provided on the second surface.

An electronic device comprises a light-emitting device and a photodetection element that detects incident light reflected from a subject and returned after being emitted from the light-emitting device and is configured to measure a distance to the subject using time difference information between a transmission signal of the light emitting device and a detection signal of the photodetection element. The photodetection element comprises a substrate having a first surface and a second surface provided on opposite sides of each other, a first node region provided within the substrate and having a first conductivity type, a second node region spaced apart from the first node region within the substrate and having a second conductivity type different from the first conductivity type, and an avalanche multiplication region formed between the first node region and the second node region. The first node region, the avalanche multiplication region, and the second node region are arranged along a first direction parallel to the first surface.

Additional aspects will be set forth in part in the description which follows and, in part, will be apparent from the description, or may be learned by practice of some example embodiments of the inventive concepts.

### BRIEF DESCRIPTION OF DRAWINGS

The above and other aspects, features, and advantages of some example embodiments of the present disclosure will be more apparent from the following description taken in conjunction with the accompanying drawings, in which:

FIG. 1 is a plan view of a photodetection element according to some example embodiments.

FIG. 2 is a cross-sectional view of the photodetection element according to some example embodiment corresponding to line A-A′ in FIG. 1.

FIGS. 3, 4, 5, 6, 7, and 8 are plan views of photodetection elements according to some example embodiments corresponding to FIG. 2.

FIGS. 9, 10, 11, 12, 13, 14, 15, 16, 17, 18, 19, 20, 21, 22A, 22B, and 22C are cross-sectional views of photodetection elements according to some example embodiments corresponding to line A-A′ in FIG. 1.

FIG. 23 is a plan view of a photodetection element according to some example embodiments.

FIG. 24 is a cross-sectional view corresponding to line B-B′ of the photodetection element of FIG. 23 according to some example embodiments.

FIGS. 25, 26, and 27A are plan views of photodetection elements according to some example embodiments.

FIG. 27B is a cross-sectional view according to some example embodiment corresponding to the Ca-Ca′ line of the photodetection element of FIG. 27A.

FIG. 28A is a plan view of a photodetection element according to some example embodiments.

FIG. 28B is a cross-sectional view taken along line Cb-Cb′ of FIG. 28A.

FIG. 29A is a plan view of a photodetection element according to some example embodiments.

FIG. 29B is a cross-sectional view according to some example embodiment corresponding to the Da-Da′ line of the photodetection element of FIG. 29A.

FIG. 30A is a plan view of a photodetection element according to some example embodiments.

FIG. 30B is a cross-sectional view according to some example embodiments corresponding to line Db-Db′ in FIG. 30A.

FIGS. 31, 32, 33, 34, 35, 36, and 37 are cross-sectional views of photodetection elements according to some example embodiments corresponding to line B-B′ in FIG. 23.

FIG. 38A is a plan view of a photodetection element according to some example embodiments.

FIG. 38B is a cross-sectional view according to some example embodiments corresponding to line Ea-Ea′ of the photodetection element of FIG. 38A.

FIG. 39A is a plan view of a photodetection element according to some example embodiments.

FIG. 39B is a cross-sectional view according to some example embodiments corresponding to line Eb-Eb′ of the photodetection element of FIG. 39A.

FIG. 40 is a plan view of a photodetection element according to some example embodiments.

FIG. 41 is a cross-sectional view corresponding to line F-F′ of the photodetection element of FIG. 40 according to some example embodiments.

FIGS. 42A and 42B are cross-sectional views of photodetection elements according to some example embodiments corresponding to line F-F′ in FIG. 40.

FIGS. 43, 44, 45, 46, 47, 48, 49, 50, 51, 52, 53, 54, and 55A are cross-sectional views of photodetectors according to some example embodiments.

FIGS. 55B and 55C are plan views of optical pattern layer according to some example embodiments of FIG. 55A.

FIGS. 56 and 57 are cross-sectional views of a photodetector according to some example embodiments.

FIG. 58 is a plan view illustrating a pixel array of a photodetector according to some example embodiments.

FIGS. 59, 60, 61, and 62A are cross-sectional views illustrating pixel arrays according to some example embodiments corresponding to line G-G′ in FIG. 58.

FIG. 62B is a plan view illustrating the first node region and the second node region of FIG. 62A.

FIGS. 63 and 64 are cross-sectional views according to some example embodiments corresponding to line G-G′ in FIG. 58.

FIG. 65 is a block diagram for explaining an electronic device according to some example embodiments.

FIGS. 66 and 67 are conceptual diagrams illustrating cases in which a LiDAR device is applied to a vehicle according to some example embodiments.

### DETAILED DESCRIPTION

Hereinafter, some example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are some example embodiments, and thus, the present disclosure is not limited thereto, and may be realized in various other forms. Some example embodiments provided in the following description is not excluded from being associated with one or more features of some other example embodiments also provided herein or not provided herein but consistent with the present disclosure. It will be also understood that, even if a certain step or operation of manufacturing an apparatus or structure is described later than another step or operation, the step or operation may be performed later than the other step or operation unless the other step or operation is described as being performed after the step or operation.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

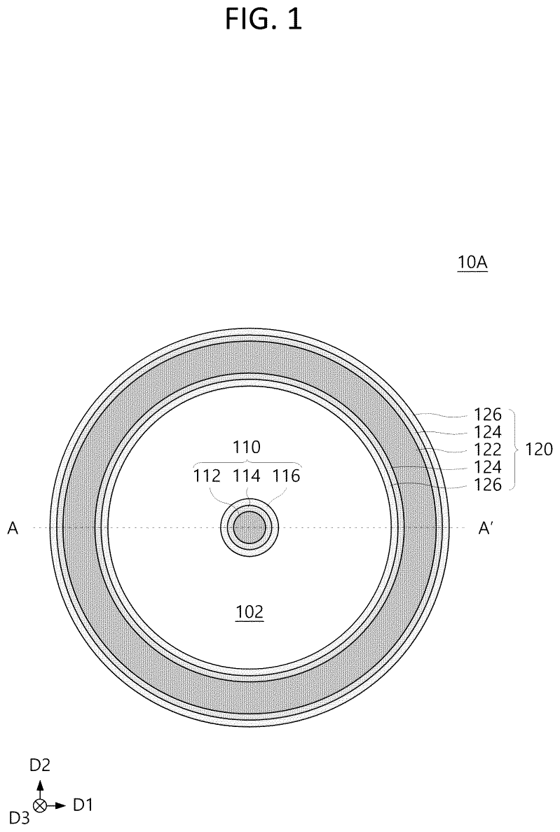

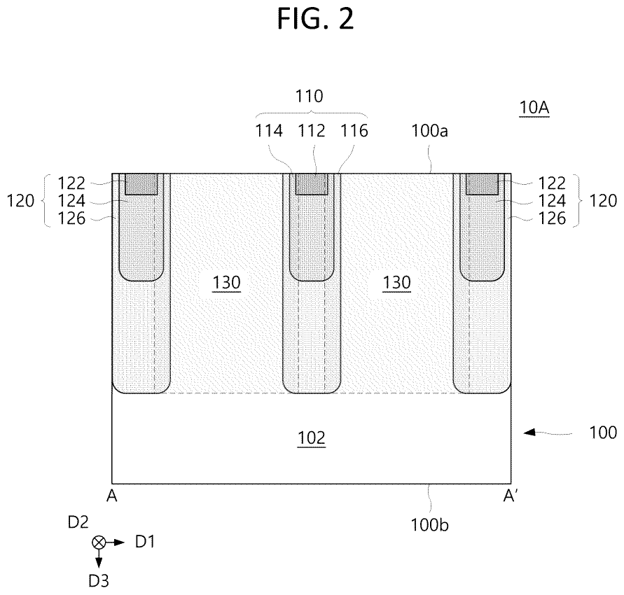

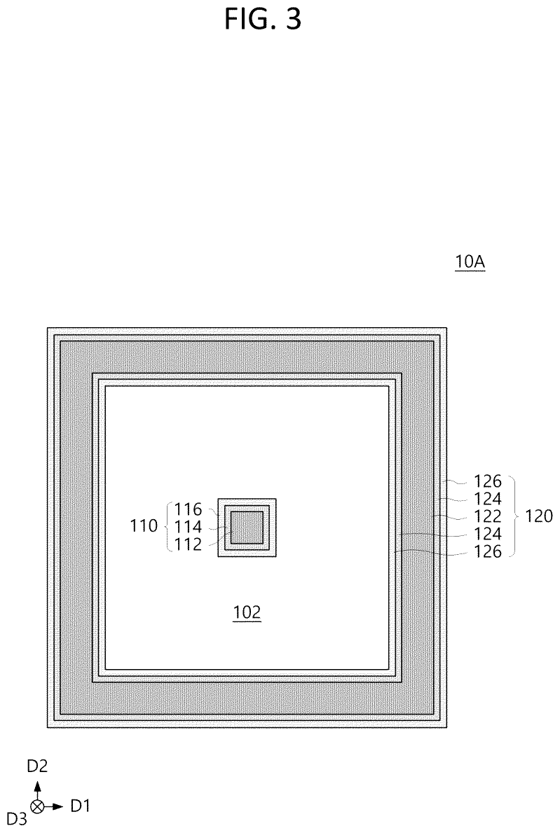

FIG. 1 is a plan view of a photodetection element according to some example embodiments. FIG. 2 is a cross-sectional view of the photodetection element according to some example embodiment corresponding to line A-A′ in FIG. 1. FIGS. 3 to 8 are plan views of photodetection elements according to some example embodiments corresponding to FIG. 2.

Referring to FIGS. 1 and 2, a photodetection element 10A may be provided. In some example embodiments, the photodetection element 10A may include an avalanche photodiode (APD) or a single photon avalanche diode (SPAD). The single photon avalanche diodes (SPADs) may be referred to as Geiger-mode avalanche diodes (Geiger-mode APDs, G-APDs). The photodetection element 10A may include a substrate 100, a first node region 110, and a second node region 120. In some example embodiments, the substrate 100 may be an epitaxial layer formed by an epitaxial growth process. The substrate 100 may include a semiconductor. For example, the substrate 100 may be a silicon (Si), a germanium (Ge), or a silicon germanium (SiGe) substrate. The substrate 100 may include a frontside surface 100a and a backside surface 100b located on opposite sides of each other. The frontside surface 100a may be a surface where various semiconductor processes are performed when manufacturing the photodetection element 10A. The frontside surface 100a and the backside surface 100b may be extended along a first direction D1 and a second direction D2. A direction from the frontside surface 100a to the backside surface 100b may be a third direction D3.

A conductivity type of the substrate 100 may be p-type or n-type. When the conductivity type of the substrate 100 is p-type, the substrate 100 may include a group 3 element or a group 2 element as an impurity. For example, the group 3 element may be boron (B), aluminum (Al), gallium (Ga), or indium (In). Hereinafter, a region that the conductivity type is p-type may include the group 3 or 2 element as the impurity (hereinafter referred to as a first impurity). When the conductivity type of the substrate 100 is n-type, the substrate 100 may include a group 5 element, a group 6 element, or a group 7 element as an impurity. For example, the group 5 element may be phosphorus (P), arsenic (As), or antimony (Sb). Hereinafter, a region that the conductivity type is n-type may include the impurity of the group 5, 6, or 7 element (hereinafter referred to as a second impurity). For example, a doping concentration of the substrate 100 may be 1×10¹⁴ to 1×10¹⁹ cm⁻³.

The first node region 110 may be provided within the substrate 100. The first node region 110 may be a cathode or an anode of the photodetection element 10A. The first node region 110 may include a first contact region 112, a first well 114, and a first deep well 116. The first contact region 112 may be provided adjacent to the frontside surface 100a. A top surface of the first contact region 112 may be located at a level adjacent to a level of the frontside surface 100a. For example, the top surface of the first contact region 112 may be located at substantially the same level as the frontside surface 100a. The first contact region 112 may have a first conductivity type. For example, the first conductivity type may be n-type or p-type. For example, a doping concentration of the first contact region 112 may be 1×10¹⁵ to 2×10²⁰ cm⁻³. In some example embodiments, when a bias voltage is applied to the first node region 110, the first contact region 112 may be electrically connected to at least one of an external power, a DC-DC converter, and other power management integrated circuit. In some example embodiments, when a photodetection signal is output from the first node region 110, the first contact region 112 may be electrically connected to at least one of a quenching resistor or quenching circuit, and other pixel circuits. The quenching resistor or quenching circuit can stop the avalanche effect and allow the photodetection element 10A to detect other photons. Other pixel circuits may include, for example, a reset or recharge circuit, a memory, an amplifier circuit, a counter, a gate circuit, a time-to-digital converter, and the like. Other pixel circuits may transmit signals to the photodetection element 10A or receive signals from the photodetection element 10A.

The first well 114 may be provided between the first contact region 112 and the backside surface 100b. The first contact region 112 and the first well 114 may be arranged along the third direction D3. The first well 114 may be formed closer to the backside surface 100b than the first contact region 112. The first well 114 may be extended onto a side surface of first contact region 112. The first well 114 may cover the side surface of the first contact region 112. A top surface of the first well 114 may be located at a level adjacent to a level of the top surface of the first contact region 112. For example, the top surface of the first well 114 may be located at substantially the same level as the top surface of the first contact region 112. The first well 114 may surround the side surface of the first contact region 112. In some other example embodiments, the first well 114 may expose at least a portion of the side surface of the first contact region 112. That is, the first well 114 may not cover at least the portion of the side surface of the first contact region 112. The first well 114 may be in contact with the first contact region 112. The first well 114 may have the first conductivity type. A doping concentration of the first well 114 may be lower than the doping concentration of the first contact region 112. For example, the doping concentration of the first well 114 may be 1×10¹⁵ to 2×10¹⁸ cm⁻³. In some example embodiments, the first well 114 may have a uniform doping concentration. In some example embodiments, the doping concentration of the first well 114 may be decreased as it approaches the frontside surface 100a. In some example embodiments, the doping concentration of the first well 114 may be increased as it approaches the frontside surface 100a. In some example embodiments, the doping concentration of the first well 114 may have a Gaussian distribution. For example, the doping concentration of the first well 114 may be increased and then decreased from the backside surface 100b to the frontside surface 100a. In some example embodiments, the top surface of the first well 114 may be located at substantially the same level as the frontside surface 100a. In some example embodiments, the top surface of the first well 114 may be located below the frontside surface 100a.

The first deep well 116 may be provided between the first well 114 and the backside surface 100b. The first contact region 112, the first well 114, and the first deep well 116 may be arranged along the third direction D3. The first deep well 116 may be formed closer to the backside surface 100b than the first well 114. The first deep well 116 may be extended onto a side surface of the first well 114. The first deep well 116 may cover the side surface of the first well 114. A top surface of the first deep well 116 may be located at a level adjacent to a level of the top surface of the first well 114. For example, the top surface of the first deep well 116 may be located at substantially the same level as the top surface of the first well 114. The first deep well 116 may surround the first well 114. In some other example embodiments, the first deep well 116 may expose at least a portion of the side surface of the first well 114. That is, the first deep well 116 may not cover at least the portion of the side surface of the first well 114. The first deep well 116 may be in contact with the first well 114. The first deep well 116 may be arranged to be spaced apart from the first contact region 112 by the first well 114. The first deep well 116 may have the first conductivity type. A doping concentration of the first deep well 116 may be different from the doping concentration of the first well 114. The doping concentration of the first deep well 116 may be lower than the doping concentration of the first contact region 112. For example, the doping concentration of the first deep well 116 may be 1×10¹⁵ to 1×10¹⁸ cm⁻³. In some example embodiments, the first deep well 116 may have a uniform doping concentration. In some example embodiments, the doping concentration of the first deep well 116 may be decreased as it approaches the frontside surface 100a. In some example embodiments, the top surface of the first deep well 116 may be located at substantially the same level as the frontside surface 100a. In some example embodiments, the top surface of the first deep well 116 may be located below the frontside surface 100a.

The first contact region 112, the first well 114, and the first deep well 116 may be electrically connected. The first well 114 may improve the electrical connection characteristics of the first contact region 112 and the first deep well 116. For example, the first well 114 may prevent, limit or reduce a voltage drop when a bias voltage is applied to the first deep well 116 through the first contact region 112. The first well 114 may be configured to uniformly apply the bias voltage to the first deep well 116. When the top surface of the first deep well 116 is located closer to the backside surface 100b than the bottom surface of the first contact region 112, the first well 114 may connect the first contact region 112 and the first deep well 116.

A second node region 120 may be provided within the substrate 100. The second node region 120 may be arranged to be spaced apart from the first node region 110. The second node region 120 may have a ring shape surrounding the first node region 110. In some example embodiments, the first node region 110 may be located at the center of the second node region 120. In some example embodiments, the first node region 110 may be shifted from the center of the second node region 120. When the first node region 110 is the cathode of a photodetection element 10A, the second node region 120 may be the anode of the photodetection element 10A. When the first node region 110 is the anode of the photodetection element 10A, the second node region 120 may be the cathode of the photodetection element 10A. The second node region 120 may include a second contact region 122, a second well 124, and a second deep well 126. A region within the substrate 100 other than the second node region 120 and the first node region 110 may be a substrate region 102.

The second contact region 122 may be provided adjacent to the frontside surface 100a. The second contact region 122 may have a ring shape surrounding the first contact region 112. In some example embodiments, the first contact region 112 may be located at the center of the second contact region 122. In some example embodiments, the first contact region 112 may be shifted from the center of the second contact region 122. A top surface of the second contact region 122 may be located at a level adjacent to the level of the top surface of the first contact region 112. For example, the top surface of the second contact region 122 may be located at substantially the same level as the top surface of the first contact region 112. A bottom surface of the second contact region 122 may be located at a level adjacent to the level of the bottom surface of the first contact region 112. For example, the bottom surface of the second contact region 122 may be located at substantially the same level as the bottom surface of the first contact region 112. The second contact region 122 may have a second conductivity type different from the first conductivity type. When the first conductivity type is n-type, the second conductivity type may be p-type. When the first conductivity type is p-type, the second conductivity type may be n-type. For example, a doping concentration of the second contact region 122 may be 1×10¹⁵ to 2×10²⁰ cm⁻³. When a photodetection signal is an output from the first node region 110 and a bias voltage is applied to the second node region 120, the second contact region 122 may be electrically connected to at least one of an external power source, DC-DC converter, and other power management integrated circuits. When a bias voltage is applied to the first node region 110 and a photodetection signal is an output from the second node region 120, the second contact region 122 may be electrically connected to at least one of a quenching resistor or quenching circuit, and other pixel circuits.

The second well 124 may be provided between the second contact region 122 and the backside surface 100b. The second contact region 122 and the second well 124 may be arranged along the third direction D3. The second well 124 may be formed closer to the backside surface 100b than the second contact region 122. The second well 124 may be located on an upper portion of the substrate 100. The second well 124 may be extended onto a side surface of second contact region 122. The second well 124 may cover the side surface of the second contact region 122. A top surface of the second well 124 may be located at a level adjacent to a level of the top surface of the second contact region 122. For example, the top surface of the second well 124 may be located at substantially the same level as the top surface of the second contact region 122. A bottom surface of the second well 124 may be located at a level adjacent to a level of the bottom surface of the first well 114. For example, the bottom surface of the second well 124 may be located at substantially the same level as the bottom surface of the first well 114. The second well 124 may surround the second contact region 122. In some other example embodiments, the second well 124 may expose at least a portion of the side surface of the second contact region 122. That is, the second well 124 may not cover at least the portion of the side surface of the second contact region 122. The second well 124 may be in contact with the second contact region 122. The second well 124 may have the second conductivity type. A doping concentration of the second well 124 may be lower than the doping concentration of the second contact region 122. For example, the doping concentration of the second well 124 may be 1×10¹⁵ to 2×10¹⁸ cm⁻³. In some example embodiments, the second well 124 may have a uniform doping concentration. In some example embodiments, the doping concentration of the second well 124 may be decreased as it approaches the frontside surface 100a. In some example embodiments, the doping concentration of the second well 124 may be increased as it approaches the frontside surface 100a. In some example embodiments, the doping concentration of the second well 124 may have a Gaussian distribution. For example, the doping concentration of the second well 124 may be increased and then decreased from the backside surface 100b to the frontside surface 100a. For example, the top surface of the second well 124 may be located at substantially the same level as the frontside surface 100a. In some example embodiments, the top surface of the second well 124 may be located below the frontside surface 100a.

The second deep well 126 may be provided between the second well 124 and the backside surface 100b. The second contact region 122, the second well 124, and the second deep well 126 may be arranged along the third direction D3. The second deep well 126 may be formed closer to the backside surface 100b than the second well 124. The second deep well 126 may be extended onto a side surface of the second well 124. The second deep well 126 may cover the side surface of the second well 124. A top surface of the second deep well 126 may be located at a level adjacent to a level of the top surface of the second well 124. For example, the top surface of the second deep well 126 may be located at substantially the same level as the top surface of the second well 124. A bottom surface of the second deep well 126 may be located at a level adjacent to a level of the bottom surface of the first deep well 116. For example, the bottom surface of the second deep well 126 may be located at substantially the same level as the bottom surface of the first deep well 116. From a perspective along the third direction D3, the second deep well 126 may surround the side surface of the second well 124. In some other example embodiments, the second deep well 126 may expose at least a portion of the side surface of the second well 124. That is, the second deep well 126 may not cover at least the portion of the side surface of the second well 124. The second deep well 126 may be in contact with the second well 124. The second deep well 126 may be spaced apart from the second contact region 122 by the second well 124. The second deep well 126 may have the second conductivity type. A doping concentration of the second deep well 126 may be different from the doping concentration of the second well 124. The doping concentration of the second deep well 126 may be lower than the doping concentration of the second well 124. For example, the doping concentration of the second deep well 126 may be 1×10¹⁵ to 1×10¹⁸ cm⁻³. In some example embodiments, the second deep well 126 may have the uniform doping concentration. In some example embodiments, the doping concentration of the second deep well 126 may be decreased as it approaches the frontside surface 100a. In some example embodiments, the top surface of the second deep well 126 may be located at substantially the same level as the frontside surface 100a. In some other example embodiments, the top surface of the second deep well 126 may be located below the frontside surface 100a.

The second contact region 122, the second well 124, and the second deep well 126 may be electrically connected. The second well 124 may improve the electrical connection characteristics of the second contact region 122 and the second deep well 126. For example, the second well 124 may prevent, limit or reduce a voltage drop when a bias voltage is applied to the second deep well 126 through the second contact region 122. The second well 124 may be configured to uniformly apply a bias voltage to the second deep well 126. When the top surface of the second deep well 126 is located closer to the backside surface 100b than the bottom surface of the second contact region 122, the second well 124 may connect the second contact region 122 and the second deep well 126.

An avalanche multiplication region, which is a depletion region 130, may be provided between the first node region 110 and the second node region 120. When the photodetection element 10A is operated, a voltage difference may be occurred between the first node region 110 and the second node region 120. The voltage difference between the first node region 110 and the second node region 120 may be determined (e.g., set) that the depletion region 130 has an electric field of 3×10⁵ V/cm or more. The depletion region 130 with the electric field greater than 3×10⁵ V/cm may be referred to as the avalanche multiplication region. The avalanche multiplication region may be configured to avalanche multiply the charge generated by incident photons. When the photodetection element 10A is operated, the avalanche multiplication region may be formed in the depletion region 130.

In some example embodiments, the depletion region 130 may overlap a portion of the first node region 110. For example, the depletion region 130 may overlap a portion of the first contact region 112 adjacent to the second node region 120. For example, the depletion region 130 may overlap a portion of the first well 114 adjacent to the second node region 120. For example, the depletion region 130 may overlap a portion of the first deep well 116 adjacent to the second node region 120. In some example embodiments, the depletion region 130 may overlap a portion of the second node region 120. For example, the depletion region 130 may overlap a portion of the second contact region 122 adjacent to the first node region 110. For example, the depletion region 130 may overlap a portion of the second well 124 adjacent to the first node region 110. For example, the depletion region 130 may overlap a portion of the second deep well 126 adjacent to the first node region 110. The depletion region 130 may be formed from the frontside surface 100a to a level adjacent to a level of a bottom of the first node region 110 and the level of a bottom of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b than the level of the bottom surface of the first node region 110 and the level of the bottom surface of the second node region 120. A shape of the depletion region 130 may be an example. The shape of the depletion region 130 may be different from those illustrated within the technical spirit of the inventive concepts.

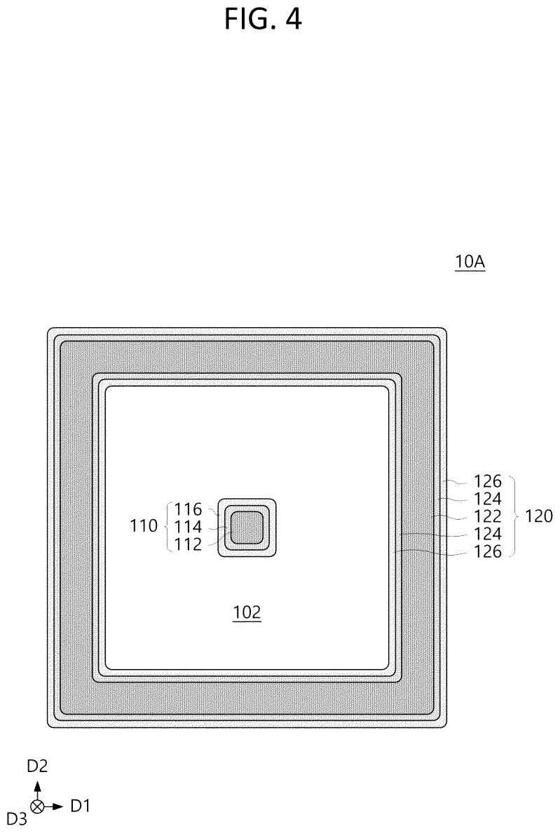

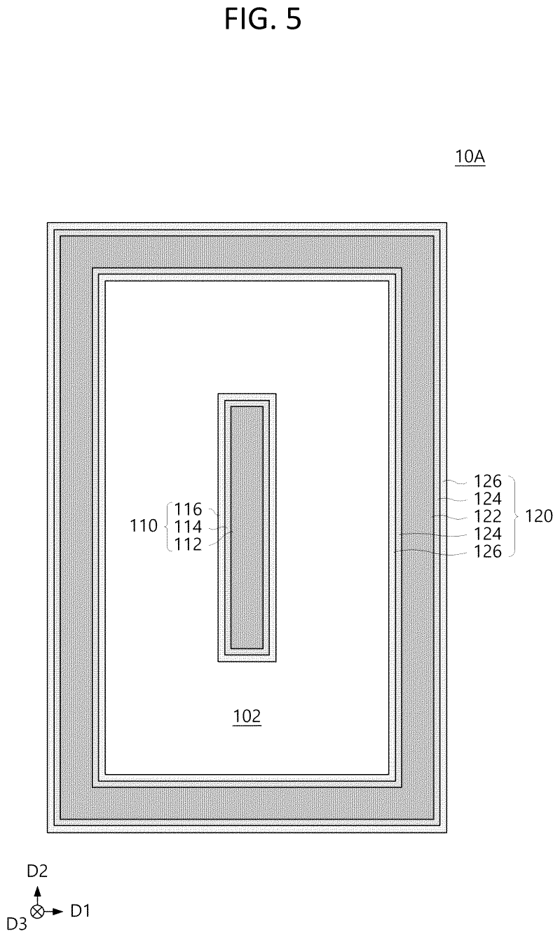

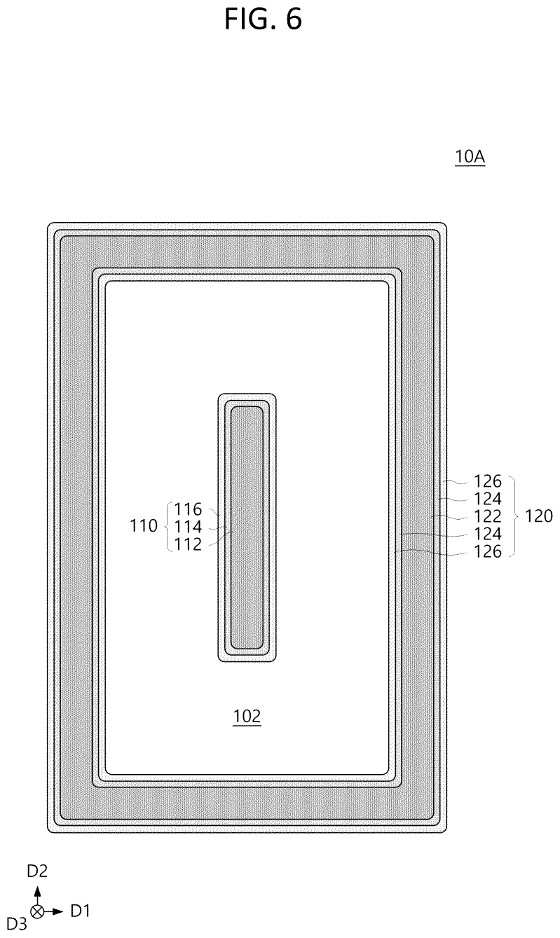

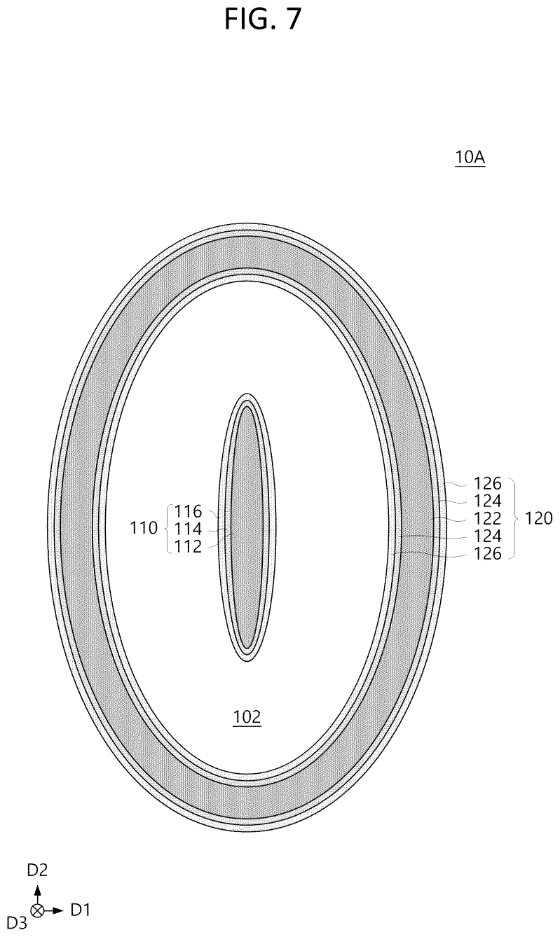

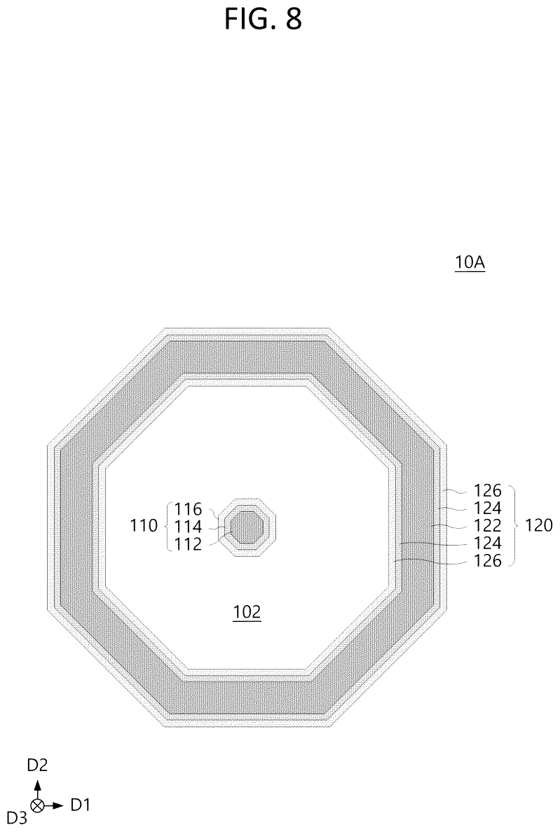

Referring to FIGS. 3 to 8, a photodetection element 10A may be provided. In some example embodiments, the first contact region 112 may have a square shape (see FIG. 3), a square shape with rounded corners (see FIG. 4), a rectangular shape (see FIG. 5), or a rectangular shape with rounded corners. (see FIG. 6), an oval shape (see FIG. 7), or an octagonal shape (see FIG. 8). In some example embodiments, the first well 114, the first deep well 116, the second contact region 122, the second well 124, and the second deep well 126 may have square ring shaped (see FIG. 3), a square ring shape with rounded corners (see FIG. 4), a rectangular ring shape (see FIG. 5), a rectangular ring shape with rounded corners (see FIG. 6), an oval ring shape (see FIG. 7), or an octagonal ring shape (see FIG. 8).

When regions of different conductivity types of a p-n junction or p-i-n junction may be arranged along a direction perpendicular to the frontside surface 100a of the substrate 100 (e.g., the third direction D3), the depletion region may be formed at a certain depth from the frontside surface 100a and have a narrow width. Carriers generated in regions shallower or deeper than the depletion region may not be detected, so photodetection efficiency may be limited when the width of the depletion region is narrow. Tunneling noise may be increased as noise charges generated by causes other than incident photons tunnel through the depletion region with the narrow width. Since an absorption depth varies depending on the wavelength of light, when the depletion region is formed at a certain depth and narrow width, the wavelength range of light that the photodetection element can efficiently detect may be narrowed. When a guard ring is used at an edge of the p-n junction or p-i-n junction, the fill factor and efficiency of the photodetection element or pixel may be decreased and miniaturization may be limited.

The depletion region 130 of the inventive concepts may be formed by the p-i-n junction formed along a horizontal direction on the frontside surface 100a of the photodetection element 10A. A formation depth and bias voltage of the first node region 110 and the second node region 120 are adjusted, so that the depletion region 130 may be formed from the frontside surface 100a to the required depth. For example, the depletion region 130 may be formed from the frontside surface 100a to a region adjacent to the backside surface 100b. Accordingly, the photodetection element 10A of the inventive concepts may include the depletion region 130 with a large thickness. Incident photons can be efficiently detected from the frontside surface 100a to the region adjacent to the backside surface 100b. As a result, the photodetection element 10A of the inventive concepts can have improved photodetection efficiency and a wider wavelength range for photodetection. Since the photodetection element 10A of the inventive concepts can operate without the use of a guard ring, it can have improved fill factor and efficiency, and can provide a more compact photodetection element, photodetection pixel, photodetector, and electronic device.

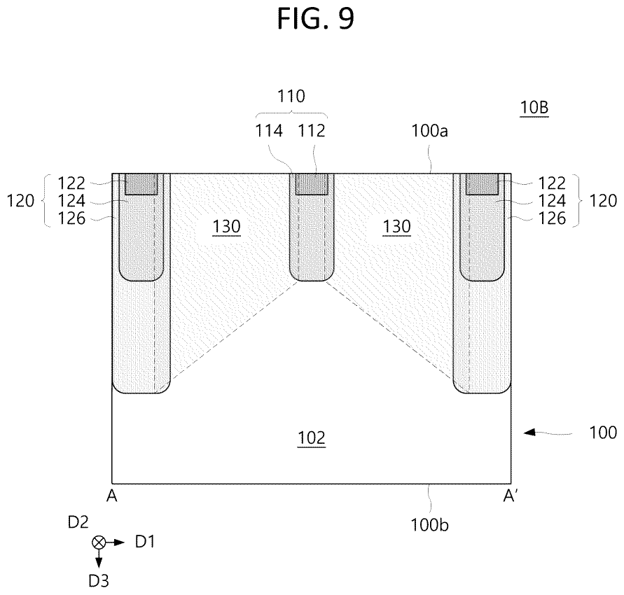

FIGS. 9 to 22C are cross-sectional views of photodetection elements according to some example embodiments corresponding to line A-A′ in FIG. 1. For brevity of explanation, these cross-sectional views may be explained focusing on differences from those described with reference to FIGS. 1 and 2.

Referring to FIG. 9, unlike those described with reference to FIGS. 1 and 2, a photodetection device 10B may not include the first deep well 116. The first well 114 may be in contact with the substrate region 102. The first node region 110 may be formed to a depth closer to the frontside surface 100a than the second node region 120. That is, the first node region 110 may be formed at a different depth than the second node region 120. The bottom surface of the second node region 120, which is close to the backside surface 100b, may be located at a different depth than the bottom surface of the first node region 110. For example, the portion of the second deep well 126 close to the backside surface 100b may be extended to a depth between the first node region 110 and the backside surface 100b.

The depletion region 130 may be formed from the frontside surface 100a to a level adjacent to the level of the bottom surface of the first node region 110 and the level of the bottom surface of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b than the level of the bottom surface of the first node region 110 and the level of the bottom surface of the second node region 120.

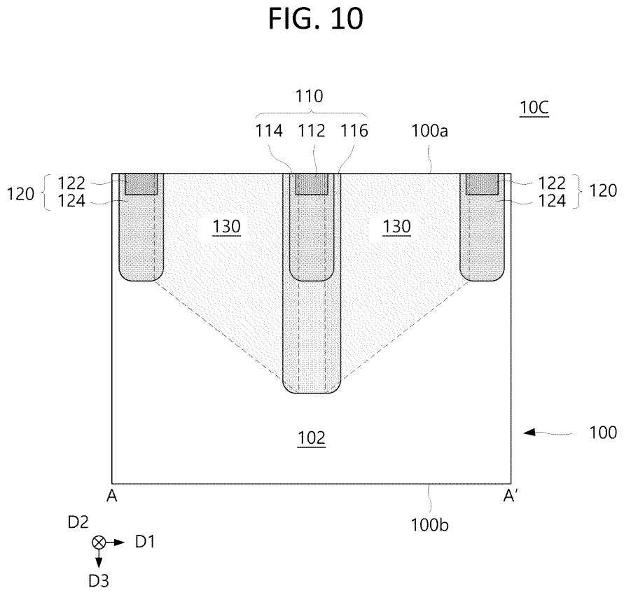

Referring to FIG. 10, unlike those described with reference to FIGS. 1 and 2, a photodetection device 10C may not include the second deep well 126. The second node region 120 may be formed to the depth closer to the frontside surface 100a than the first node region 110. That is, the first node region 110 may be formed at a different depth than the second node region 120. The bottom surface of the first node region 110 close to the backside surface 100b may be located at a different depth than the bottom surface of the second node region 120. For example, the portion of the first deep well 116 close to the backside surface 100b may be extended to a depth between the second node region 120 and the backside surface 100b.

The depletion region 130 may be formed from the frontside surface 100a to a level adjacent to the level of the bottom surface of the first node region 110 and the level of the bottom surface of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b than the level of the bottom surface of the first node region 110 and the level of the bottom surface of the second node region 120.

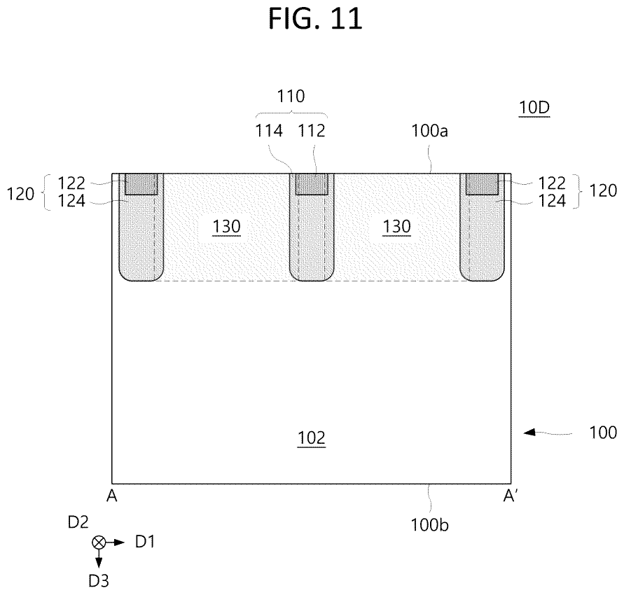

Referring to FIG. 11, unlike those described with reference to FIGS. 1 and 2, a photodetection device 10D may not include the first deep well 116 and the second deep well 126. The first well 114 and the second well 124 may be in contact with the substrate region 102. The depletion region 130 may be provided between the first well 114 and the second well 124. The depletion region 130 may be formed to a depth adjacent to the bottom surface of the first well 114 and the bottom surface of the second well 124 from the frontside surface 100a to the backside surface 100b. The depletion region 130 may overlap the portion of the first contact region 112 and the portion of the first well 114 close to the second node region 120. The depletion region 130 may overlap the portion of the second contact region 122 and the portion of the second well 124 close to the first node region 110.

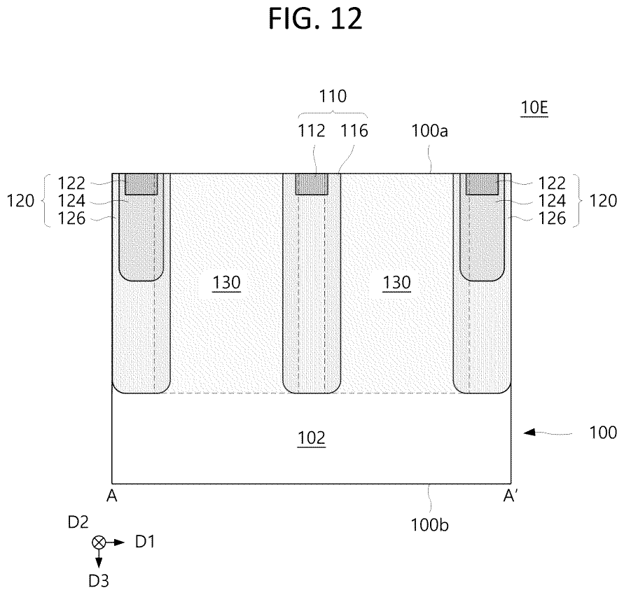

Referring to FIG. 12, unlike those described with reference to FIGS. 1 and 2, a photodetection device 10E may not include the first well 114. In some example embodiments, the depletion region 130 may overlap the portion of the first contact region 112 and the portion of the first deep well 116 close to the second node region 120. In some example embodiments, the depletion region 130 may overlap the portion of the second contact region 122, the portion of the second well 124, and the portion of the second deep well 126 close to the first node region 110.

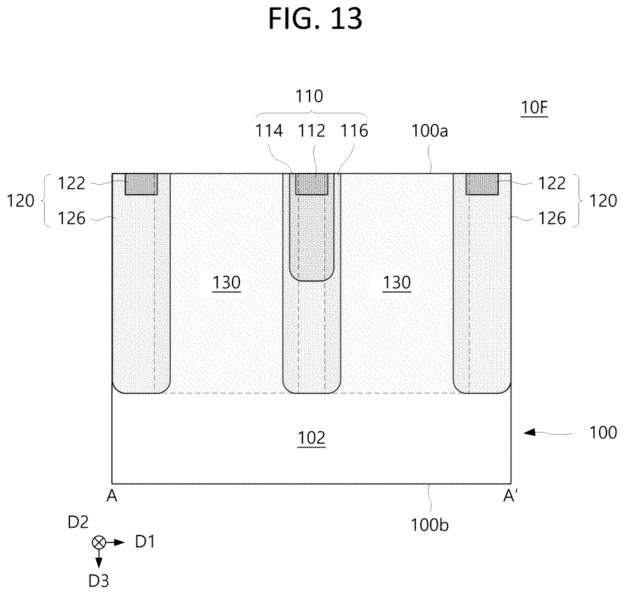

Referring to FIG. 13, unlike those described with reference to FIGS. 1 and 2, a photodetection device 10F may not include the second well 124. In some example embodiments, the depletion region 130 may overlap the portion of the first contact region 112, a portion of the first well 114, and the portion of the first deep well 116 close to the second node region 120. In some example embodiments, the depletion region 130 may overlap the portion of the second contact region 122 and the portion of the second deep well 126 close to the first node region 110.

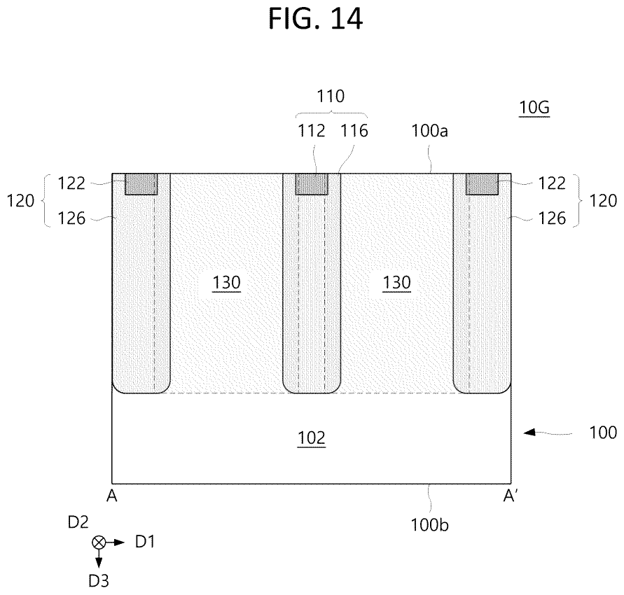

Referring to FIG. 14, unlike those described with reference to FIGS. 1 and 2, a photodetection element 10G may not include the first well 114 and the second well 124. In some example embodiments, the depletion region 130 may overlap the portion of the first contact region 112 and the portion of the first deep well 116 close to the second node region 120. In some example embodiments, the depletion region 130 may overlap the portion of the second contact region 122 and the portion of the second deep well 126 close to the first node region 110.

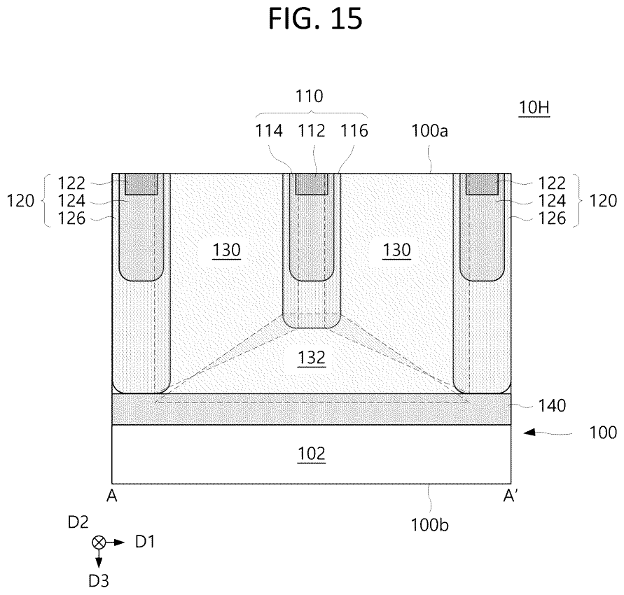

Referring to FIG. 15, unlike those described with reference to FIGS. 1 and 2, a photodetection element 10H may further include a buried well 140. The buried well 140 may be extended along the first direction D1 and the second direction D2 parallel to the frontside surface 100a. The buried well 140 may be provided between the first node region 110 and the backside surface 100b and between the second node region 120 and the backside surface 100b. The buried well 140 may be provided closer to the backside surface 100b than the first node region 110 and the second node region 120. The buried well 140 may overlap the first node region 110 and the second node region 120 along the third direction D3. The buried well 140 may have the second conductivity type. A doping concentration of the buried well 140 may be similar to the doping concentration of the second deep well 126. For example, the doping concentration of buried well 140 may be 1×10¹⁵ to 1×10¹⁸ cm⁻³.

The first node region 110 may be formed to the depth closer to the frontside surface 100a than the second node region 120. That is, the first node region 110 may be formed at a different depth than the second node region 120. The bottom surface of the second node region 120, which is close to the backside surface 100b, may be located at a different depth than the bottom surface of the first node region 110. For example, the portion of the second deep well 126 close to the backside surface 100b may be located to extend to the depth between the first node region 110 and the backside surface 100b.

The second deep well 126 may be formed to a deeper location than the first deep well 116. A distance between the second deep well 126 and the backside surface 100b may be smaller than a distance between the first deep well 116 and the backside surface 100b. The bottom surface of the second deep well 126 may be located closer to the backside surface 100b than the bottom surface of the first deep well 116. For example, the second deep well 126 may be in contact with the buried well 140.

The first deep well 116 and the buried well 140 may be spaced apart from each other along the third direction D3. An avalanche multiplication region, which is the depletion region 130, may be formed between the first node region 110 and the second node region 120. The depletion region 130 may be formed from the frontside surface 100a to a level adjacent to the level of the bottom surface of the first node region 110 and the level of the bottom surface of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b than the level of the bottom surface of the first node region 110 and the level of the bottom surface of the second node region 120.

An additional avalanche multiplication region, which is an additional depletion region 132, may be further formed between the first node region 110 and the buried well 140. When the photodetection element 10H is operated, a voltage difference may be occurred between the first node region 110 and the buried well 140. The voltage difference between the first node region 110 and the buried well 140 may be determined that the additional depletion region 132 has an electric field of 3×10⁵ V/cm or more. The additional depletion regions 132 with the electric fields greater than 3×10⁵ V/cm may be referred to as the additional avalanche multiplication regions. The additional avalanche multiplication regions may be configured to multiply the charge generated by incident photons. The additional depletion region 132 may overlap a lower portion of the first node region 110. For example, the additional avalanche multiplication region 132 may overlap a lower portion of first deep well 116. The additional avalanche multiplication region 132 may overlap an upper portion of the buried well 140.

The inventive concepts can increase photodetection efficiency by using the avalanche multiplication region formed between the first node region 110 and the second node region 120 and the additional avalanche multiplication region 132 formed between the first node region 110 and the buried well 140. Accordingly, the photodetection element 10H with improved photodetection efficiency may be provided.

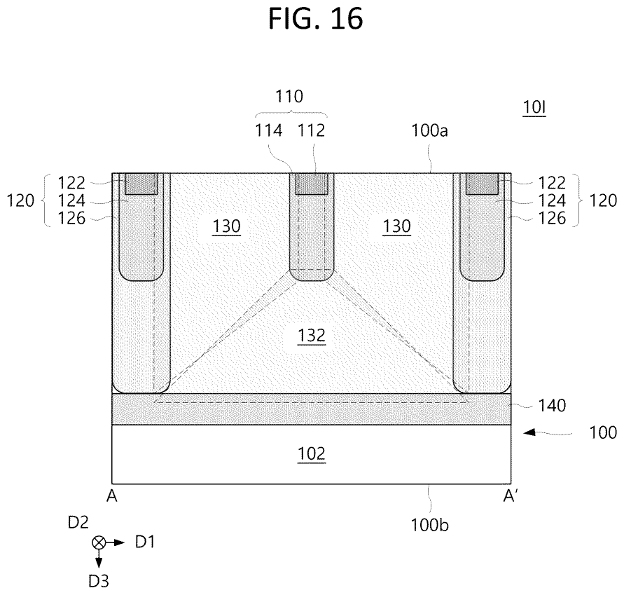

Referring to FIG. 16, unlike those described with reference to FIGS. 1 and 15, a photodetection element 10I may not include the first deep well 116. For brevity of explanation, these cross-sectional views may be explained by focusing on differences from those described with reference to FIGS. 1 and 15. The first well 114 may be in contact with the substrate region 102.

The second deep well 126 may be formed at a location deeper than the first well 114. The distance between the second deep well 126 and the backside surface 100b may be smaller than a distance between the first well 114 and the backside surface 100b. The bottom surface of the second deep well 126 may be located closer to the backside surface 100b than the bottom surface of the first well 114. For example, the second deep well 126 may be in contact with the buried well 140.

The first well 114 and the buried well 140 may be spaced apart from each other along the third direction D3. The avalanche multiplication region, which is the depletion region 130, may be formed between the first node region 110 and the second node region 120. The depletion region 130 may be formed from the frontside surface 100a to a level adjacent to the level of the bottom surface of the first node region 110 and the level of the bottom surface of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b than the level of the bottom surface of the first node region 110 and the level of the bottom surface of the second node region 120.

The additional avalanche multiplication region, which is the additional depletion region 132, may be further formed between the first node region 110 and the buried well 140. The additional depletion region 132 may overlap the lower portion of the first node region 110. For example, the additional avalanche multiplication region 132 may overlap a lower portion of the first well 114. The additional avalanche multiplication region 132 may overlap the upper portion of the buried well 140.

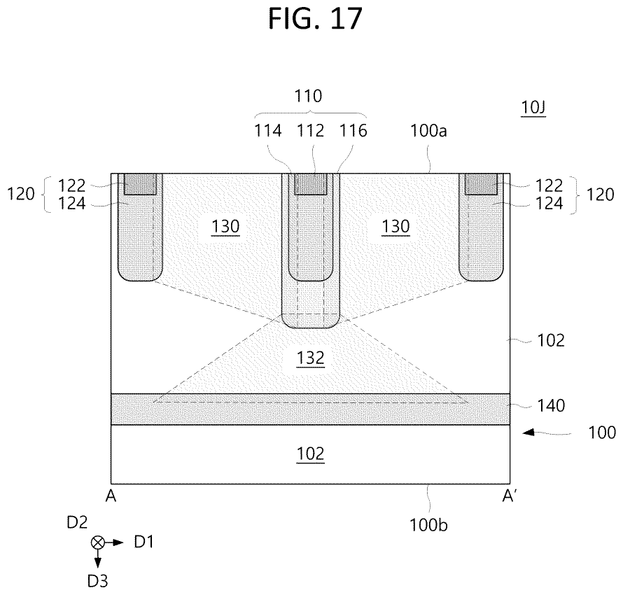

Referring to FIG. 17, unlike those described with reference to FIGS. 1 and 15, a photodetection element 10J may not include the second deep well 126. For brevity of explanation, these cross-sectional views may be explained by focusing on differences from those described with reference to FIGS. 1 and 15. The second well 124 may be in contact with the substrate region 102. The second node region 120 may be formed to the depth closer to the frontside surface 100a than the first node region 110. That is, the second node region 120 may be formed at a different depth from the first node region 110. The bottom surface of the first node region 110, which is close to the backside surface 100b, may be located at a different depth than the bottom surface of the second node region 120. For example, the portion of the first deep well 116 close to the backside surface 100b may be located to extend to the depth between the second node region 120 and the backside surface 100b.

The first deep well 116 may be formed at a location deeper than the second well 124. The distance between the first deep well 116 and the backside surface 100b may be smaller than a distance between the second well 124 and the backside surface 100b. The bottom surface of the first deep well 116 may be located closer to the backside surface 100b than the bottom surface of the second well 124.

The first deep well 116 and the buried well 140 may be spaced apart from each other along the third direction D3. The avalanche multiplication region, which is the depletion region 130, may be formed between the first node region 110 and the second node region 120. The depletion region 130 may be formed from the frontside surface 100a to a level adjacent to the level of the bottom surface of the first node region 110 and the level of the bottom surface of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b to the level than the level of the bottom surface of the first node region 110 and the level of the bottom surface of the second node region 120.

The additional avalanche multiplication region, which is the additional depletion region 132, may be further formed between the first node region 110 and the buried well 140. The additional depletion region 132 may overlap the lower portion of the first node region 110. For example, the additional avalanche multiplication region 132 may overlap the lower portion of the first deep well 116. The additional avalanche multiplication region 132 may overlap the upper portion of the buried well 140.

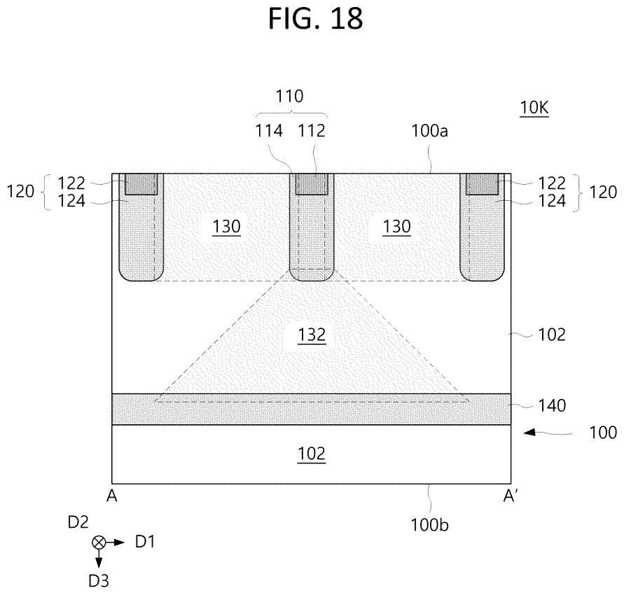

Referring to FIG. 18, unlike those described with reference to FIGS. 1 and 15, a photodetection element 10K may not include the first deep well 116 and the second deep well 126. For brevity of explanation, these cross-sectional views may be explained by focusing on differences from those described with reference to FIGS. 1 and 15. The first well 114 and the second well 124 may be in contact with the substrate region 102.

The first deep well 116 and the buried well 140 may be spaced apart from each other along the third direction D3. The avalanche multiplication region, which is the depletion region 130, may be formed between the first node region 110 and the second node region 120. The depletion region 130 may be formed from the frontside surface 100a to a level adjacent to the level of the bottom of the first node region 110 and the level of the bottom of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b than the level of the bottom surface of the first node region 110 and the level of the bottom surface of the second node region 120.

The additional avalanche multiplication region, which is the additional depletion region 132, may be further formed between the first node region 110 and the buried well 140. The additional depletion region 132 may overlap the lower portion of the first node region 110. For example, the additional avalanche multiplication region 132 may overlap a lower portion of the first well 114. The additional avalanche multiplication region 132 may overlap the upper portion of the buried well 140.

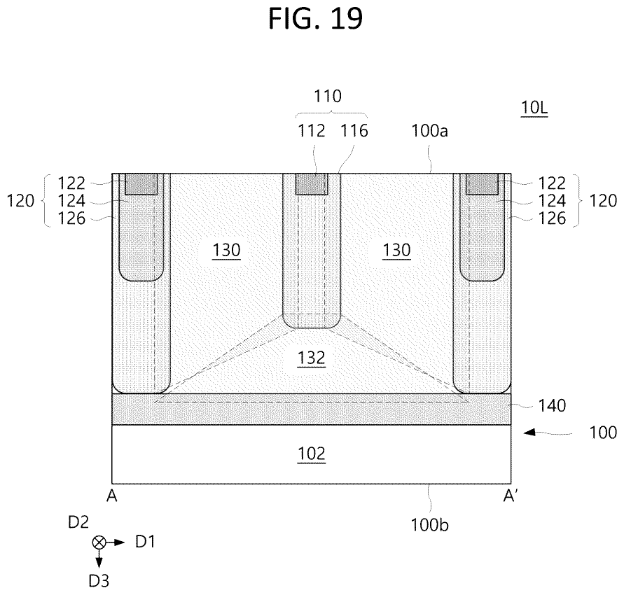

Referring to FIG. 19, unlike those described with reference to FIGS. 1 and 15, a photodetection element 10L may not include the first well 114.

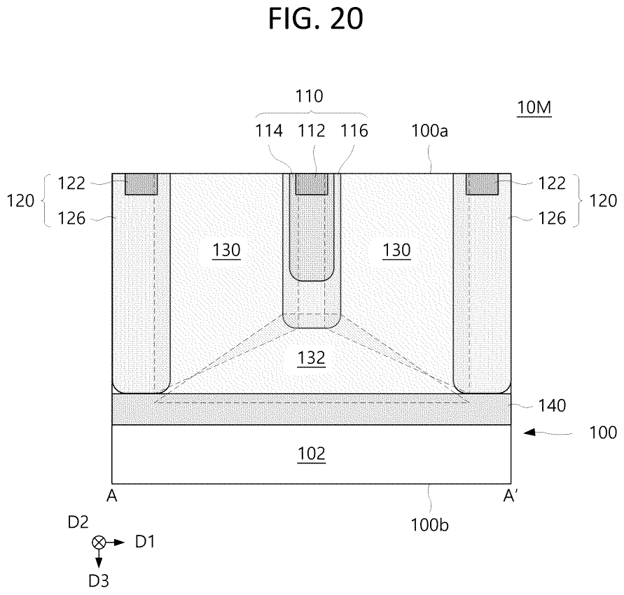

Referring to FIG. 20, unlike those described with reference to FIGS. 1 and 15, a photodetection element 10M may not include the second well 124.

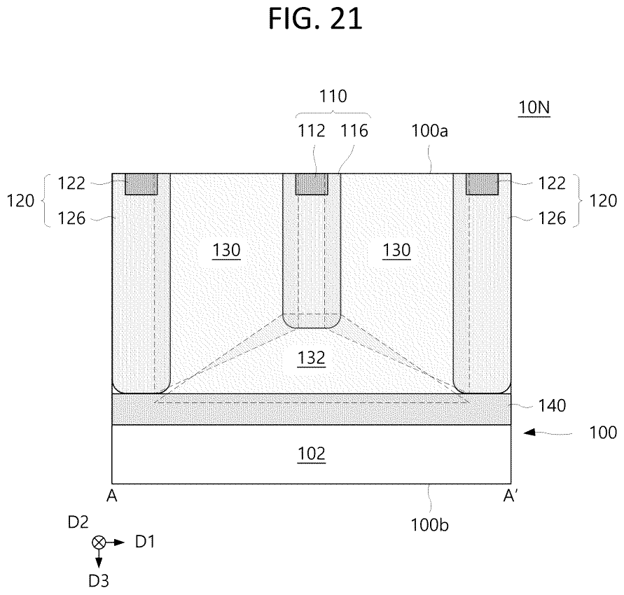

Referring to FIG. 21, unlike those described with reference to FIGS. 1 and 15, a photodetection element 10N may not include the first well 114 and the second well 124.

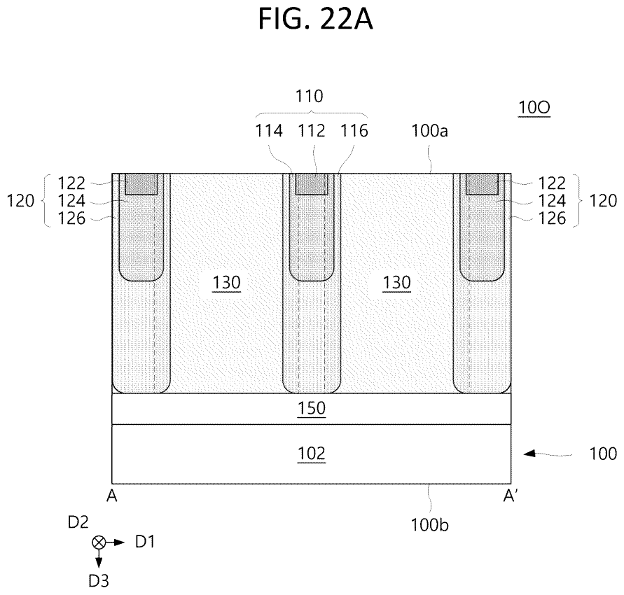

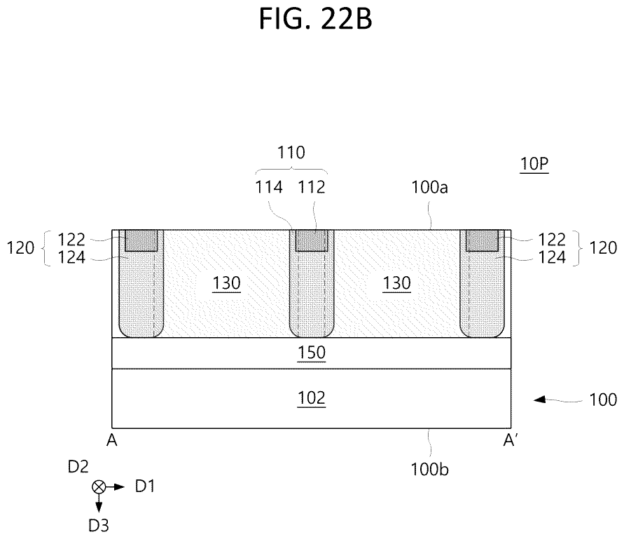

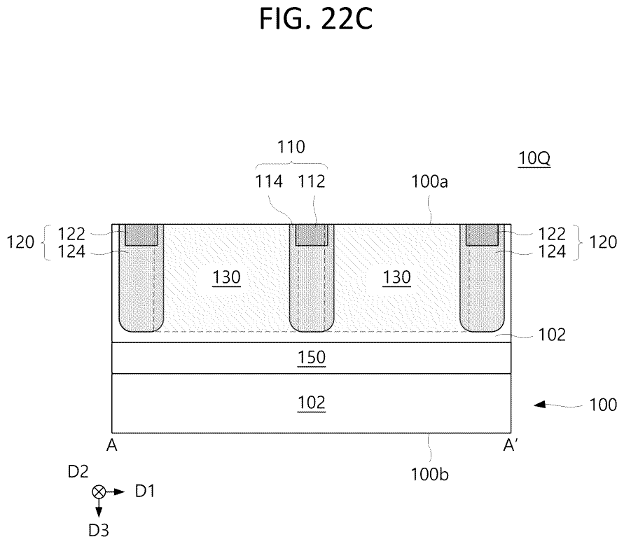

Referring to FIG. 22A, unlike those described with reference to FIGS. 1 and 2, a photodetection element 100 may further include a buried insulating layer 150. For brevity of explanation, these cross-sectional views may be explained focusing on differences from those described with reference to FIGS. 1 and 2. The buried insulating layer 150 may be provided between the first node region 110 and the backside surface 100b and between the second node region 120 and the backside surface 100b. The buried insulating layer 150 may be extended along a direction parallel to the frontside surface 100a and cross the substrate 100. In some example embodiments, the buried insulating layer 150 may be in contact with the first node region 110 and the second node region 120. For example, the buried insulating layer 150 may be in contact with a lower portion of the first deep well 116 and a lower portion of the second deep well 126. The buried insulating layer 150 may include an electrically insulating material. For example, the buried insulating layer 150 may include silicon oxide (e.g., SiO₂). The buried insulating layer 150 may improve the breakdown characteristics of the photodetection element 10A. Specifically, the buried insulating layer 150 may alleviate a concentration of the electric field in a portion of the depletion region 130 and prevent premature breakdown. The premature breakdown phenomenon may be occurred when breakdown occurs first in the portion of the depletion region 130 before an electric field of sufficient magnitude is applied throughout the depletion region 130. The premature breakdown phenomenon may be occurred as the electric field is concentrated in the portion of the depletion region 130. The buried insulating layer 150 may improve the leakage current characteristics of the photodetection element 100. The buried insulating layer 150 may improve the crosstalk phenomenon of the photodetection element 100. When the conductivity type of the substrate 100 is p-type, the buried insulating layer 150 may separate the anode of the photodetection element 100 from the substrate region 102. When the conductivity type of the substrate 100 is n-type, the buried insulating layer 150 may separate the cathode of the photodetection element 100 from the substrate region 102. This can make the implementation and operation of the circuit easier. The buried insulating layer 150 may serve to reflect incident light, and thus the photodetection element 100 of the inventive concepts may have improved photodetection efficiency and a wider wavelength range for photodetection.

The first node region 110 and the second node region 120 may be configured in various ways. For example, as illustrated in FIG. 9, the first node region 110 may not include the first deep well 116. For example, as illustrated in FIG. 10, the second node region 120 may not include the second deep well 126. For example, as illustrated in FIG. 12, the first node region 110 may not include the first well 114. For example, as illustrated in FIG. 13, the second node region 120 may not include the second well 124. For example, as illustrated in FIG. 14, the first node region 110 and the second node region 120 may not include the first well 114 and the second well 124, respectively.

Referring to FIG. 22B, a photodetection device 10P may be provided. Unlike FIG. 22A, the first node region 110 and the second node region 120 may not include the first deep well 116 and the second deep well 126, respectively. The buried insulating layer 150 may be in contact with the first well 114 and the second well 124.

Referring to FIG. 22C, a photodetection device 10Q may be provided. Unlike FIG. 22B, the buried insulating layer 150 may be spaced apart from the first well 114 and the second well 124. The substrate region 102 may be disposed between the buried insulating layer 150 and the first well 114 and between the buried insulating layer 150 and the second well 124.

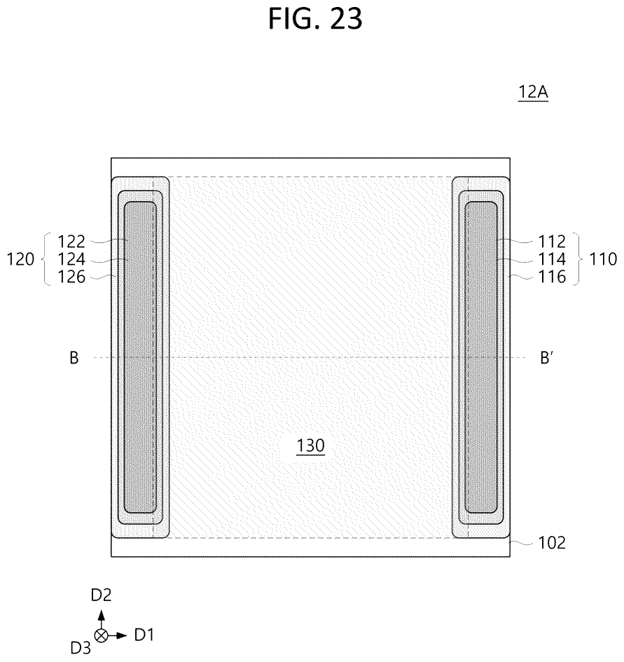

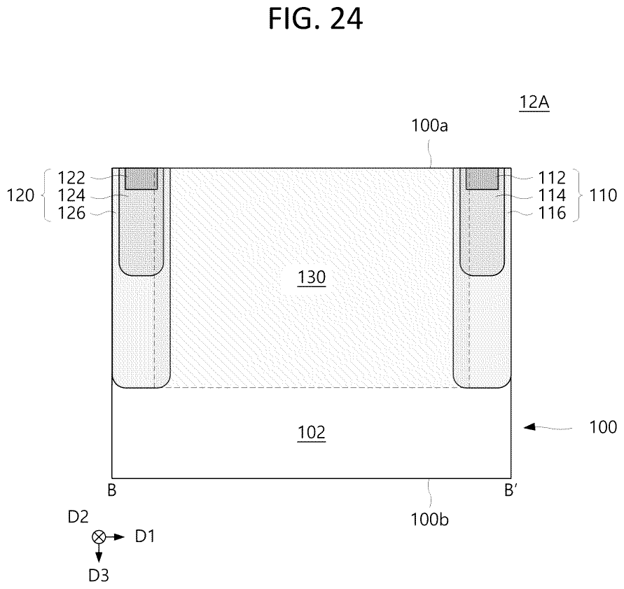

FIG. 23 is a plan view of a photodetection device according to some example embodiments. FIG. 24 is a cross-sectional view corresponding to line B-B′ of the photodetection device of FIG. 23 according to some example embodiments. For brevity of explanation, differences from those described with reference to FIGS. 1 and 2 may be explained.

Referring to FIGS. 23 and 24, a photodetection element 12A may be provided. The photodetection element 12A may include a substrate 100, a first node region 110, and a second node region 120. Unlike those described with reference to FIGS. 1 and 2, the first node region 110 and the second node region 120 may be extended along the second direction D2 and spaced apart from each other along the first direction D1. For example, the first node region 110 and the second node region 120 may be parallel to each other. Each of the first node region 110 and the second node region 120 may have a shape in which a length along the second direction D2 is greater than a width along the first direction D1. Each of the first node region 110 and the second node region 120 may have a rectangular shape with rounded corners.

The first node region 110 may include a first contact region 112, a first well 114, and a first deep well 116. The first contact region 112 may be extended along the second direction D2. A length of the first contact region 112 along the second direction D2 may be greater than a width of the first contact region 112 along the first direction D1. The first contact region 112 may have a constant width. From a perspective along the third direction D3, the first well 114 may completely surround the first contact region 112. The first contact region 112 may be disposed within the first well 114. From a perspective along the third direction D3, the first deep well 116 may completely surround the first well 114. The first deep well 116 may be spaced apart from the first contact region 112 by the first well 114.

The second node region 120 may include a second contact region 122, a second well 124, and a second deep well 126. The second contact region 122 may be extended along the second direction D2. A length of the second contact region 122 along the second direction D2 may be greater than a width of the second contact region 122 along the first direction D1. The second contact region 122 may have a constant width. From a perspective along the third direction D3, the second well 124 may completely surround the second contact region 122. The second contact region 122 may be disposed within the second well 124. From a perspective along the third direction D3, the second deep well 126 may completely surround the second well 124. The second deep well 126 may be spaced apart from the second contact region 122 by the second well 124.

The depletion region 130 may be provided between the first node region 110 and the second node region 120. The depletion region 130 may overlap the first node region 110 and the second node region 120 along the first direction D1. For example, the depletion region 130 may completely overlap the first node region 110 and the second node region 120 along the first direction D1.

The depletion region 130 may overlap the portion of the first node region 110. For example, the depletion region 130 may overlap the portion of the first contact region 112 adjacent to the second node region 120. For example, the depletion region 130 may overlap the portion of the first well 114 adjacent to the second node region 120. For example, the depletion region 130 may overlap the portion of the first deep well 116 adjacent to the second node region 120.

The depletion region 130 may overlap the portion of the second node region 120. For example, the depletion region 130 may overlap the portion of the second contact region 122 adjacent to the first node region 110. For example, the depletion region 130 may overlap the portion of the second well 124 adjacent to the first node region 110. For example, the depletion region 130 may overlap the portion of the second deep well 126 adjacent to the first node region 110.

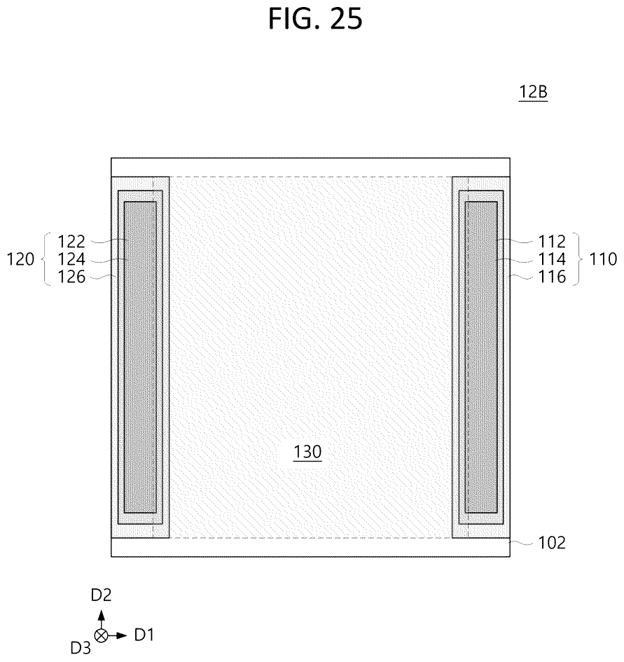

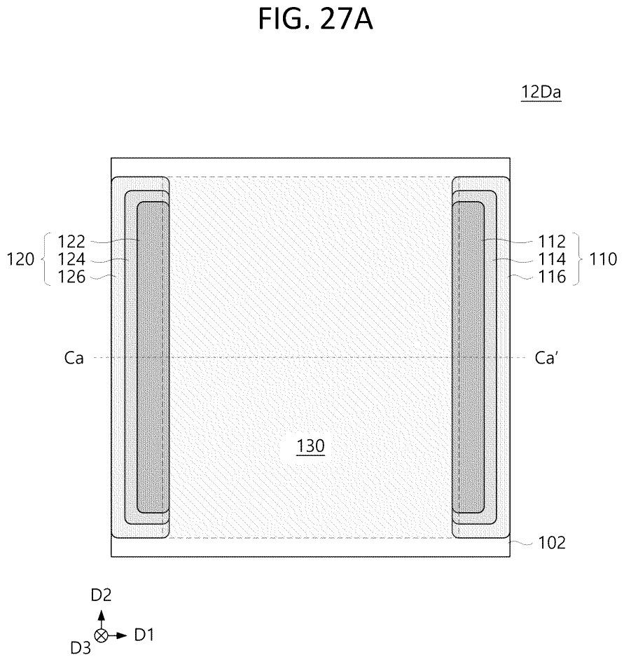

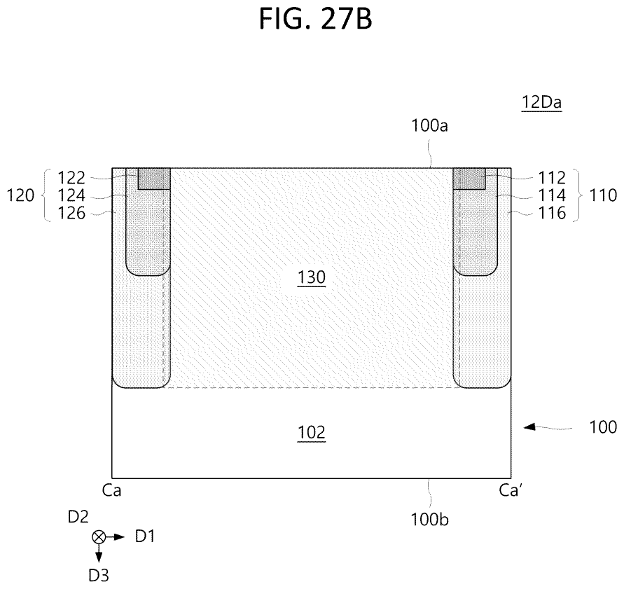

Referring to FIGS. 25 to 27A are plan views of photodetection devices according to some example embodiments. FIG. 27B is a cross-sectional view according to some example embodiment corresponding to the Ca-Ca′ line of the photodetection device of FIG. 27A. For brevity of explanation, differences from those described with reference to FIGS. 23 and 24 may be explained.

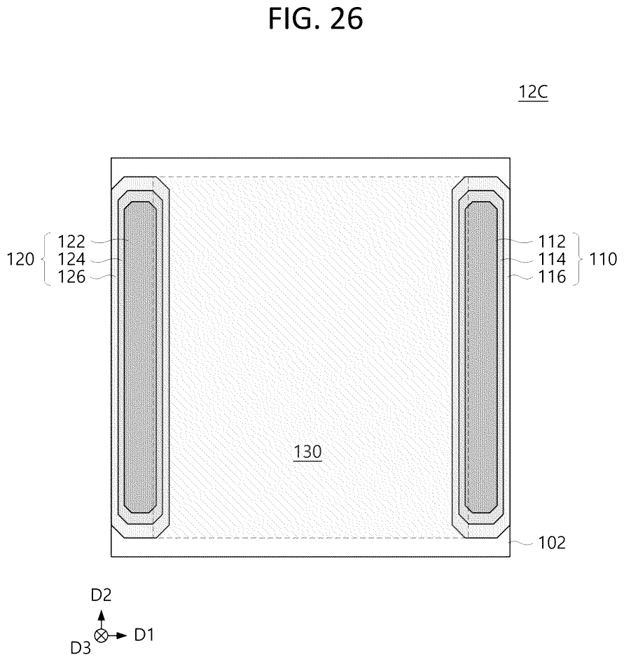

Referring to FIGS. 25 and 26, photodetection devices 12B and 12C may be provided. Unlike those described with reference to FIGS. 23 and 24, the first node region 110 may have a rectangular shape (see FIG. 25) or an octagonal shape (see FIG. 26). For example, the first contact region 112, the first well 114, and the first deep well 116 may have a rectangular shape (see FIG. 25) or an octagonal shape (see FIG. 26). The second node region 120 may have a rectangular shape (see FIG. 25) or an octagonal shape (see FIG. 26). For example, the second contact region 122, the second well 124, and the second deep well 126 may have a rectangular shape (see FIG. 25) or an octagonal shape (see FIG. 26).

Referring to FIGS. 27A and 27B, a photodetection device 12Da may be provided. The photodetection device 12Da may include a first node 110 and a second node 120. The first node 110 may include a first contact region 112, a first well 114, and a first deep well 116. The first contact region 112 may be shifted from a center of the first deep well 116 toward the second node region 120. For example, the first contact region 112 may be shifted from the center of the first deep well 116 in a direction opposite to the first direction D1. The first contact region 112 may be shifted from a center of the first well 114 toward the second node region 120. For example, the first contact region 112 may be shifted from the center of the first well 116 in the direction opposite to the first direction D1.

The first well 114 may be shifted from the center of the first deep well 116 toward the second node region 120. For example, the first well 114 may be shifted from the center of the first deep well 116 in the direction opposite to the first direction D1.

In some example embodiments, central portions of the first contact region 112 and the first well 114 may overlap a side portion of the first deep well 116 close to the second node region 120 along the third direction D3. A width of the first well 114 on a side surface of the first contact region 112 close to the second node region 120 may be smaller than the width of the first well 114 on the side surface of the first contact region 112 far from the second node region 120. A width of the first deep well 116 on the side surface of the first well 114 close to the second node region 120 may be smaller than the width of the first deep well 116 on a side surface of the first well 114 far from the second node region 120. For example, the side surfaces of the first contact region 112, the first well 114, and the first deep well 116 close to the second node region 120 may be aligned. For example, the side surfaces of the first contact region 112, the first well 114, and the first deep well 116 close to the second node region 120 may be coplanar.

The second node 120 may include a second contact region 122, a second well 124, and a second deep well 126. The second contact region 122 may be shifted from a center of the second deep well 126 toward the first node region 110. For example, the second contact region 122 may be shifted from the center of the second deep well 126 in the first direction D1. The second contact region 122 may be shifted from a center of the second well 124 toward the second node region 120. For example, the second contact region 122 may be shifted from the center of the second well 124 in the first direction D1.

The second well 124 may be shifted from the center of the second deep well 126 toward the first node region 110. For example, the second well 124 may be shifted in the first direction D1 from the center of the second deep well 126.

In some example embodiments, central portions of the second contact region 122 and the second well 124 may overlap a side portion of the second deep well 126 close to the first node region 110 along the third direction D3. A width of the second well 124 on a side surface of the second contact region 122 close to the first node region 110 may be smaller than the width of the second well 124 on the side surface of the second contact region 122 far from the first node region 110. The width of the second deep well 126 on the side surface of the second well 124 close to the first node region 110 may be smaller than the width of the second deep well 126 on a side surface of the second well 124 far from the first node region 110. For example, the side surfaces of the second contact region 122, the second well 124, and the second deep well 126 close to the first node region 110 may be aligned. For example, the side surfaces of the second contact region 122, the second well 124, and the second deep well 126 close to the first node region 110 may be coplanar.

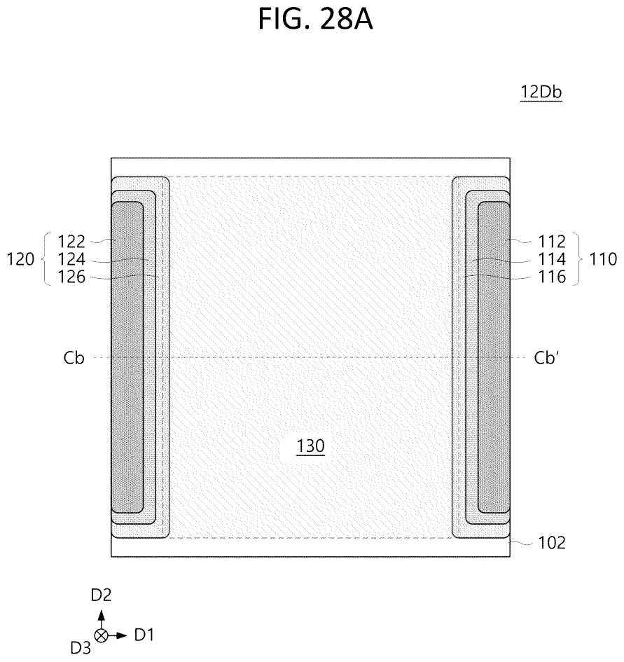

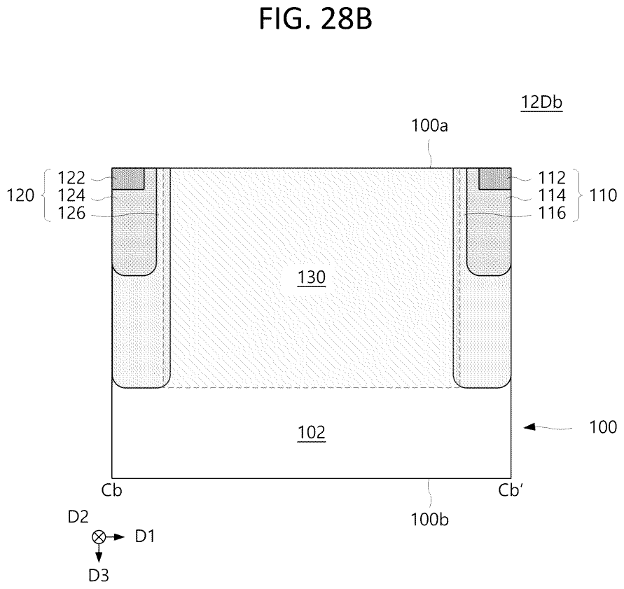

FIG. 28A is a plan view of a photodetection element according to some example embodiments. FIG. 28B is a cross-sectional view taken along line Cb-Cb′ of FIG. 28A. For brevity of explanation, differences from those described with reference to FIGS. 27A and 27B may be explained.

Referring to FIGS. 28A and 28B, a photodetection device 12 Db may be provided. The photodetection element 12Db may include a first node 110 and a second node 120. The first node 110 may include a first contact region 112, a first well 114, and a first deep well 116. Unlike those described with reference to FIGS. 27A and 27B, the first contact region 112 and the first well 114 may be shifted from the center of the first deep well 116 in a direction away from the second node region 120. For example, the first contact region 112 and the first well 114 may be shifted from the center of the first deep well 116 in the first direction D1.

The second node 120 may include a second contact region 122, a second well 124, and a second deep well 126. Unlike those described with reference to FIGS. 27A and 27B, the second contact region 122 and the second well 124 may be shifted from the center of the second deep well 126 in a direction away from the first node region 110. For example, the second contact region 122 and the second well 124 may be shifted from the center of the second deep well 126 in a direction opposite to the first direction D1.

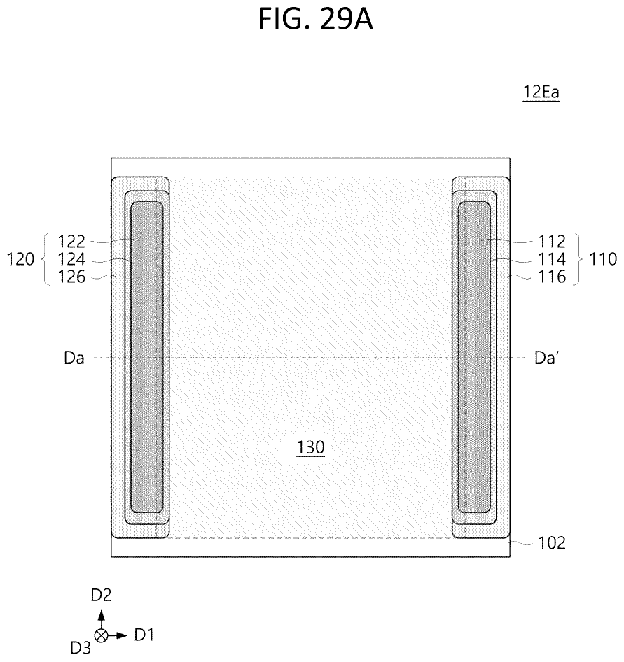

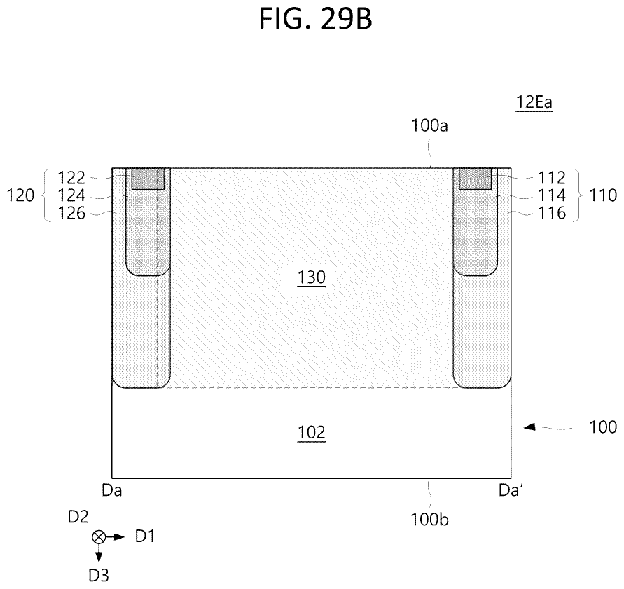

FIG. 29A is a plan view of a photodetection device according to some example embodiments. FIG. 29B is a cross-sectional view according to some example embodiment corresponding to the Da-Da′ line of the photodetection device of FIG. 29A. For brevity of explanation, differences from those described with reference to FIGS. 27A and 27B may be explained.

Referring to FIGS. 29A and 29B, a photodetection element 12Ea may be provided. Unlike those described with reference to FIGS. 27A and 27B, the first contact region 112 may be aligned at the center of the first well 114. The width of the first well 114 on the side surface of the first contact region 112 close to the second node region 120 may be substantially the same as the width of the first well 114 on the side surface of the first contact region 112 far from the second node region 120. For example, the central portions of the first contact region 112 and the first well 114 extending along the second direction D2 may substantially overlap.

The second contact region 122 may be aligned with the center of the second well 124. The width of the second well 124 on the side surface of the second contact region 122 close to the first node region 110 may be substantially the same as the width of the second well 124 on the side surface of the second contact region 122 far from the first node region 110. For example, the central portions of the second contact region 122 and the second well 124 extending along the second direction D2 may substantially overlap.

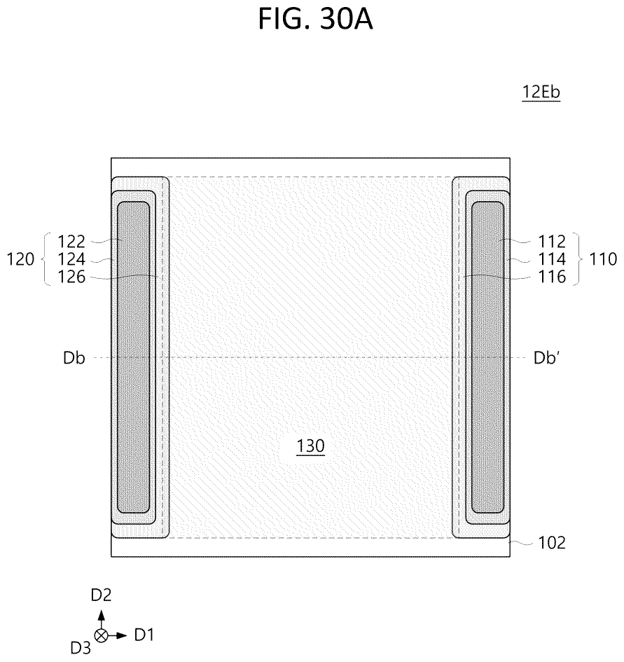

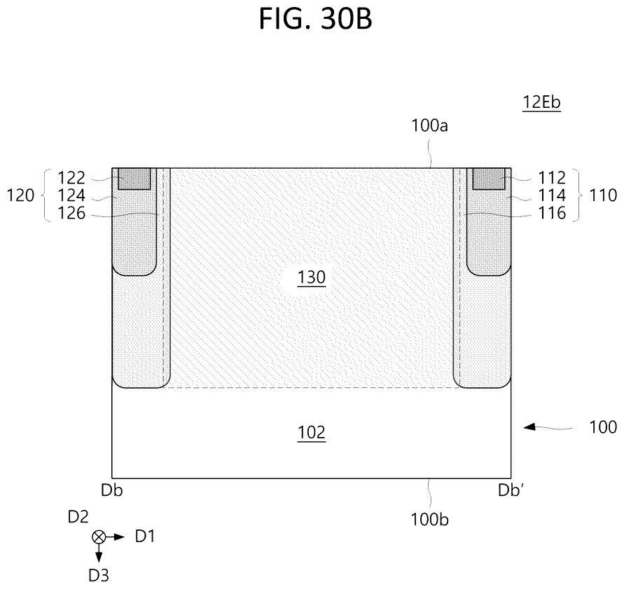

FIG. 30A is a plan view of a photodetection element according to some example embodiments. FIG. 30B is a cross-sectional view according to some example embodiments corresponding to line Db-Db′ in FIG. 30A. For brevity of explanation, differences from those described with reference to FIGS. 28A and 28B may be explained.

Referring to FIGS. 30A and 30B, a photodetection element 12Eb may be provided. Unlike those described with reference to FIGS. 28A and 28B, the first contact region 112 may be aligned at the center of the first well 114. The width of the first well 114 on the side surface of the first contact region 112 adjacent to the second node region 120 may be substantially the same as the width of the first well 114 on the side surface of the first contact region 112 far from the second node region 120. For example, the central portions of the first contact region 112 and the first well 114 extending along the second direction D2 may substantially overlap.

The second contact region 122 may be aligned with the center of the second well 124. The width of the second well 124 on the side surface of the second contact region 122 close to the first node region 110 may be substantially the same as the width of the second well 124 on the side surface of the second contact region 122 far from the first node region 110. For example, the central portions of the second contact region 122 and the second well 124 extending along the second direction D2 may substantially overlap.

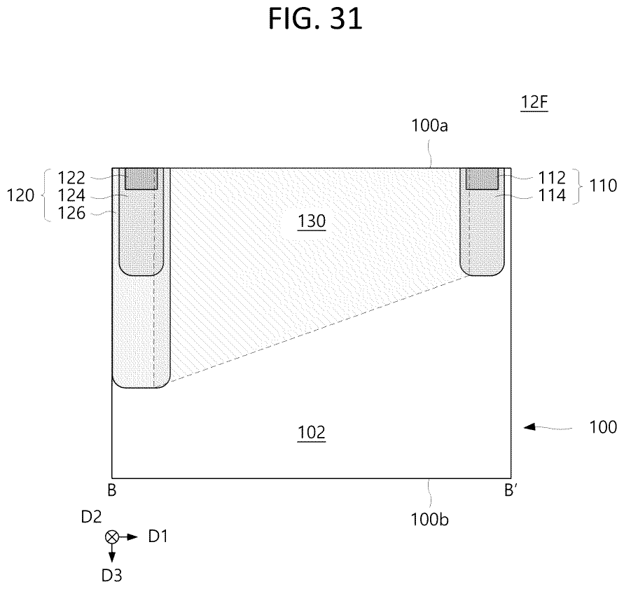

FIGS. 31 to 37 are cross-sectional views of photodetection elements according to some example embodiments corresponding to line B-B′ in FIG. 23. For brevity of explanation, differences from those described with reference to FIGS. 23 and 24 are explained.

Referring to FIG. 31, a photodetection element 12F may be provided. Unlike those described with reference to FIGS. 23 and 24, the first node region 110 may not include the first deep well 116. The first node region 110 may include the first contact region 112 and the first well 114. The first well 114 may be in contact with the substrate region 102. The first node region 110 may be formed to a depth closer to the frontside surface 100a than the second node region 120. That is, the first node region 110 may be formed at a different depth than the second node region 120. The bottom surface of the second node region 120, which is close to the backside surface 100b may be located at a different depth than the bottom surface of the first node region 110. For example, a portion of the second deep well 126 close to the backside surface 100b may be extended to a depth between the first node region 110 and the backside surface 100b.

The depletion region 130 may be formed from the frontside surface 100a to a level adjacent to the level of the bottom surface of the first node region 110 and the level of the bottom surface of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b than the level of the bottom surface of the first node region 110 from the frontside surface 100a and the level of the bottom surface of the second node region 120.

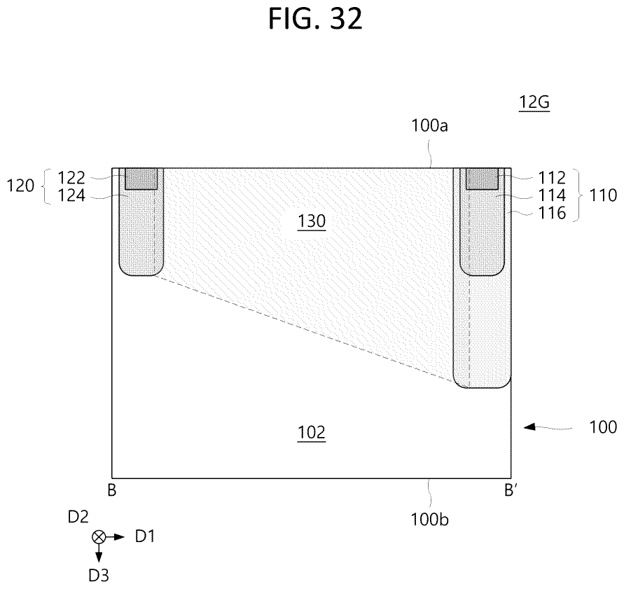

Referring to FIG. 32, a photodetection element 12G may be provided. Unlike those described with reference to FIGS. 23 and 24, the second node region 120 may not include the second deep well 126. The second node region 120 may include the second contact region 122 and the second well 124. The second well 124 may be in contact with the substrate region 102. The second node region 120 may be formed to a depth closer to the frontside surface 100a than the first node region 110. That is, the first node region 110 may be formed at a different depth than the second node region 120. The bottom surface of the first node region 110, which is close to the backside surface 100b may be located at a different depth than the bottom surface of the second node region 120. For example, a portion of the first deep well 116 close to the backside surface 100b may be extended to a depth between the second node region 120 and the backside surface 100b.

The depletion region 130 may be formed from the frontside surface 100a to a level adjacent to the level of the bottom surface of the first node region 110 and the level of the bottom surface of the second node region 120. In some example embodiments, the depletion region 130 may be formed from the frontside surface 100a to a level substantially the same as the bottom surface of the first node region 110 and the bottom surface of the second node region 120. In some example embodiments, the depletion region 130 may be formed from the frontside surface 100a to a level adjacent to the backside surface 100b than the level of the bottom surface of the first node region 110 and the level of the bottom surface of the second node region 120.

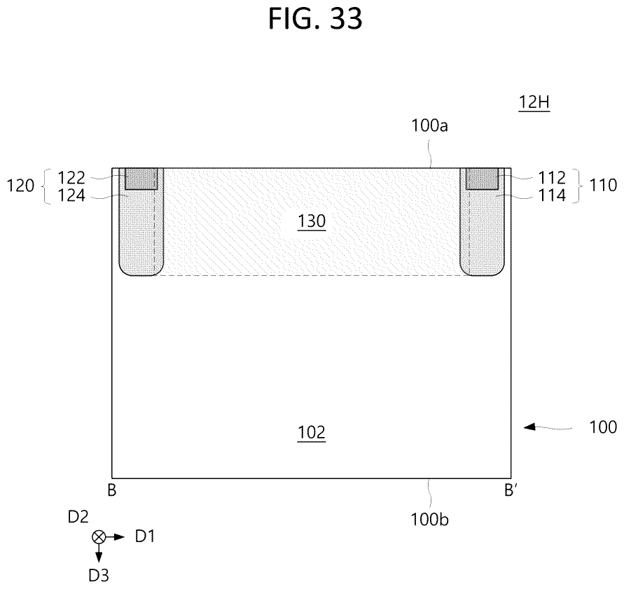

Referring to FIG. 33, a photodetection element 12H may be provided. Unlike those described with reference to FIGS. 23 and 24, the first node region 110 and the second node region 120 may not include the first deep well 116 and the second deep well 126, respectively. The first node region 110 may include the first contact region 112 and the first well 114. The second node region 120 may include the second contact region 122 and the second well 124. The first well 114 and the second well 124 may be in contact with the substrate region 102.

The depletion region 130 may be formed from the frontside surface 100a to a depth adjacent to the bottom surface of the first well 114 and the bottom surface of the second well 124 close to the backside surface 100b. The depletion region 130 may overlap a portion of the first contact region 112 and a portion of the first well 114 close to the second node region 120. The depletion region 130 may overlap a portion of the second contact region 122 and a portion of the second well 124 close to the first node region 110.

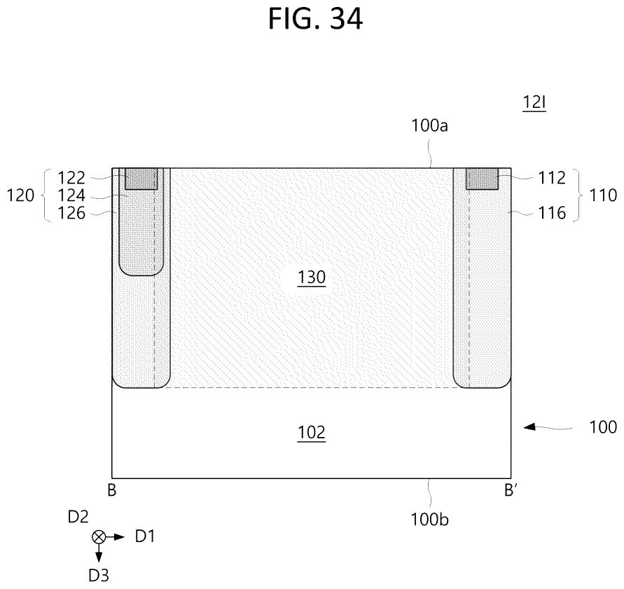

Referring to FIG. 34, a photodetection element 12I may be provided. Unlike those described with reference to FIGS. 23 and 24, the first node region 110 may not include the first well 114. In some example embodiments, the depletion region 130 may overlap a portion of the first contact region 112 adjacent to the second node region 120 and a portion of the first deep well 116. In some example embodiments, the depletion region 130 may include a portion of the second contact region 122, a portion of the second well 124, and a portion of the second deep well 126 adjacent to the first node region 110.

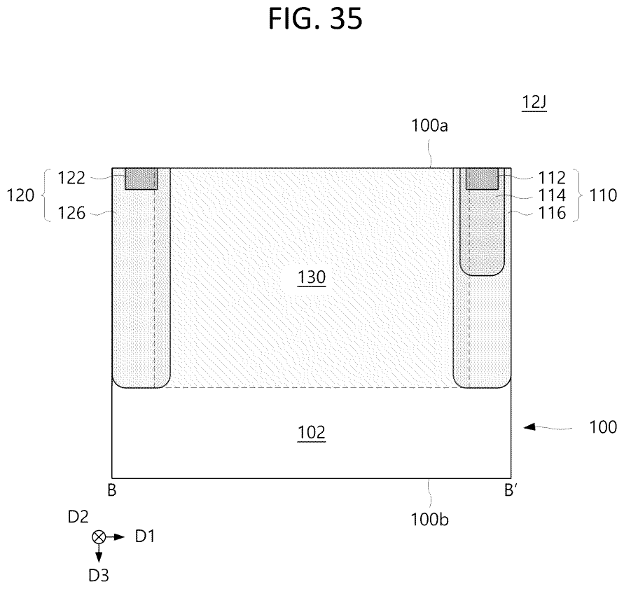

Referring to FIG. 35, a photodetection element 12J may be provided. Unlike those described with reference to FIGS. 23 and 24, the second node region 120 may not include the second well 124. In some example embodiments, the depletion region 130 may overlap a portion of the first contact region 112, a portion of the first well 114, and a portion of the first deep well 116 adjacent to the second node region 120. In some example embodiments, the depletion region 130 may overlap a portion of the second contact region 122 and a portion of the second deep well 126 adjacent to the first node region 110.

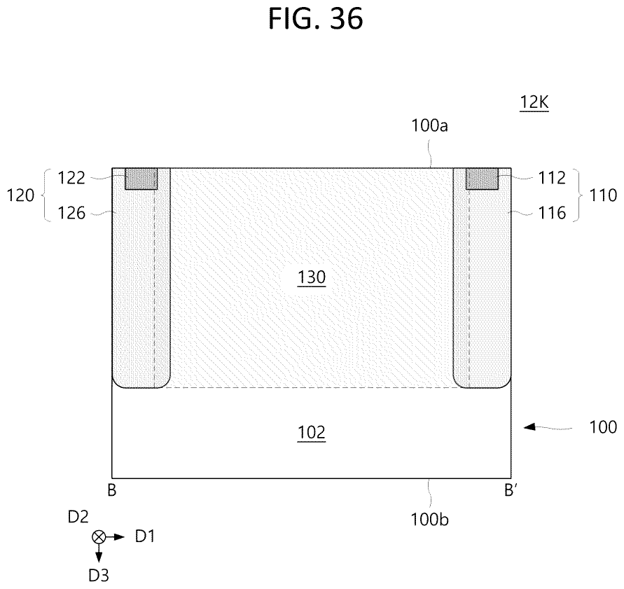

Referring to FIG. 36, a photodetection element 12K may be provided. Unlike those described with reference to FIGS. 23 and 24, the first node region 110 and the second node region 120 may not include the first well 114 and the second well 124, respectively. In some example embodiments, the depletion region 130 may overlap a portion of the first contact region 112 and a portion of the first deep well 116 adjacent to the second node region 120. In some example embodiments, the depletion region 130 may overlap a portion of the second contact region 122 and a portion of the second deep well 126 adjacent to the first node region 110.

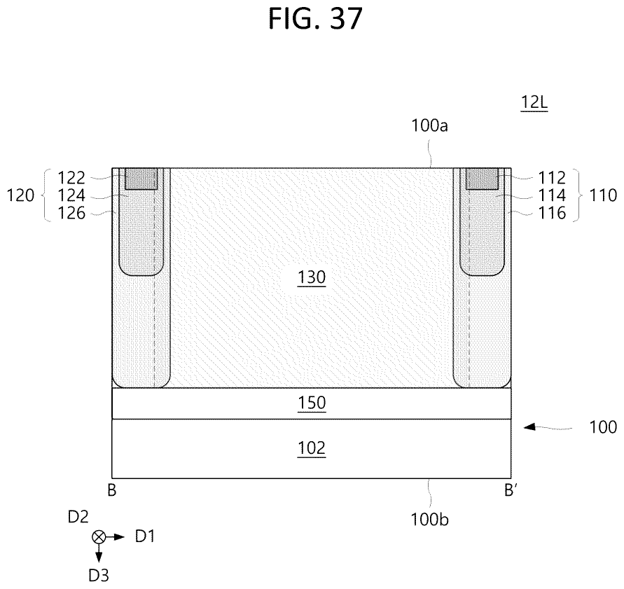

Referring to FIG. 37, a photodetection element 12L may be provided. Unlike those described with reference to FIGS. 23 and 24, the photodetection element 12L may further include a buried insulating layer 150. The buried insulating layer 150 may be provided between the first node region 110, the second node region 120, and the backside surface 100b. The buried insulating layer 150 may be extended along a direction parallel to the frontside surface 100a and cross the substrate 100. In some example embodiments, the buried insulating layer 150 may be in contact with the first node region 110 and the second node region 120. For example, the buried insulating layer 150 may be in contact with a lower portion of the first deep well 116 and a lower portion of the second deep well 126. The buried insulating layer 150 may include an electrically insulating material. For example, the buried insulating layer 150 may include silicon oxide (e.g., SiO₂). The buried insulating layer 150 may improve the yield characteristics of the photodetection element 12L. Specifically, the buried insulating layer 150 may alleviate a concentration of an electric field in a portion of the depletion region 130 and prevent premature breakdown. The buried insulating layer 150 may improve the leakage current characteristics of the photodetection element 12L. The buried insulating layer 150 may improve the crosstalk phenomenon of the photodetection element 12L. When the conductivity type of the substrate 100 is p-type, the buried insulating layer 150 may separate an anode of the photodetection element 12L from the substrate region 102. When the conductivity type of the substrate 100 is n-type, the buried insulating layer 150 may separate a cathode of the photodetection element 12L from the substrate region 102. This can make the implementation and operation of the circuit easier. The buried insulating layer 150 may serve to reflect incident light, and thus the photodetection element 12L of the inventive concepts may have improved photodetection efficiency and a wider wavelength range for photodetection.

In some example embodiments, the first node region 110 and the second node region 120 may be configured in various ways. For example, as illustrated in FIG. 31, the first node region 110 may not include the first deep well 116. For example, as illustrated in FIG. 32, the second node region 120 may not include the second deep well 126. For example, as illustrated in FIG. 33, the first node region 110 and the second node region 120 may not include the first deep well 116 and the second deep well 126, respectively. For example, as illustrated in FIG. 34, the first node region 110 may not include the first well 114. For example, as illustrated in FIG. 35, the second node region 120 may not include the second well 124. For example, as illustrated in FIG. 36, the first node region 110 and the second node region 120 may not include the first well 114 and the second well 124, respectively.

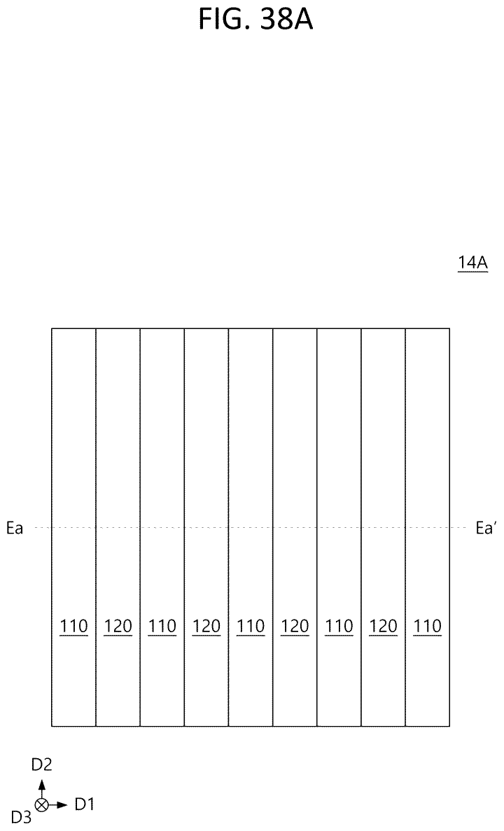

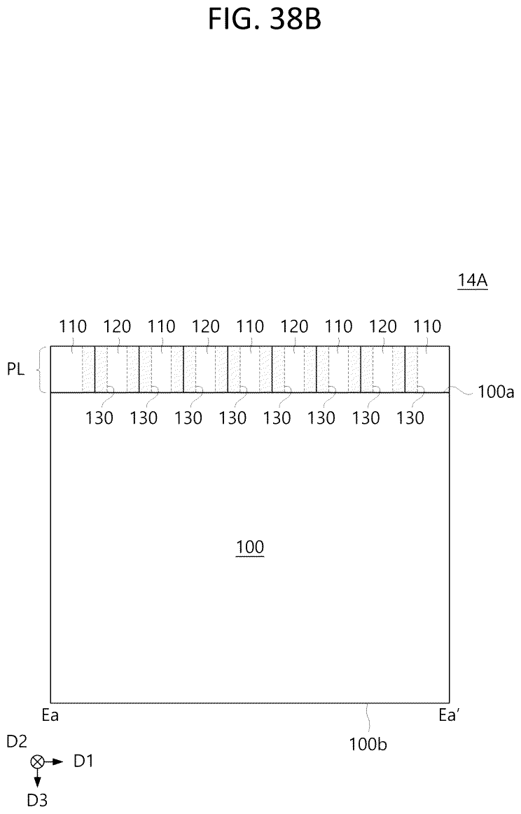

FIG. 38A is a plan view of a photodetection element according to some example embodiments. FIG. 38B is a cross-sectional view according to some example embodiments corresponding to line Ea-Ea′ of the photodetection element of FIG. 38A. For brevity of explanation, content substantially the same as that described with reference to FIGS. 1 and 2 may not be described.

Referring to FIGS. 38A and 38B, a photodetection element 14A may be provided. The photodetection element 14A may include a substrate 100 and a polysilicon layer PL. The substrate 100 may be substantially the same as the substrate 100 described with reference to FIGS. 1 and 2.

The polysilicon layer PL may include first node regions 110 and second node regions 120. The first node regions 110 may be n-type polysilicon regions. The second node regions 120 may be p-type polysilicon regions. The first node regions 110 and the second node regions 120 may be extended along the second direction D2. The first node regions 110 and the second node regions 120 may be alternately arranged along the first direction D1. The first node regions 110 and the second node regions 120 that are immediately adjacent to each other may be in contact with each other.

When a photodetection signal is output from the first node regions 110, a bias voltage may be applied to the second node regions 120. When the bias voltage is applied to the first node regions 110, the photodetection signal may be output from the second node regions 120. In some example embodiments, regions where the bias voltage is applied among the first node regions 110 and the second node regions 120 may be electrically connected to at least one of an external power source, a DC-DC converter, and other power management integrated circuits. In some example embodiments, regions where the photodetection signal is output among the first node regions 110 and the second node regions 120 may be electrically connected to at least one of a quenching resistor (or a quenching circuit) and other pixel circuits. The quenching resistor (or the quenching circuit) can stop the avalanche effect and allow the photodetection element 14A to detect other photons. Other pixel circuits may include, for example, a reset or recharge circuit, a memory, an amplifier circuit, a counter, a gate circuit, a time-to-digital converter, and the like. Other pixel circuits may transmit signals to the photodetection element 14A or receive signals from the photodetection element 14A.

Depletion regions 130 may be formed between the first node regions 110 and the second node regions 120 that are immediately adjacent to each other. The depletion regions 130 may overlap the first node regions 110 and the second node regions 120. When the photodetection device 14A is operated, a voltage difference may be occurred between the first node regions 110 and the second node regions 120. The voltage difference between the first node regions 110 and the second node regions 120 may be determined that the depletion region 130 has an electric field of 3×10⁵ V/cm or more. The depletion region 130 with the electric field of 3×10⁵ V/cm or more may be referred to as an avalanche multiplication region. The avalanche multiplication region may be configured to avalanche multiply the charge generated by incident photons. When the photodetection element 14A is operated, the avalanche multiplication region may be formed in the depletion region 130.

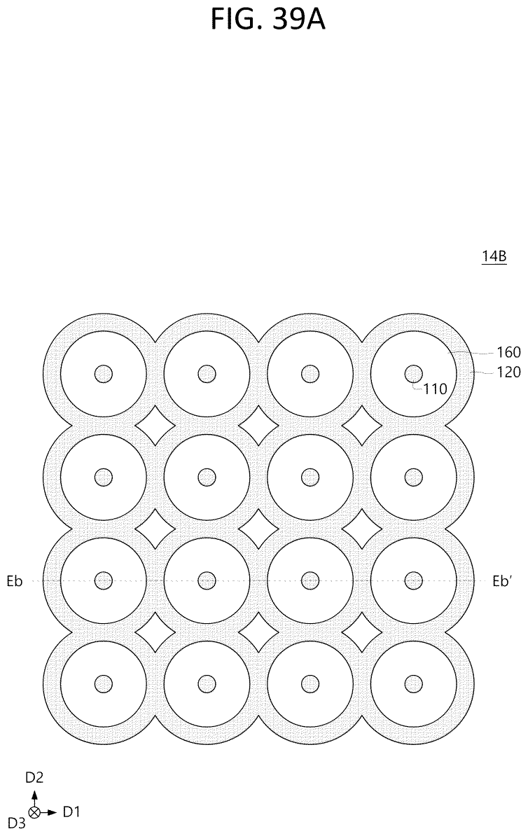

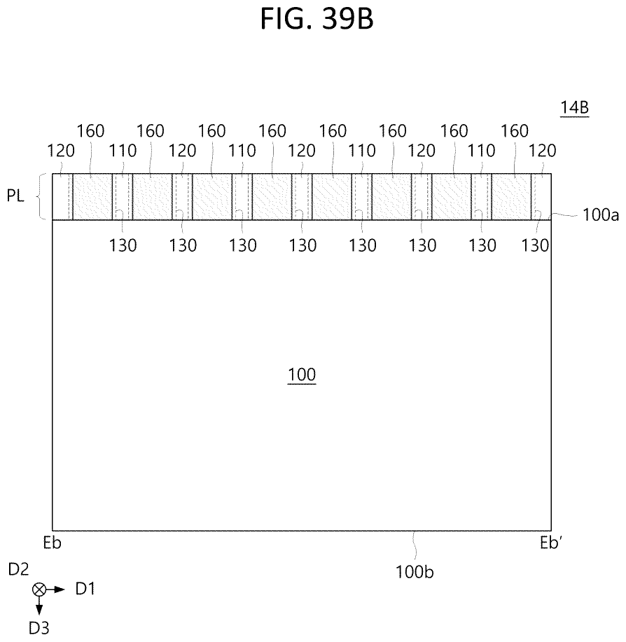

FIG. 39A is a plan view of a photodetection element according to some example embodiments. FIG. 39B is a cross-sectional view according to some example embodiments corresponding to line Eb-Eb′ of the photodetection element of FIG. 39A. For brevity of explanation, content substantially the same as that described with reference to FIGS. 1 and 2 may not be described.

Referring to FIGS. 39A and 39B, a photodetection element 14B may be provided. The photodetection element 14B may include a substrate 100 and a polysilicon layer PL. The substrate 100 may be substantially the same as the substrate 100 described with reference to FIGS. 1 and 2.

The polysilicon layer PL may include first node regions 110, second node regions 120, and intrinsic regions 160. The first node regions 110 may be n-type polysilicon regions. The first node regions 110 may be arranged along the first direction D1 and the second direction D2. For example, the space between the first node regions 110 may be constant.

The second node regions 120 may be p-type polysilicon regions. The second node regions 120 may surround the first node regions 110, respectively. The second node regions 120 may have ring shapes connected to each other. In some example embodiments, the first node regions 110 may be located at centers of the second node regions 120, respectively. In some example embodiments, the first node regions 110 may be shifted from the centers of the second node regions 120, respectively. For example, the second node regions 120 are illustrated to have a circular ring shape. The shape of the second node regions 120 may be determined as needed. In some example embodiments, the second node regions 120 may have a square ring shape, a square ring shape with rounded corners, a rectangular ring shape, a rectangular ring shape with rounded corners, an elliptical ring shape, or an octagonal ring shape.

The intrinsic regions 160 may be intrinsic polysilicon regions. The first node regions 110 may be spaced apart from the second node regions 120 by the intrinsic regions 160.

When a bias voltage is applied to the first node regions 110, a photodetection signal may be output from the second node regions 120. When the photodetection signal is output from the first node regions 110, the bias voltage may be applied to the second node regions 120. In some example embodiments, a region that the bias voltage is applied among the first node regions 110 and the second node regions 120 may be electrically connected to at least one of an external power source, a DC-DC converter, and other power management integrated circuit. In some example embodiments, a region that the photodetection signal is output among the first node regions 110 and the second node regions 120 may be electrically connected to at least one of a quenching resistor (or a quenching circuit) and other pixel circuits.

Depletion regions 130 may be formed between the first node regions 110 and the second node regions 120. The depletion regions 130 may overlap the second node regions 120 and the first node regions 110. When the photodetection element 14B is operated, a voltage difference may be occurred between the first node region 110 and the second node region 120 that are adjacent to each other. The voltage difference between the first node region 110 and the second node region 120 may be determined that the depletion region 130 has an electric field of 3×10⁵ V/cm or more. When the photodetection element 14B is operated, avalanche multiplication regions may be formed in the depletion regions 130.

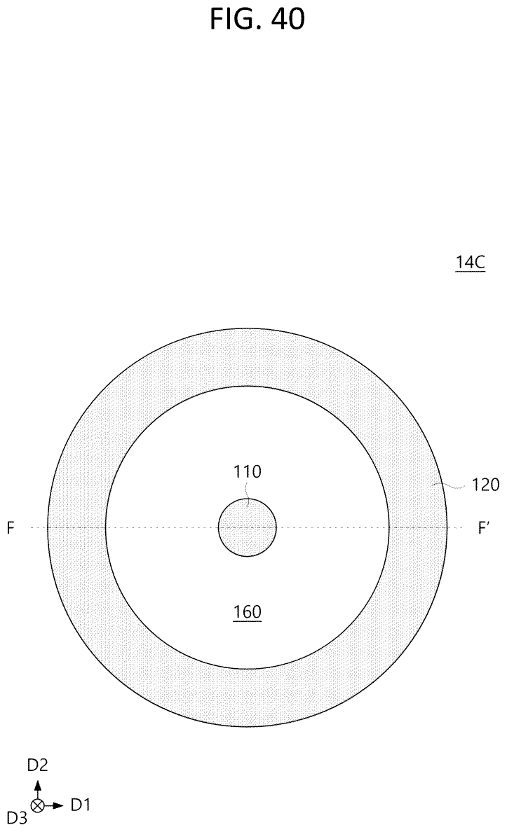

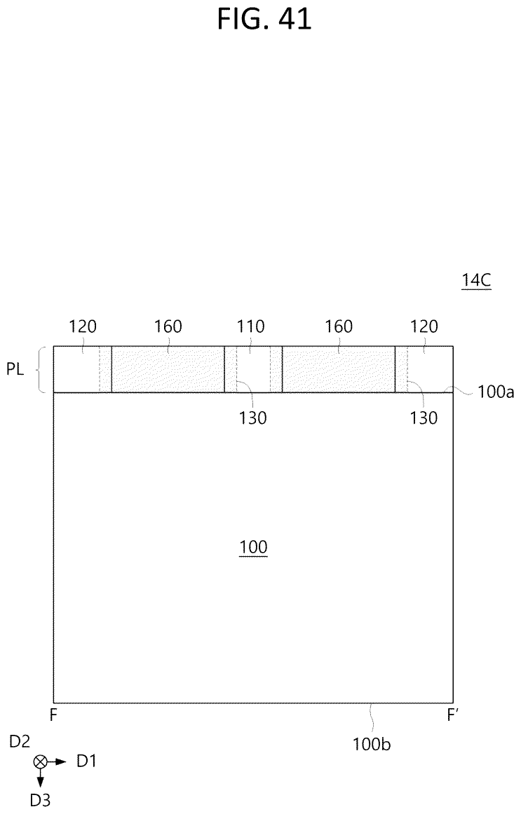

FIG. 40 is a plan view of a photodetection element according to some example embodiments. FIG. 41 is a cross-sectional view corresponding to line F-F′ of the photodetection element of FIG. 40 according to some example embodiments. For brevity of explanation, content that is substantially the same as that described with reference to FIGS. 1 and 2 may not be described.

Referring to FIGS. 40 and 41, a photodetection element 14C may be provided. The photodetection element 14C may include a substrate 100 and a polysilicon layer PL. The substrate 100 may be substantially the same as the substrate 100 described with reference to FIGS. 1 and 2.

The polysilicon layer PL may include a first node region 110, a second node region 120, and an intrinsic region 160. The first node region 110 may be an n-type polysilicon region. The second node region 120 may be a p-type polysilicon region. The intrinsic region 160 may be an intrinsic polysilicon region. The first node region 110 may be spaced apart from the second node region 120 by the intrinsic region 160. The first node region 110 may be surrounded by the second node region 120. In some example embodiments, the first node region 110 may be configured to be located at a center of the second node region 120. In some example embodiments, the first node region 110 may be configured to be located shifted from the center of the second node region 120. In some example embodiments, the first node region 110 is illustrated to have a circular shape. The shape of the first node region 110 may be determined as needed. In some example embodiments, the first node region 110 may have a square shape, a square shape with rounded corners, a rectangular shape, a rectangular shape with rounded corners, an elliptical shape, or an octagonal shape.

The second node region 120 may have a ring shape surrounding the first node region 110. In some example embodiments, the second node region 120 is illustrated to have a circular ring shape. The shape of the second node region 120 may be determined as needed. In some example embodiments, the second node region 120 may have a square ring shape, a square ring shape with rounded corners, a rectangular ring shape, a rectangular ring shape with rounded corners, an elliptical ring shape, or an octagonal ring shape.

When a bias voltage is applied to the first node region 110, a photodetection signal may be output from the second node region 120. When the photodetection signal is output from the first node region 110, the bias voltage may be applied to the second node region 120. In some example embodiments, a region that the bias voltage is applied among the first node region 110 and the second node region 120 may be electrically connected to at least one of an external power source, a DC-DC converter, and other power management integrated circuits. In some example embodiments, a region that the photodetection signal is output among the first node region 110 and the second node region 120 may be electrically connected to at least one of a quenching resistor (or a quenching circuit) and other pixel circuits.

The depletion region 130 may be formed between the first node region 110 and the second node region 120. The depletion region 130 may overlap the second node region 120 and the first node region 110. When the photodetection element 14C is operated, a voltage difference may be occurred between the first node region 110 and the second node region 120. The voltage difference between the first node region 110 and the second node region 120 may be determined such that the depletion region 130 has an electric field of 3×10⁵ V/cm or more. When the photodetection element 14C is operated, an avalanche multiplication region may be formed in the depletion region 130.

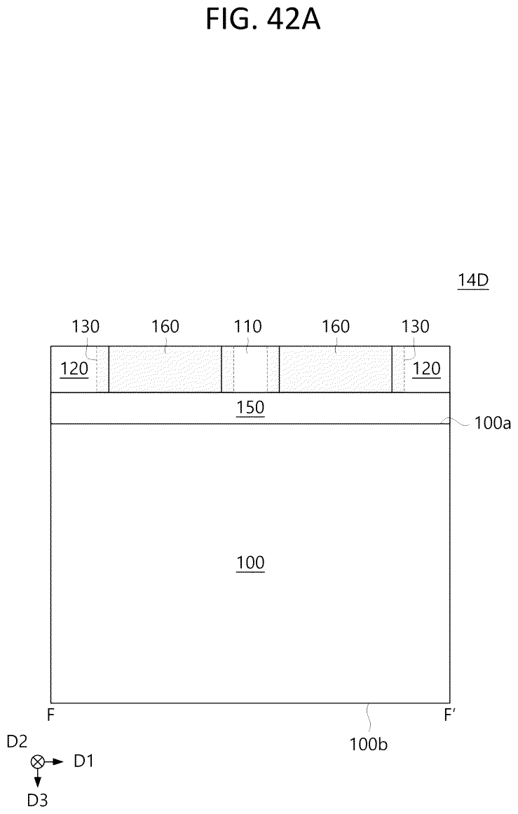

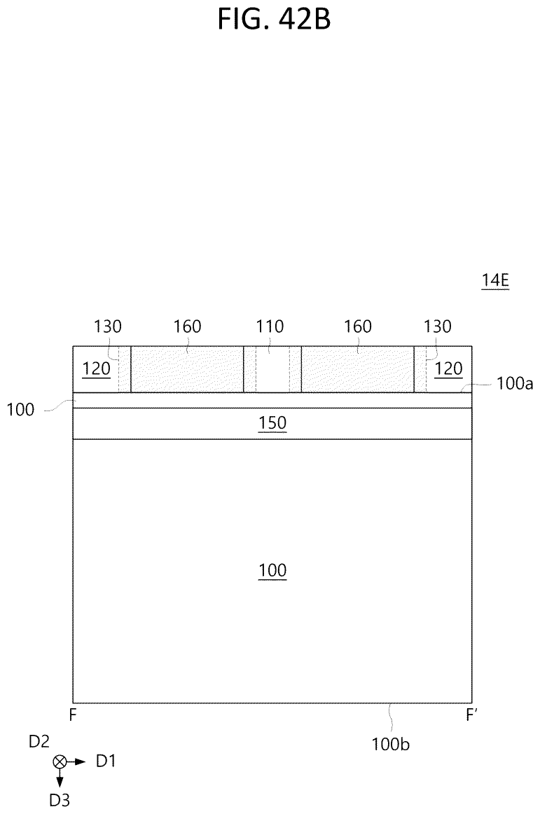

FIGS. 42A and 42B are cross-sectional views of photodetection elements according to some example embodiments corresponding to line F-F′ in FIG. 40. For brevity of explanation, differences from those described with reference to FIGS. 40 and 41 are explained.

Referring to FIGS. 42A and 42B, unlike those described with reference to FIGS. 40 and 41, the photodetection element 14D may further include a buried insulating layer 150. The buried insulating layer 150 may be provided between the first and second node regions 110, 120 and the substrate region 102. The buried insulating layer 150 may be extended along a direction parallel to the frontside surface 100a. In some example embodiments, the buried insulating layer 150 may be in contact with the first node region 110 and the second node region 120. The buried insulating layer 150 may include an electrically insulating material. For example, the buried insulating layer 150 may include silicon oxide (e.g., SiO₂). The buried insulating layer 150 may improve the yield characteristics of the photodetection element 14D. Specifically, the buried insulating layer 150 may alleviate a concentration of an electric field in a portion of the depletion region 130 and prevent premature breakdown. The buried insulating layer 150 may improve the leakage current characteristics of the photodetection element 14D. The buried insulating layer 150 may improve the crosstalk phenomenon of the photodetection element 14D. When the conductivity type of the substrate 100 is p-type, the buried insulating layer 150 may separate an anode of the photodetection element 14D from the substrate 100. When the conductivity type of the substrate 100 is n-type, the buried insulating layer 150 may separate a cathode of the photodetection element 14D from the substrate 100. This can make the implementation and operation of the circuit easier. The buried insulating layer 150 may serve to reflect incident light, and thus the photodetection element 14D of the inventive concepts may have improved photodetection efficiency and a wider wavelength range for photodetection.

Referring to FIG. 42B, unlike FIG. 42A, the buried insulating layer 150 may be spaced apart from the first node region 110, the second node region 120, and the intrinsic region 160. For brevity of explanation, differences from those described with reference to FIG. 42A are explained. The substrate region 102 may be disposed between the buried insulating layer 150 and the first node region 110, the second node region 120, and the intrinsic region 160.

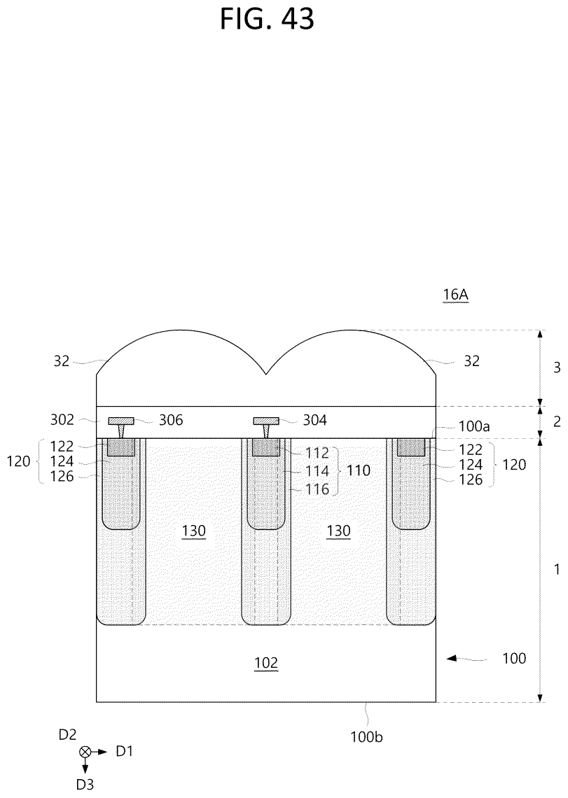

FIGS. 43 to 55A are cross-sectional views of photodetectors according to some example embodiments. For brevity of explanation, content substantially the same as that described with reference to FIGS. 1 and 2 may not be described.

Referring to FIG. 43, a photodetector 16A may be provided. In some example embodiments, the photodetector 16A may constitute one pixel in an image sensor including the photodetector 16A. The photodetector 16A may include a photodetector device layer 1, a connection layer 2, and a lens layer 3. In some example embodiments, the photodetection element layer 1 may include the photodetection element 10A described with reference to FIGS. 1 and 2. In some example embodiments, the photodetection device layer 1 may include any one of the photodetection elements 10A to 10Q described with reference to FIGS. 3 to 22C and the photodetection elements 14B to 14E described with reference to FIGS. 40 to 42B instead of the photodetection element 10A described with reference to FIGS. 1 and 2.

The connection layer 2 may be provided on the frontside surface 100a. The connection layer 2 may include an insulating layer 302, a first conductive line 304, and a second conductive line 306. The insulating layer 302 may include an electrically insulating material. For example, the insulating layer 302 may include silicon oxide (e.g., SiO₂), silicon nitride (e.g., SiN), silicon oxynitride (e.g., SiON), aluminum oxide (e.g., Al₂O₃), hafnium oxide (e.g., HfO₂), or a combination thereof.

The first conductive line 304 may be electrically connected to the first contact region 112. The first conductive line 304 may include an electrically conductive material. For example, the first conductive line 304 may include copper (Cu), aluminum (Al), tungsten (W), titanium (Ti), titanium nitride (TiN), or a combination thereof. In some example embodiments, the first conductive line 304 may be configured to apply a bias voltage to the first contact region 112. For example, the first conductive line 304 may be electrically connected to at least one of an external power source, a DC-DC converter, and other power management integrated circuit. In some example embodiments, the first conductive line 304 may be configured to receive a photodetection signal output from the first contact region 112. For example, the first conductive line 304 may be electrically connected to at least one of a quenching resistor (or a quenching circuit) and other pixel circuit.

The second conductive line 306 may be electrically connected to the second contact region 122. The second conductive line 306 may include an electrically conductive material. For example, the second conductive line 306 may include copper (Cu), aluminum (Al), tungsten (W), titanium (Ti), titanium nitride (TiN), or a combination thereof. When the first conductive line 304 is configured to apply a bias voltage to the first contact region 112, the second conductive line 306 may be configured to receive a photodetection signal output from the second contact region 122. For example, the second conductive line 306 may be electrically connected to at least one of an external power source, a DC-DC converter, and other power management integrated circuit. In some example embodiments, when the first conductive line 304 is configured to receive a photodetection signal output from the first contact region 112, the second conductive line 306 may be configured to apply a bias voltage to the first contact region 112. For example, the second conductive line 306 may be electrically connected to at least one of a quenching resistor (or a quenching circuit) and other pixel circuit. In some example embodiments, electronic elements and circuits (not illustrated) electrically connected to the first conductive line 304 and the second conductive line 306 may be located around the photodetection element layer 1.

The lens layer 3 may be provided on the connection layer 2. The lens layer 3 may include lenses 32. The lenses 32 may focus the incident light and transmit it to the photodetection element layer 1. For example, the lenses 32 may include a microlens, a fresnel lens, or a metalens. The lenses 32 may be configured to focus incident light onto the avalanche multiplication region. Optical axes of the lenses 32 may be configured to overlap the depletion region 130. The optical axes of the lenses 32 may be configured to be shifted from a central axis of the depletion region 130. In some example embodiments, the lenses 32 may have the required number and arrangement to focus incident light onto the depletion region 130. For example, the lenses 32 may be arranged in a 2×2 shape along a direction parallel to the frontside surface 100a. For example, an outer side surface of the lenses 32 may be formed at the same location as an outer side surface of the second deep well 126. For example, the outer side surface of the lenses 32 may be formed more outer than the outer side surface of the second deep well 126. For example, the outer side surface of the lenses 32 may be formed inside the second deep well 126 rather than the outer side. For example, the outer side surfaces of the lenses 32 may be formed at the same location as a central axis of the second deep well 126. For example, the lenses 32 may be configured to be shifted from a center of the photodetection element layer 1. As incident light is prevented from being focused on regions other than the depletion region 130, the photodetector 16A that prevents a decrease in photodetection efficiency may be provided. In some example embodiments, at least one optical element may be inserted between the lens 32 and the photodetection element layer 1. For example, the optical elements may be a color filter, a bandpass filter, a metal grid, an air grid, a grid based on low refractive index materials, an anti-reflective coating, a passivation (aluminum oxide (e.g., Al₂O₃), hafnium oxide (e.g., HfO₂), etc.), a 2D nanomaterial layer, or an organic material layer. In some example embodiments, the anti-reflective coating may be formed on the lenses 32. The lens layer 3 may be referred to as an optical element layer.

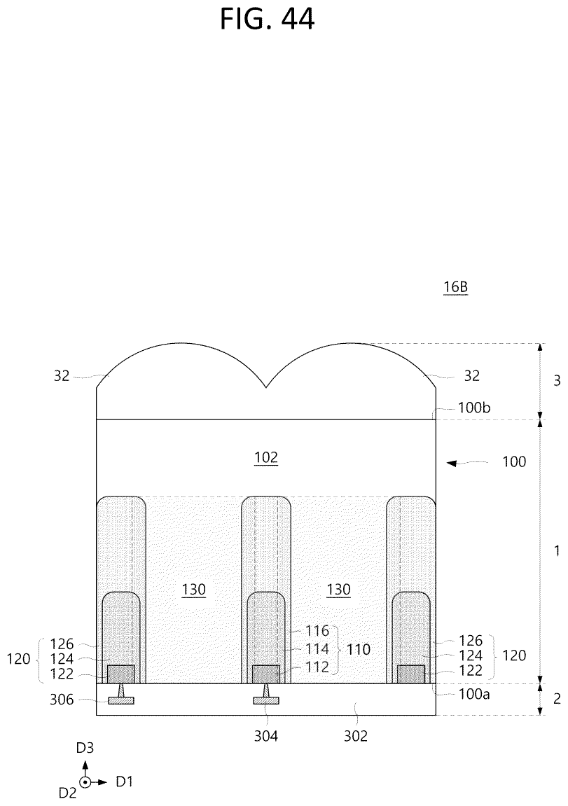

Referring to FIG. 44, a photodetector 16B may be provided. For brevity of explanation, differences from those described with reference to FIG. 43 may be explained. The photodetector 16B may include the photodetector device layer 1, the connection layer 2, and the lens layer 3. Unlike those illustrated in FIG. 43, the photodetector 16B is illustrated that the frontside surface 100a and the backside surface 100b of the substrate 100 may be located at a bottom surface and a top surface, respectively. The photodetection element layer 1 and the connection layer 2 may be substantially the same as the photodetection element layer 1 and the connection layer 2 described with reference to FIG. 43.

The lens layer 3 may be provided on the backside surface 100b of the substrate 100. Light may be incident on the backside surface 100b. The photodetector 16B may use a backside illumination (BSI) method. The lens layer 3 may be substantially the same as the lens layer 3 described with reference to FIGS. 42 and 43 except for its location. In some example embodiments, at least one optical element may be inserted between the lens 32 and the photodetection element layer 1. For example, the optical elements may be a color filter, a bandpass filter, a metal grid, an air grid, a grid based on low refractive index materials, an anti-reflective coating, a passivation (aluminum oxide (e.g., Al₂O₃), hafnium oxide (e.g., HfO₂), etc.), a 2D nanomaterial layer, or an organic material layer. In some example embodiments, the anti-reflective coating may be formed on the lenses 32.

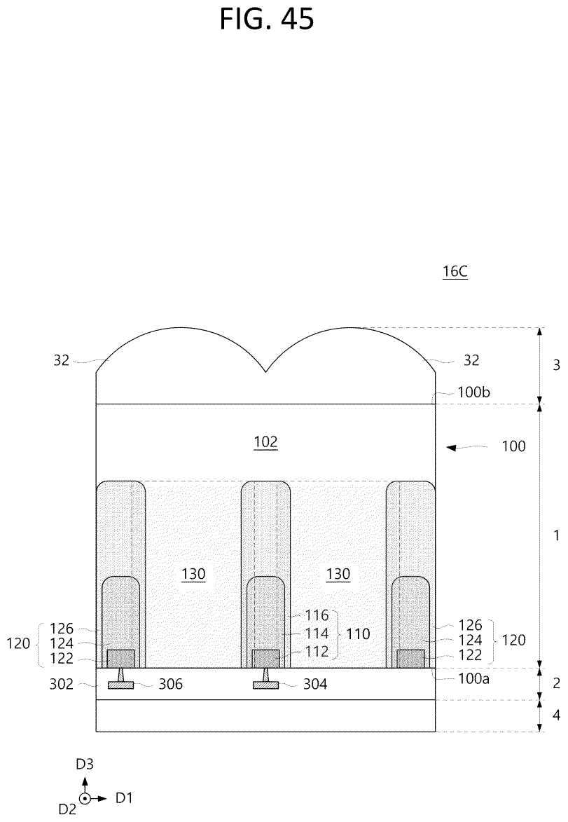

Referring to FIG. 45, a photodetector 16C may be provided. For brevity of explanation, differences from those described with reference to FIG. 43 may be explained. The photodetector 16C may include a photodetector device layer 1, a connection layer 2, a lens layer 3, and a control layer 4. Unlike those illustrated in FIG. 43, the photodetector 16C is illustrated that the frontside surface 100a and the backside surface 100b of the substrate 100 may be located at a bottom surface and a top surface, respectively. The photodetection element layer 1 and the connection layer 2 may be substantially the same as the photodetection element layer 1 and the connection layer 2 described with reference to FIG. 43.

The lens layer 3 may be provided on the backside surface 100b of the substrate 100. Light may be incident on the backside surface 100b. The photodetector 16C may use a backside illumination method. The lens layer 3 may be substantially the same as the lens layer 3 described with reference to FIG. 43 except for its location.

The control layer 4 may be provided on the frontside surface 100a of the substrate 100. The control layer 4 may be provided on the connection layer 2. The control layer 4 may be spaced apart from the photodetection element layer 1 with the connection layer 2 interposed therebetween. The control layer 4 may include the photodetection element layer 1 and circuits (hereinafter referred to as required circuits) required for the operation of the image sensor including the photodetection element layer 1. For example, the control layer 4 may be in a form of a stacked structure with a separate semiconductor chip on which the required circuits are formed. The photodetection element layer 1 and the separate semiconductor chip including the control layer 4 may be electrically connected through a through-silicon via (TSV) that passes from the backside surface 100b to the frontside surface 100a of the photodetection element layer 1. Additionally, the separate semiconductor chip including the control layer 4 and the first conductive line 304 or the second conductive line 306 of connection layer 2 may be electrically connected through the TSV.

The required circuits may be implemented by various electronic devices as needed. In some example embodiments, the required circuits may include a quenching resistor (or a quenching circuit) and a pixel circuit. The pixel circuit may be composed of a reset or recharge circuit, a memory, an amplifier circuit, a counter, a gate circuit, a time-to-digital converter, and the like. In some example embodiments, the required circuits may include a DC-DC converter and other power management integrated circuits. The required circuit may transmit a signal to the photodetection element layer 1 or receive a signal from the photodetection element layer 1.

Although not illustrated, the control layer 4 may be provided on the backside surface 100b in FIG. 43. The control layer 4 may include the photodetection element layer 1 and circuits (hereinafter referred to as required circuits) required for operation of the image sensor including the photodetection element layer 1. For example, the control layer 4 may be in a form of a stacked structure with a separate semiconductor chip on which the required circuits are formed. The photodetection element layer 1 and the separate semiconductor chip including the control layer 4 may be electrically connected through the TSV that passes from the frontside surface 100a to the backside surface 100b of the photodetection element layer 1. Additionally, the separate semiconductor chip including the control layer 4 and the first conductive line 304 or the second conductive line 306 of the photodetection element layer may be electrically connected through the TSV.

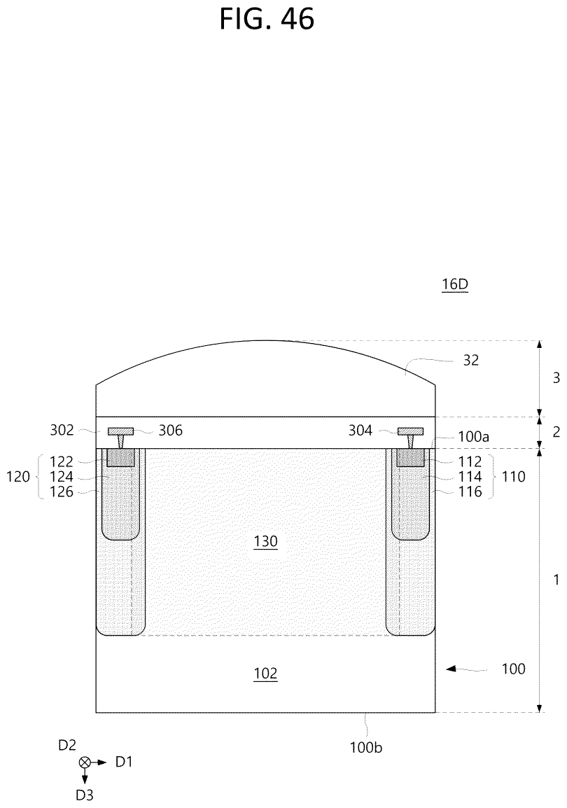

Referring to FIG. 46, a photodetector 16D may be provided. For brevity of explanation, content substantially the same as that described with reference to FIG. 43 may not be described. The photodetector 16A may include a photodetector device layer 1, a connection layer 2, and a lens layer 3. In some example embodiments, the photodetection element layer 1 may be substantially the same as the photodetection element 12A described with reference to FIGS. 23 and 24. In some example embodiments, the photodetection device layer 1 may include any one of the photodetection elements 12B to 12L described with reference to FIGS. 25 to 37 instead of the photodetection element 12A described with reference to FIGS. 23 and 24.

The connection layer 2 may be substantially the same as the connection layer 2 described with reference to FIG. 43.

The lens layer 3 may be provided on the connection layer 2. The lens layer 3 may include a lens 32. The lens 32 may focus the incident light and transmit it to the photodetection element layer 1. For example, the lens 32 may include a microlens, a Fresnel lens, or a metalens. The lens 32 may be configured to focus incident light on the depletion region 130. For example, the lens 32 may focus incident light on the central portion of the substrate 100 from a perspective along the third direction D3. An optical axis of the lens 32 may be configured to overlap the depletion region 130. The optical axis of the lens 32 may be configured to be shifted from a central axis of the depletion region 130. For example, an outer side surface of the lens 32 may be formed at the same location as an outer side surface of the first deep well 116 and the second deep well 126. For example, an outer side surface of the lens 32 may be formed more outer than the outer side surface of the first deep well 116 and the second deep well 126. For example, the outer side surface of the lens 32 may be formed more internally than the outer side surface of the first deep well 116 and the second deep well 126. For example, the outer side surface of the lens 32 may be formed at the same location as the central axis of the first deep well 116 and the second deep well 126. In some example embodiments, the lens layer 3 may include the lenses 32 as illustrated in FIG. 43. The lenses 32 may have the required number and arrangement form to focus incident light on the avalanche multiplication region.

In some example embodiments, an optical element may be inserted between the lens 32 and the photodetection element layer 1. For example, the optical elements may be a color filter, a bandpass filter, a metal grid, an air grid, a grid based on low refractive index materials, an anti-reflective coating, a 2D nanomaterial layer, or an organic material layer. In some example embodiments, the anti-reflective coating may be formed on lenses 32.

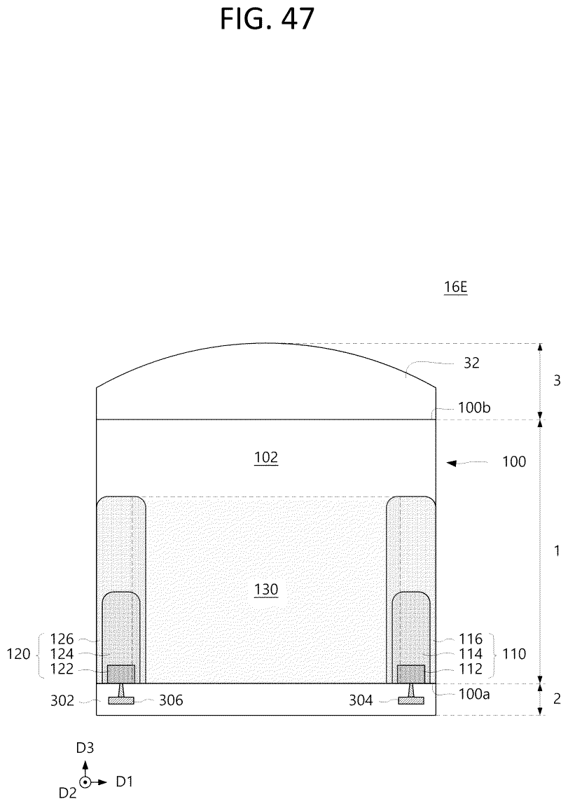

Referring to FIG. 47, a photodetector 16E may be provided. For brevity of explanation, differences from those described with reference to FIG. 46 may be explained. The photodetector 16E may include a photodetector device layer 1, a connection layer 2, and a lens layer 3. Unlike those illustrated in FIG. 46, the photodetector 16E is illustrated that the frontside surface 100a and the backside surface 100b of the substrate 100 may be located at a bottom surface and a top surface, respectively. The photodetection element layer 1 and the connection layer 2 may be substantially the same as the photodetection element layer 1 and the connection layer 2 described with reference to FIG. 46.

The lens layer 3 may be provided on the backside surface 100b of the substrate 100. Light may be incident on the backside surface 100b. The photodetector 16E may use a backside illumination method. The lens layer 3 may be substantially the same as the lens layer 3 described with reference to FIG. 46 except for its location.

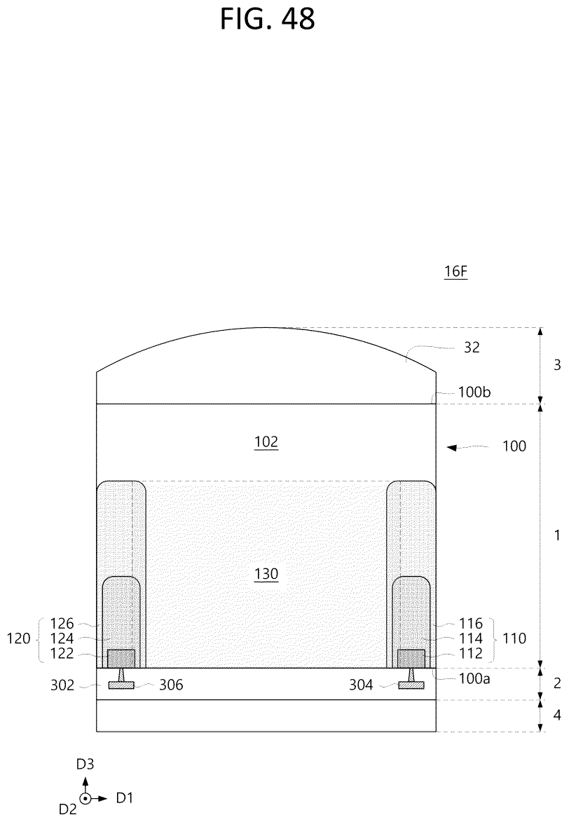

Referring to FIG. 48, a photodetector 16F may be provided. For brevity of explanation, differences from those described with reference to FIG. 46 may be explained. The photodetector 16F may include a photodetector device layer 1, a connection layer 2, a lens layer 3, and a control layer 4. Unlike those illustrated in FIG. 46, the photodetector 16F is illustrated that the frontside surface 100a and the backside surface 100b of the substrate 100 may be located at a bottom surface and a top surface, respectively. The photodetection element layer 1 and the connection layer 2 may be substantially the same as the photodetection element layer 1 and the connection layer 2 described with reference to FIG. 46.

The lens layer 3 may be provided on the backside surface 100b of the substrate 100. Light may be incident on the backside surface 100b. The photodetector 16F may use a backside illumination method. The lens layer 3 may be substantially the same as the lens layer 3 described with reference to FIG. 46 except for its location.

The control layer 4 may be provided on the connection layer 2. The control layer 4 may be provided on the frontside surface 100a of the substrate 100. The control layer 4 may include circuit necessary for the operation of the photodetection element layer 1. For example, the control layer 4 may be a chip on which the circuit necessary for the operation of the photodetection element layer 1 is formed. The circuit required for the operation of the photodetection element layer 1 (hereinafter referred to as a required circuit) may be implemented by various electronic devices as needed. In some example embodiments, the required circuit may include a quenching resistor (or a quenching circuit) and a pixel circuit. The pixel circuit may be composed of a reset or recharge circuit, a memory, an amplifier circuit, a counter, a gate circuit, a time-to-digital converter, and the like. In some example embodiments, the required circuit may include a DC-DC converter and other power management integrated circuits. The required circuit may transmit a signal to the photodetection element layer 1 or receive a signal from the photodetection element layer 1.

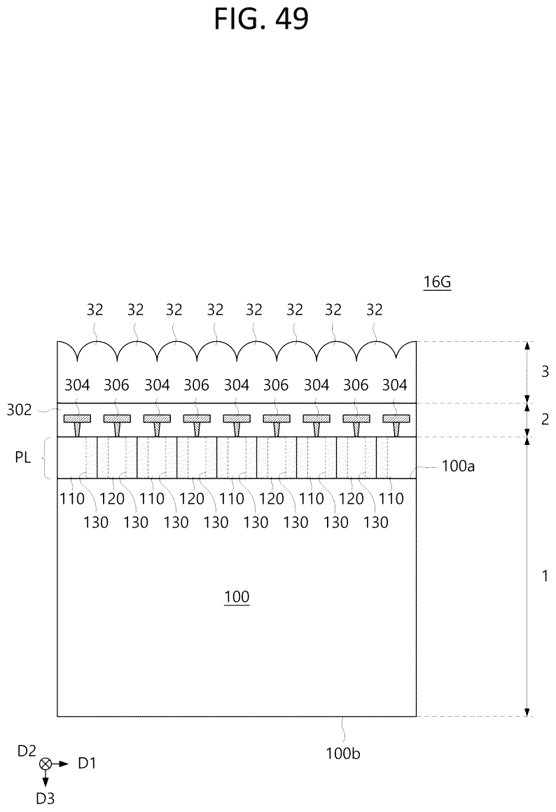

Referring to FIG. 49, a photodetector 16G may be provided. For brevity of explanation, content substantially the same as that described with reference to FIG. 43 may not be described. The photodetector 16G may include a photodetector device layer 1, a connection layer 2, and a lens layer 3. The photodetection element layer 1 may be substantially the same as the photodetection element 14A described with reference to FIGS. 38 and 39.

The connection layer 2 may include an insulating layer 302, first conductive lines 304, and second conductive lines 306. The insulating layer 302 may be substantially the same as the connection layer 2 described with reference to FIG. 43. The first conductive lines 304 may be electrically connected to the first node regions 110, respectively. For example, the first conductive lines 304 may be in contact with n-type polysilicon regions, respectively. The second conductive lines 306 may be electrically connected to the second node regions 120, respectively. For example, the second conductive lines 306 may be in contact with p-type polysilicon regions, respectively.

The lens layer 3 may be provided on the connection layer 2. The lens layer 3 may include lenses 32. The lenses 32 may focus the incident light and transmit it to the photodetection element layer 1. For example, the lenses 32 may include a microlens, a Fresnel lens, or a metalens. The lenses 32 may be configured to focus incident light onto the avalanche multiplication region. For example, optical axes of the lenses 32 may be configured to overlap the depletion regions 130, respectively. The optical axes of the lenses 32 may be configured to be located shifted from the central axis of the depletion regions 130. In some example embodiments, at least one optical element may be inserted between the lens 32 and the photodetection element layer 1. For example, the optical elements may include a color filter, a bandpass filter, a metal grid, an air grids, a grid based on low refractive index materials, an anti-reflective coating, a 2D nanomaterial layer, or an organic material layer. In some example embodiments, the anti-reflective coating may be formed on the lenses 32.

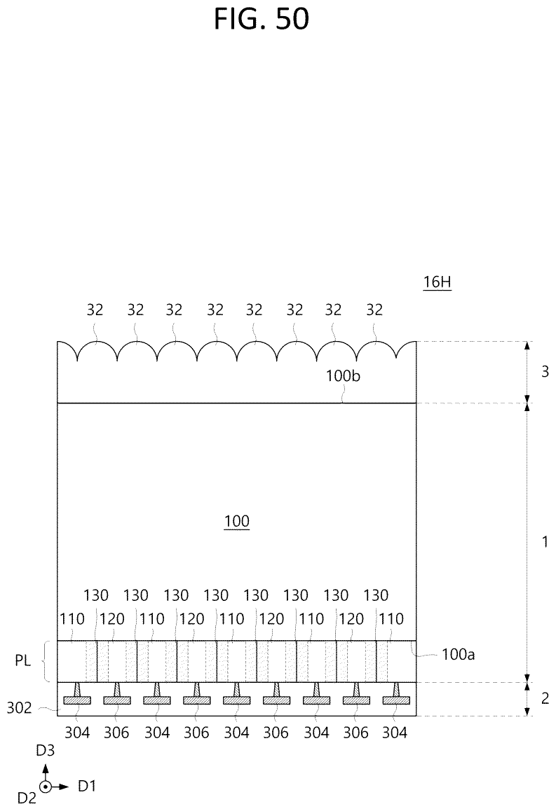

Referring to FIG. 50, a photodetector 16H may be provided. For brevity of explanation, differences from those described with reference to FIG. 49 may be explained. The photodetector 16H may include a photodetector device layer 1, a connection layer 2, and a lens layer 3. Unlike those illustrated in FIG. 49, the photodetector 16H is illustrated that the frontside surface 100a and the backside surface 100b of the substrate 100 may be located at a bottom surface and a top surface, respectively. The photodetection element layer 1 and the connection layer 2 may be substantially the same as the photodetection element layer 1 and the connection layer 2 described with reference to FIG. 49.

The lens layer 3 may be provided on the backside surface 100b of the substrate 100. Light may be incident on the backside surface 100b. The photodetector 16H may use a backside illumination method. The lens layer 3 may be substantially the same as the lens layer 3 described with reference to FIG. 49 except for its location.

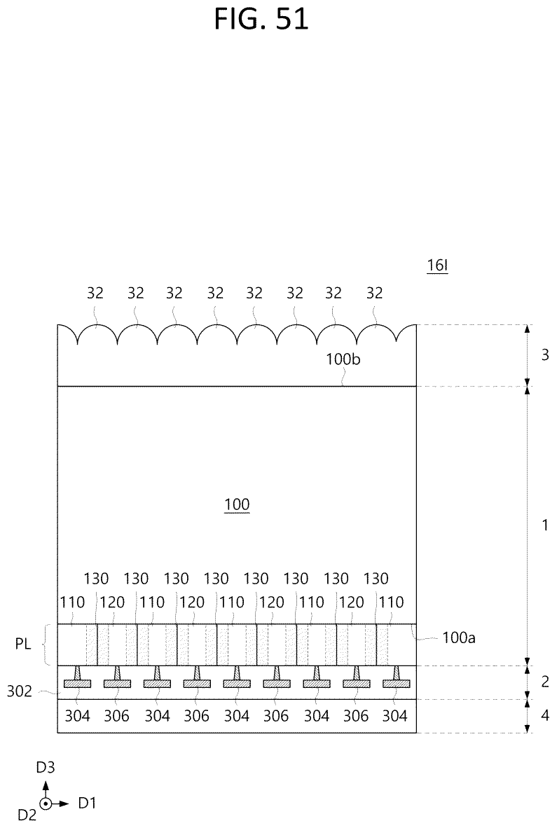

Referring to FIG. 51, a photodetector 16I may be provided. For brevity of explanation, differences from those described with reference to FIG. 49 may be explained. The photodetector 16I may include a photodetector device layer 1, a connection layer 2, a lens layer 3, and a control layer 4. Unlike those illustrated in FIG. 49, the photodetector 16I is illustrated that the frontside surface 100a and the backside surface 100b of the substrate 100 may be located at a bottom surface and a top surface, respectively. The photodetection element layer 1 and the connection layer 2 may be substantially the same as the photodetection element layer 1 and the connection layer 2 described with reference to FIG. 49.

The lens layer 3 may be provided on the backside surface 100b of the substrate 100. Light may be incident on the backside surface 100b of the substrate 100. The photodetector 16I may use a backside illumination (BSI) method. The lens layer 3 may be substantially the same as the lens layer 3 described with reference to FIG. 49 except for its location.

The control layer 4 may be provided on the connection layer 2. The control layer 4 may be provided on the frontside surface 100a of the substrate 100. The control layer 4 may include a circuit (hereinafter referred to as a required circuit) required for operation of the photodetection element layer 1. For example, the control layer 4 may be a chip on which the required circuit is formed. The required circuit may be implemented by various electronic devices as needed. In some example embodiments, the required circuit may include a quenching resistor (or a quenching circuit) and a pixel circuit. The pixel circuit may be composed of a reset or recharge circuit, a memory, an amplifier circuit, a counter, a gate circuit, a time-to-digital converter, and the like. The required circuits may include DC-DC converters and other power management integrated circuits. The required circuit may transmit a signal to the photodetection element layer 1 or receive a signal from the photodetection device layer 1.

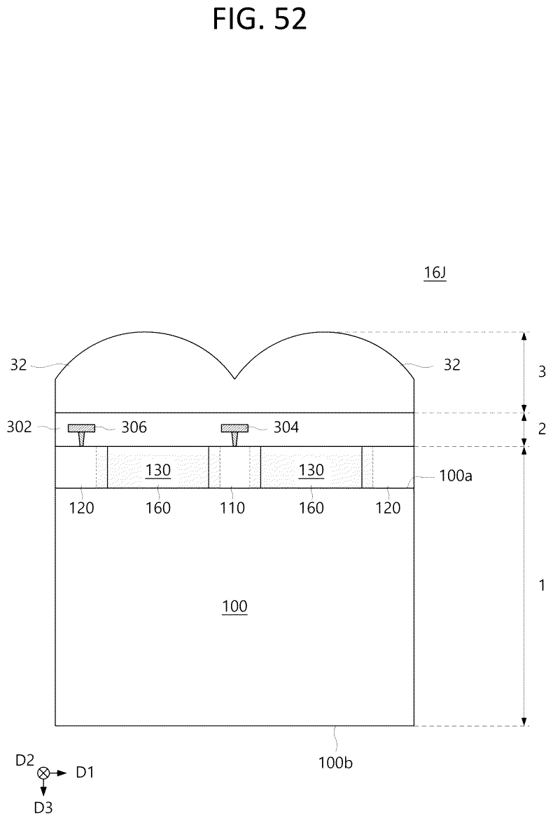

Referring to FIG. 52, a photodetector 16J may be provided. For brevity of explanation, content substantially the same as that described with reference to FIG. 43 may not be described. The photodetector 16J may include a photodetector device layer 1, a connection layer 2, and a lens layer 3. In some example embodiments, the photodetection element layer 1 may be substantially the same as the photodetection element 14B described with reference to FIGS. 40 and 41. In some example embodiments, the photodetection element layer 1 may include the photodetection element 14C described with reference to FIG. 42 instead of the photodetection element 14B described with reference to FIGS. 40 and 41.

The connection layer 2 may include an insulating layer 302, a first conductive line 304, and a second conductive line 306. The insulating layer 302 may be substantially the same as the connection layer 2 described with reference to FIG. 43. The first conductive line 304 may be electrically connected to the first node region 110. For example, the first conductive line 304 may be in contact with a n-type polysilicon region. The second conductive line 306 may be electrically connected to the second node region 120. For example, the second conductive line 306 may be in contact with a p-type polysilicon region.

The lens layer 3 may be substantially the same as the lens layer 3 described with reference to FIG. 43.

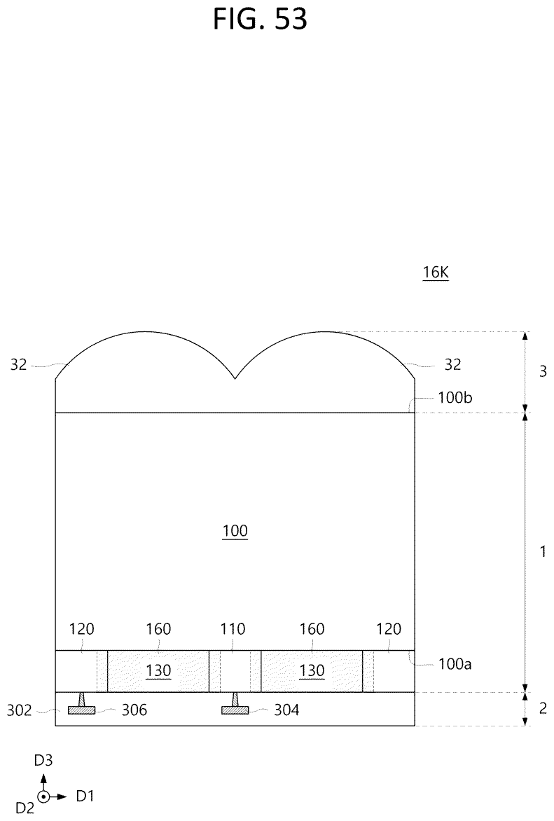

Referring to FIG. 53, a photodetector 16K may be provided. For brevity of explanation, differences from those described with reference to FIG. 52 may be explained. The photodetector 16K may include a photodetector device layer 1, a connection layer 2, and a lens layer 3. Unlike those illustrated in FIG. 52, the photodetector 16K is illustrated that the frontside surface 100a and the backside surface 100b of the substrate 100 may be located at a bottom surface and a top surface, respectively. The photodetection element layer 1 and the connection layer 2 may be substantially the same as the photodetection element layer 1 and the connection layer 2 described with reference to FIG. 52.

The lens layer 3 may be provided on the backside surface 100b of the substrate 100. Light may be incident on the backside surface 100b. The photodetector 16K may use a backside illumination method. The lens layer 3 may be substantially the same as the lens layer 3 described with reference to FIG. 52 except for its location.

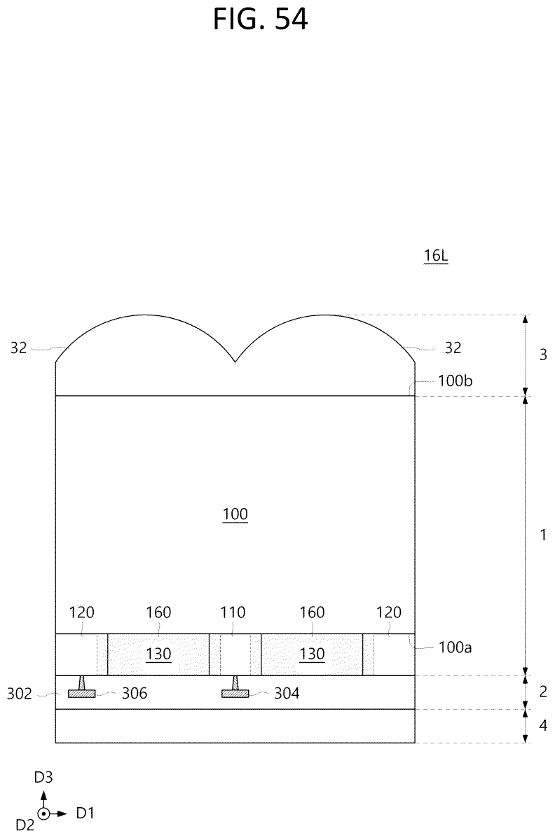

Referring to FIG. 54, a photodetector 16L may be provided. For brevity of explanation, differences from those described with reference to FIG. 52 may be explained. The photodetector 16L may include a photodetector device layer 1, a connection layer 2, a lens layer 3, and a control layer 4. Unlike those illustrated in FIG. 52, the photodetector 16L is illustrated that the frontside surface 100a and the backside surface 100b of the substrate 100 may be located at a bottom surface and a top surface, respectively. The photodetection element layer 1 and the connection layer 2 may be substantially the same as the photodetection element layer 1 and the connection layer 2 described with reference to FIG. 52.

The lens layer 3 may be provided on the backside surface 100b of the substrate 100. Light may be incident on the backside surface 100b. The photodetector 16L may use a back illumination method. The lens layer 3 may be substantially the same as the lens layer 3 described with reference to FIG. 52 except for its location.

The control layer 4 may be provided on the connection layer 2. The control layer 4 may be provided on the frontside surface 100a of the substrate 100. The control layer 4 may include circuit (hereinafter referred to as a required circuit) required for the operation of the photodetection element layer 1. For example, the control layer 4 may be in a form of a stacked structure with a separate semiconductor chip on which the required circuits are formed, and may be electrically connected to the photodetection element layer 1 through a TSV, as described in FIG. 45, and may also be provided on the backside surface 100b of the substrate 100. The required circuit may be implemented by various electronic devices as needed. In some example embodiments, the required circuit may include a quenching resistor (or a quenching circuit) and a pixel circuit. The pixel circuit may be composed of a reset or recharge circuit, a memory, an amplifier circuit, a counter, a gate circuit, a time-to-digital converter, and the like. The required circuits may include DC-DC converters and other power management integrated circuits. The circuit required for the operation of the photodetection element layer 1 may transmit a signal to the photodetection element layer 1 or may receive a signal from the photodetection element layer 1.

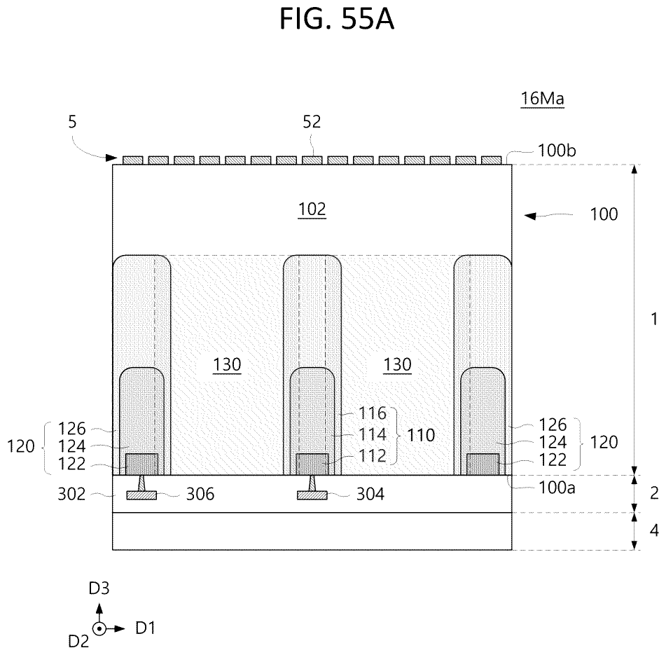

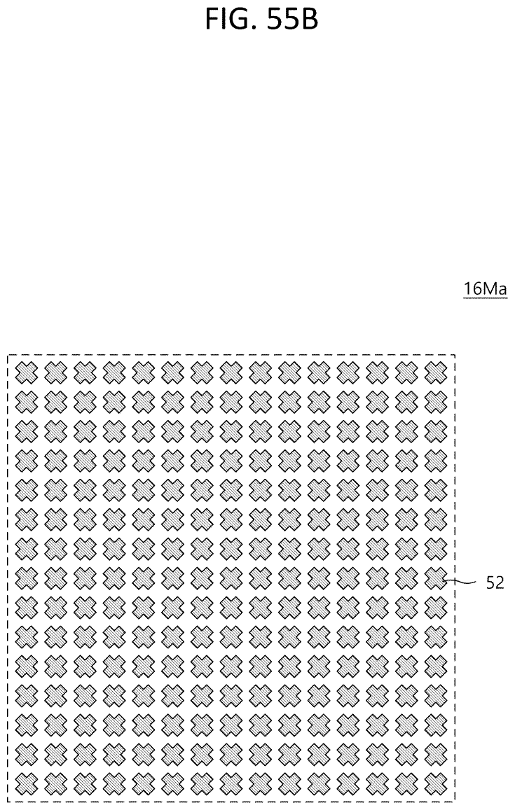

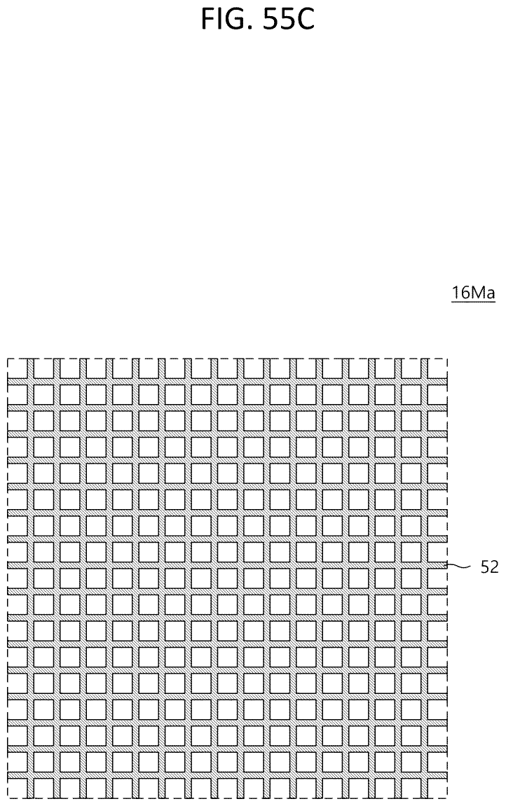

FIG. 55 is a cross-sectional view of a photodetector according to some example embodiments. FIGS. 55B and 55C are plan views of optical pattern layer according to some example embodiments of FIG. 55A. For brevity of explanation, content that is substantially the same as that described with reference to FIGS. 1 and 2 and that described with reference to FIG. 45 may not be described.

Referring to FIGS. 55A to 55C, a photodetector 16M may be provided. The photodetector 16M may include a photodetection element layer 1, a connection layer 2, an optical pattern layer 5, and a control layer 4. Unlike those described with reference to FIG. 45, the photodetector 16M may include the optical pattern layer 5 instead of the lens layer 3. In some example embodiments, the photodetection element layer 1 may be substantially the same as the photodetection element 10A described with reference to FIGS. 1 and 2. In some example embodiments, the photodetection element layer 1 may include any one of the photodetection devices 10A to 10Q described with reference to FIGS. 3 to 22C, the photodetection elements 12A to 12L described with reference to FIGS. 23 to 37, and the photodetection elements 14A to 14E described with reference to FIGS. 38 to 42B instead of the photodetection element 10A described with reference to FIGS. 1 and 2.

The optical pattern layer 5 may be provided on the backside surface 100b of the substrate 100. The optical pattern layer 5 may include optical patterns 52. In some example embodiments, the optical patterns 52 may be diffraction patterns. The diffraction patterns may be configured to diffract incident light. Light diffracted by the diffraction patterns may have a longer absorption length within the photodetection element layer 1 than light that is not diffracted. In some example embodiments, the optical patterns 52 may be scattering patterns. The scattering patterns may be configured to scatter incident light. Light scattered by the scattering patterns may have a longer absorption length within the photodetection element layer 1 than light that is not scattered. The optical pattern layer 5 may improve the light absorption efficiency of the photodetector 16M. The optical patterns 52 may be, for example, cross-shaped or X-shaped patterns. In some other example embodiments, the optical patterns 52 may be patterns that combine a cross shape and an X-shape, or patterns in which each shape is connected. In some example embodiments, as illustrated in FIG. 55C, the optical pattern layer 5 may have a grid shape. In some example embodiments, at least one optical element may be inserted between the optical patterns 52 and the photodetection element layer 1. For example, the optical elements may be a color filter, a bandpass filter, a metal grid, an air grid, a grid based on low refractive index materials, and an anti-reflective coating, a 2D nanomaterial layer, or an organic material layer. In some example embodiments, a lens layer (not illustrated) may be formed on the optical patterns 52 along the third direction D3. The optical pattern layer 5 may be referred to as an optical element layer.

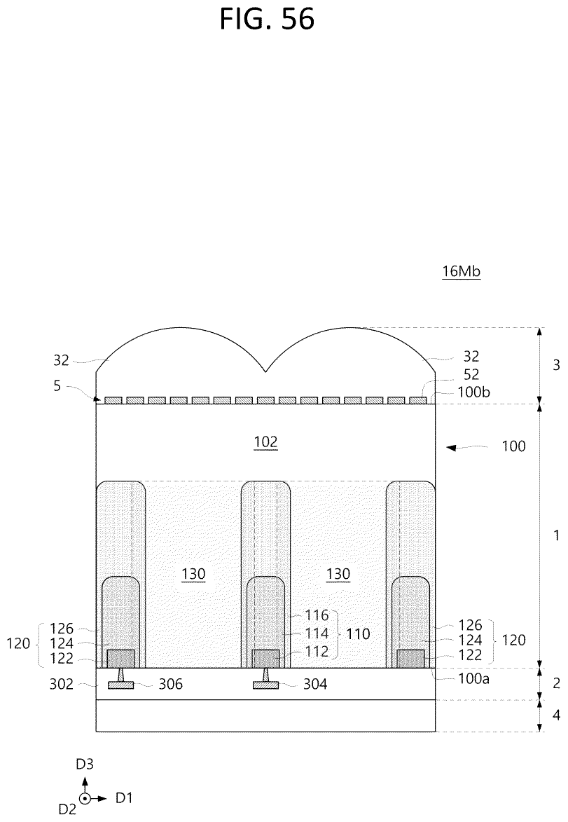

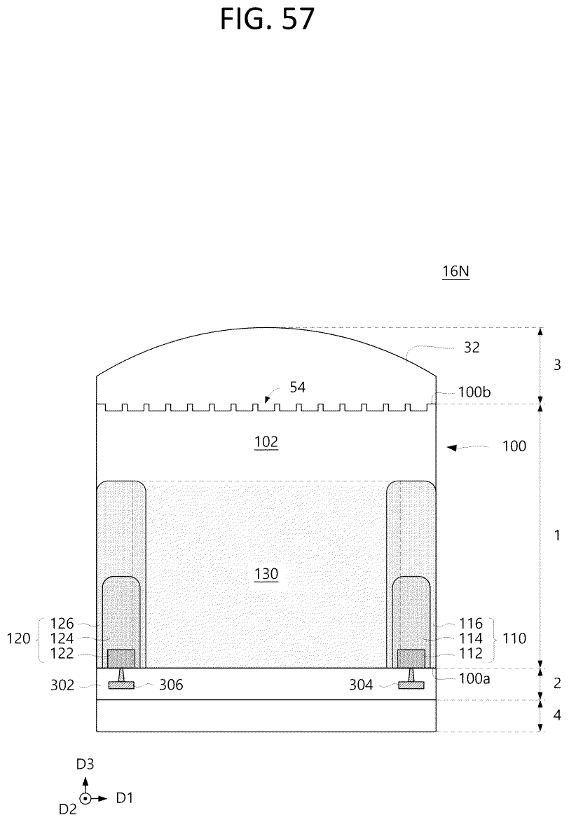

FIGS. 56 and 57 are cross-sectional views of a photodetector according to some example embodiments. For brevity of explanation, content that is substantially the same as that described with reference to FIGS. 1 and 2, that described with reference to FIG. 55A, and that described with reference to FIG. 43 may not be described.

Referring to FIG. 56, a photodetector 16N may be provided. Unlike those described with reference to FIG. 55A, a lens layer 3 may be provided on the backside surface 100b. The lens layer 3 may be substantially the same as the lens layer 3 described with reference to FIG. 43. The lens layer 3 may cover the optical pattern layer 5.

Referring to FIG. 57, a photodetector 160 may be provided. The photodetector 160 may include a photodetector device layer 1, a connection layer 2, a lens layer 3, and a control layer 4. For brevity of explanation, content that is substantially the same as that described with reference to FIGS. 1 and 2 and that described with reference to FIG. 45 may not be described. In some example embodiments, the photodetection element layer 1 may be substantially the same as the photodetection device 10A described with reference to FIGS. 1 and 2. In some example embodiments, the photodetection element layer 1 may include any one of the photodetection elements 10A to 10Q described with reference to FIGS. 3 to 22C, the photodetection elements 12A to 12L described with reference to FIGS. 23 to 37, and the photodetection elements 14A to 14E described with reference to FIGS. 38 to 42B instead of the photodetection element 10A described with reference to FIGS. 1 and 2. The photodetector 160 is illustrated that the frontside surface 100a and the backside surface 100b of the substrate 100 may be located at a bottom surface and a top surface, respectively. Light may be incident on the backside surface 100b of the substrate 100. The photodetector 160 may use a backside illumination (BSI) method.

Optical grooves 54 may be provided on the backside surface 100b of the substrate 100. In some example embodiments, the optical grooves 54 may have a grid shape. For example, the optical grooves 54 may be formed by etching the backside surface 100b of the substrate 100. In some example embodiments, the optical grooves 54 may be filled with the lens layer 3. In some example embodiments, a space between the optical grooves 54 and the lens layer 3 may be filled with passivation (aluminum oxide (e.g., Al₂O₃), hafnium oxide (e.g., HfO₂), etc.). In some example embodiments, the optical grooves 54 may be diffractive grooves. The diffraction grooves may be configured to diffract incident light. Light diffracted by the diffraction grooves may have a longer absorption length within the photodetection element layer 1 than light that is not diffracted. In some example embodiments, the optical grooves 54 may be scattering grooves. The scattering grooves may be configured to scatter incident light. Light scattered by the scattering grooves may have a longer absorption length within the photodetection element layer 1 than unscattered light. The optical grooves 54 may improve the light absorption efficiency of the photodetector 160.

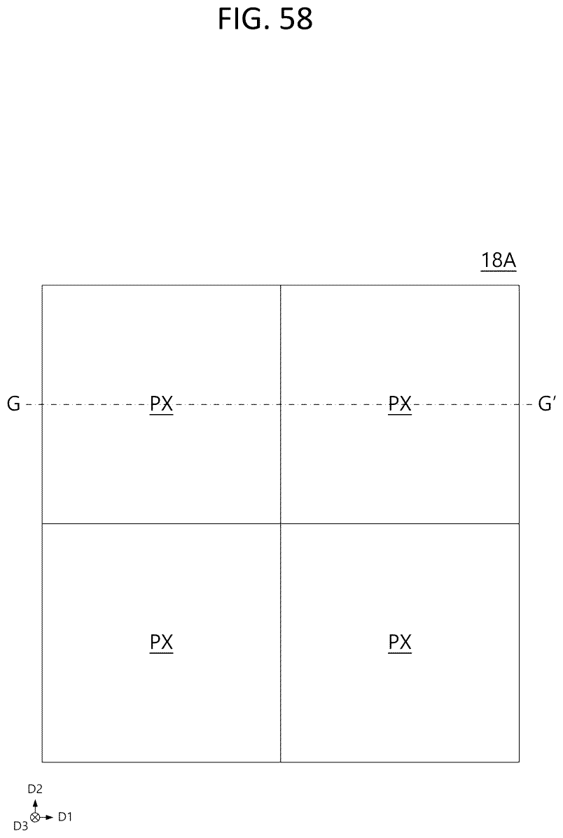

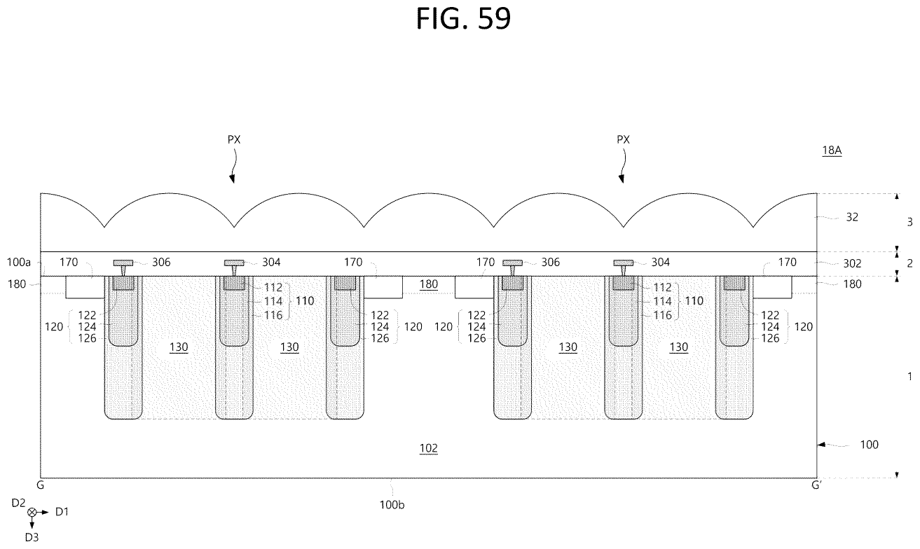

FIG. 58 is a plan view illustrating a pixel array of a photodetector according to some example embodiments. FIGS. 59 to 62A are cross-sectional views illustrating pixel arrays according to some example embodiments corresponding to line G-G′ in FIG. 58. For brevity of explanation, content substantially the same as that described with reference to FIG. 43 may not be described.

Referring to FIGS. 58 and 59, a photodetection array 18A may be provided. The photodetection array 18A may include a photodetection element layer 1, a connection layer 2, and a lens layer 3. The photodetection array 18A may include pixels PX arranged in two dimensions. Each of the pixels PX may include the photodetector 16A described with reference to FIG. 43. Each of the pixels PX may include the photodetection element layer 1, the connection layer 2, and the lens layer 3 described with reference to FIG. 43. The photodetection element layers 1, the connection layers 2, and lens layers 3 of the pixels PX that are immediately adjacent to each other may be connected to each other. The photodetection element layers 1 of the pixels PX may be connected to each other to form the photodetection element layer 1 of the photodetection array 18A. The connection layers 2 of the pixels PX may be connected to each other to form the connection layer 2 of the photodetection array 18A. The lens layers 3 of the pixels PX may be connected to each other to form the lens layer 3 of the photodetection array 18A.

Separation insulating layers 170 may be provided between the pixels PX that are immediately adjacent to each other. The isolation insulating layers 170 may include an electrically insulating material. For example, the isolation insulating layers 170 may include silicon oxide (e.g., SiO₂), silicon nitride (e.g., SiN), silicon oxynitride (e.g., SiON), or a combination thereof. The isolation insulating layers 170 may be formed, for example, by filling a recessed region formed by etching the semiconductor substrate 100 with an electrically insulating material (e.g., silicon oxide). For example, the isolation insulating layers 170 may be shallow trench isolation (STI). For example, the isolation insulating layers 170 may be deep trench isolation (DTI). For example, a bottom surface of the isolation insulating layers 170 may be located at a level adjacent to the level of a bottom surface of the second deep well 126. For example, the bottom surface of the isolation insulating layers 170 may be formed closer to the backside surface 100b than the bottom surface of the second deep well 126. The isolation insulating layers 170 may electrically separate pixels PX that are immediately adjacent to each other. The isolation insulating layers 170 may electrically separate the pixels PX from other semiconductor devices or electronic devices constituting other circuits.

A peripheral region 180 may be exposed between the isolation insulating layers 170. The peripheral region 180 may be one region of the substrate 100. In some example embodiments, at least a portion of a circuit (hereinafter referred to as a required circuit) required for operation of the photodetection element layer 1 may be formed in the peripheral region 180. In some example embodiments, the first conductive lines 304 and second conductive lines 306 may be configured to be electrically connected the first node regions 110 and the second node regions 120 to the required circuit formed into the peripheral region 180.

For example, the photodetection element layer 1 may include a plurality of the photodetection elements 10A described with reference to FIGS. 1 and 2. In some example embodiments, the photodetection element layer 1 may include a plurality of any one of the photodetection elements 10A to 10Q described with reference to FIGS. 3 to 22C, the photodetection elements 12A to 12L described with reference to FIGS. 23 to 37, and the photodetection elements 14A to 14E described with reference to FIGS. 38A to 42B instead of the photodetection element 10A described with reference to FIGS. 1 and 2.

In some other example embodiments, each of the pixels PX may include a plurality of any one of the photodetector 16D described with reference to FIG. 46, the photodetector 16G described with reference to FIG. 49, the photodetector 16J described with reference to FIG. 52 instead of the photodetector 16A.

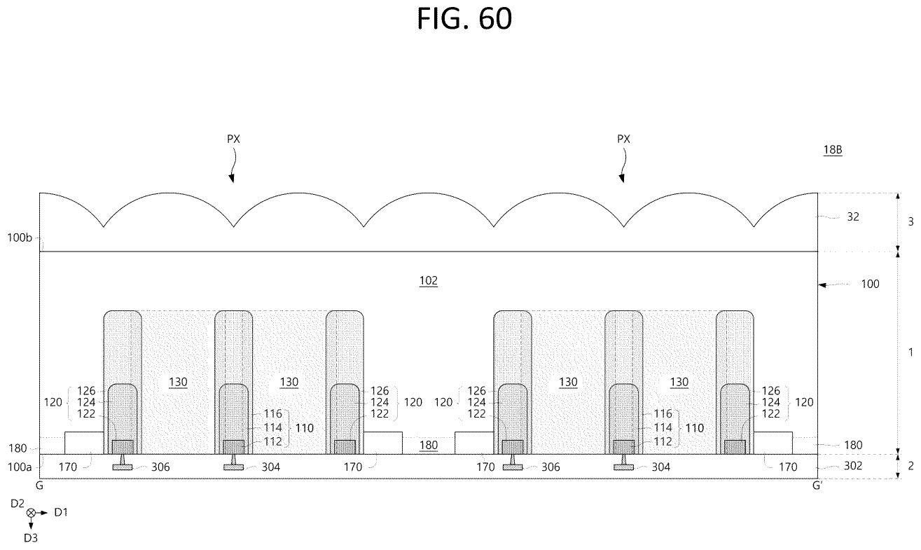

Referring to FIGS. 58 and 60, a photodetection array 18B may be provided. For brevity of explanation, differences from those described with reference to FIGS. 58 and 59 are explained. The photodetection array 18B may include a photodetection element layer 1, a connection layer 2, and a lens layer 3. The photodetection array 18B may include pixels PX arranged in two dimensions. Each of the pixels PX may include the photodetector 16B described with reference to FIG. 44. Each of the pixels PX may include the photodetection element layer 1, the connection layer 2, and the lens layer 3 described with reference to FIG. 44. The photodetection element layers 1, connection layers 2, and lens layers 3 of the pixels PX that are immediately adjacent to each other may be connected to each other. The photodetection element layers 1 of the pixels PX may be connected to each other to form the photodetection element layer 1 of the photodetection array 18B. The connection layers 2 of the pixels PX may be connected to each other to form the connection layer 2 of the photodetection array 18B. The lens layers 3 of the pixels PX may be connected to each other to form the lens layer 3 of the photodetection array 18B.

For example, the photodetection element layer 1 may include a plurality of the photodetection elements 10A described with reference to FIGS. 1 and 2. In some example embodiments, the photodetection element layer 1 may include a plurality of any one of the photodetection elements 10A to 10Q described with reference to FIGS. 3 to 22C, the photodetection elements 12A to 12L described with reference to FIGS. 23 to 37, and the photodetection elements 14A to 14E described with reference to FIGS. 38A to 42B instead of the photodetection element 10A described with reference to FIGS. 1 and 2.

In some example embodiments, each of the pixels PX may include a plurality of any one of the photodetector 16E described with reference to FIG. 47, the photodetector 16H described with reference to FIG. 50, and the photodetector 16K described with reference to FIG. 53 instead of the photodetector 16B described with reference to FIG. 44.

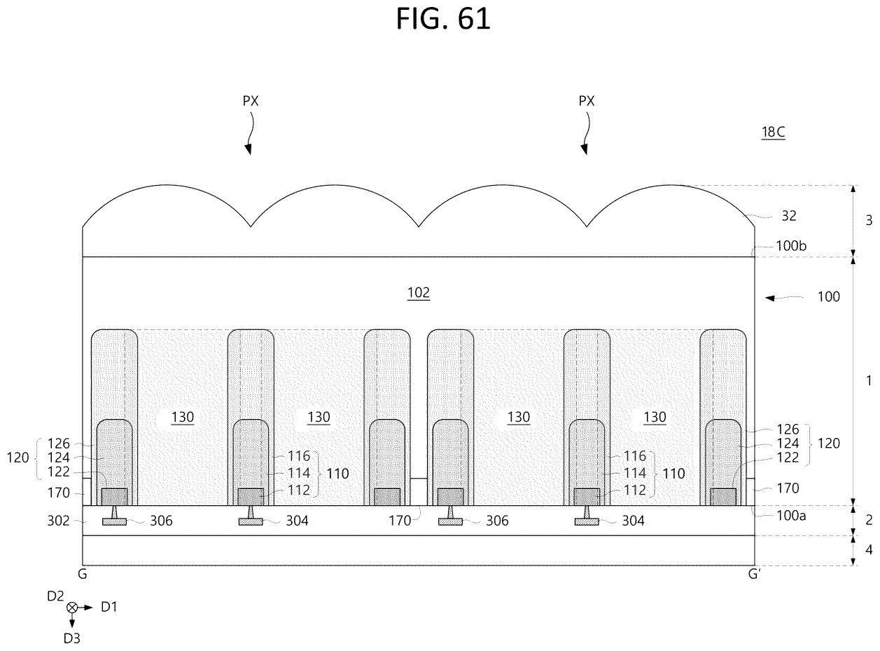

Referring to FIGS. 58 and 61, a photodetection array 18C may be provided. For brevity of explanation, differences from those described with reference to FIGS. 58 and 59 are explained. The photodetection array 18C may include a photodetection element layer 1, a connection layer 2, a lens layer 3, and a control layer 4. The photodetection array 18C may include pixels PX arranged in two dimensions. Each of the pixels PX may include the photodetector 16C described with reference to FIG. 45. Each of the pixels PX may include a photodetection element layer 1, a connection layer 2, a lens layer 3, and a control layer 4 described with reference to FIG. 45. The photodetection element layer 1, the connection layer 2, the lens layer 3, and the control layer 4 of the pixels PX that are immediately adjacent to each other may be connected to each other. The photodetection element layers 1 of the pixels PX may be connected to each other to form the photodetection element layer 1 of the photodetection array 18C. The connection layers 2 of the pixels PX may be connected to each other to form the connection layer 2 of the photodetection array 18C. The lens layers 3 of the pixels PX may be connected to each other to form the lens layer 3 of the photodetection array 18C. The control layer 4 of the pixels PX may be connected to each other to form the control layer 4 of the photodetection array 18C.

For example, the photodetection element layer 1 may include a plurality of the photodetection elements 10A described with reference to FIGS. 1 and 2. In some example embodiments, the photodetection element layer 1 may include a plurality of any one of the photodetection elements 10A to 10Q described with reference to FIGS. 3 to 22C, the photodetection elements 12A to 12L described with reference to FIGS. 23 to 37, and the photodetection elements 14A to 14E described with reference to FIGS. 38A to 42B instead of the photodetection element 10A described with reference to FIGS. 1 and 2.

In some other example embodiments, each of the pixels PX may include a plurality of any one of the photodetector 16F described with reference to FIG. 48, the photodetector 16I described with reference to FIG. 51, the photodetector 16L described with reference to FIG. 54, the photodetector 16M described with reference to FIGS. 55A to 55C, the photodetector 16N described with reference to FIG. 56, and the photodetectors 160 described with reference to FIG. 57 instead of the photodetector 16C described with reference to FIG. 45.

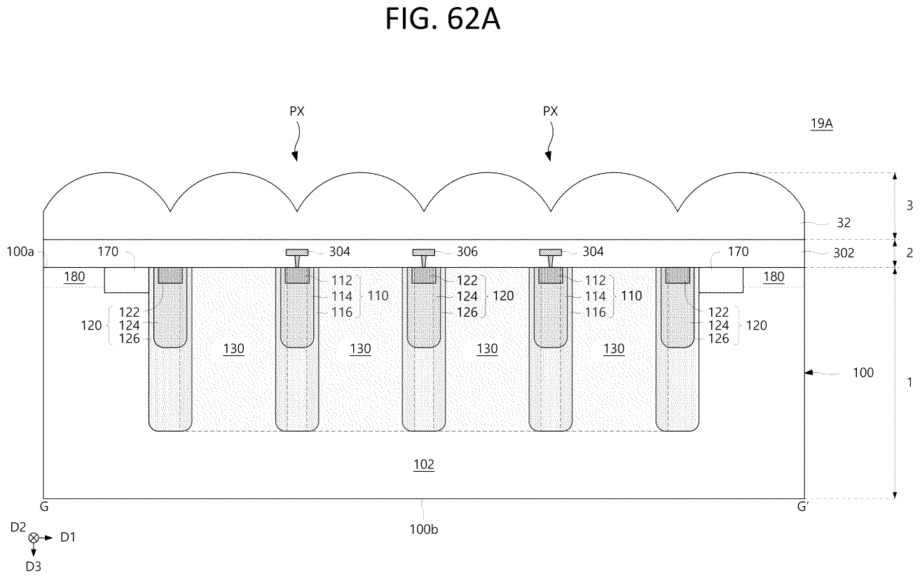

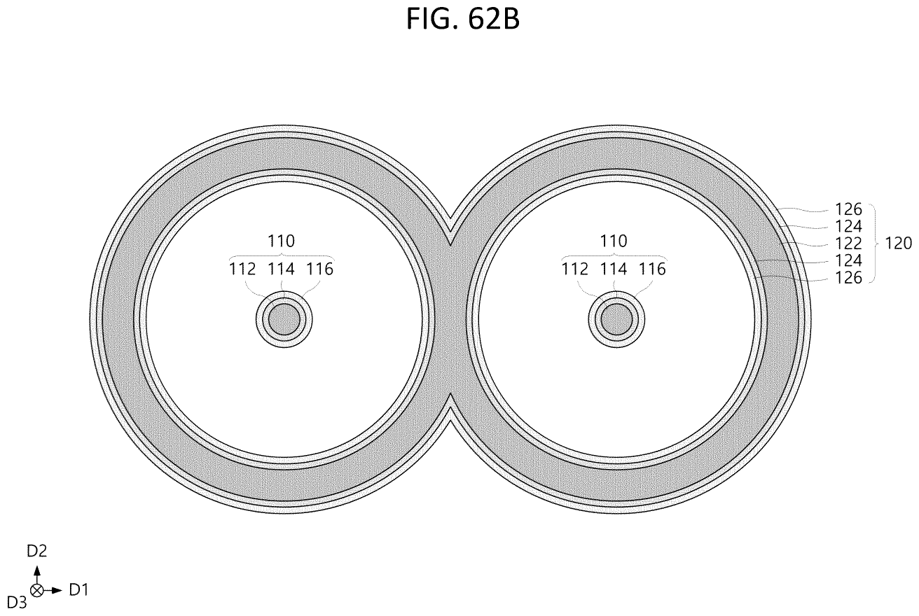

Referring to FIGS. 58 and 62A, a photodetection array 19A may be provided. The photodetection array 19A may include a photodetection element layer 1, a connection layer 2, and a lens layer 3. The photodetection array 19A may include pixels PX arranged in two dimensions. Each of the pixels PX may include the photodetector 16A described with reference to FIG. 43. Each of the pixels PX may include the photodetection element layer 1, the connection layer 2, and the lens layer 3 described with reference to FIG. 43.

FIG. 62B is a plan view illustrating the first node region and the second node region of FIG. 62A. For brevity of explanation, content that is substantially the same as that described with reference to FIG. 59 may not be described.

Referring to FIG. 62B, unlike those illustrated in FIG. 59, the second node regions 120 may be connected to each other. Pixels PX that are immediately adjacent to each other may share the second node regions 120.

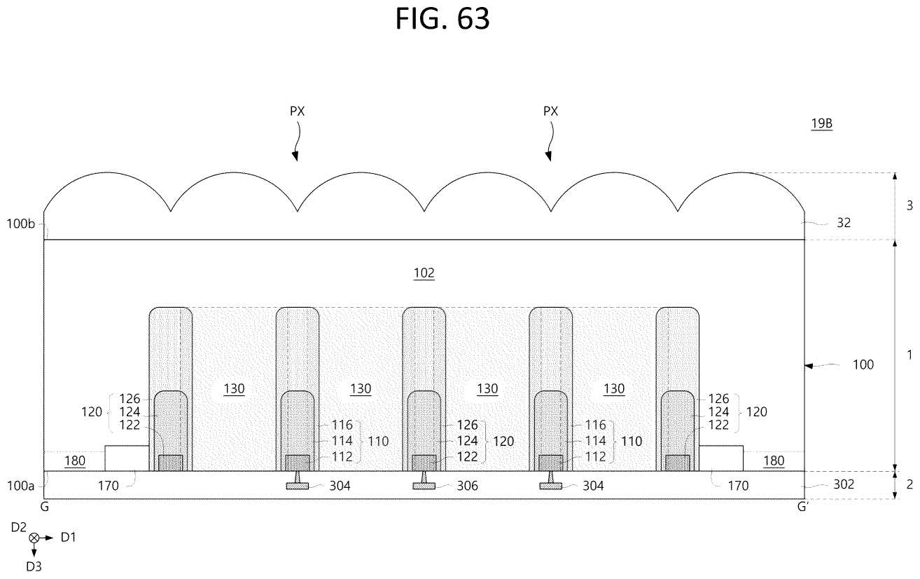

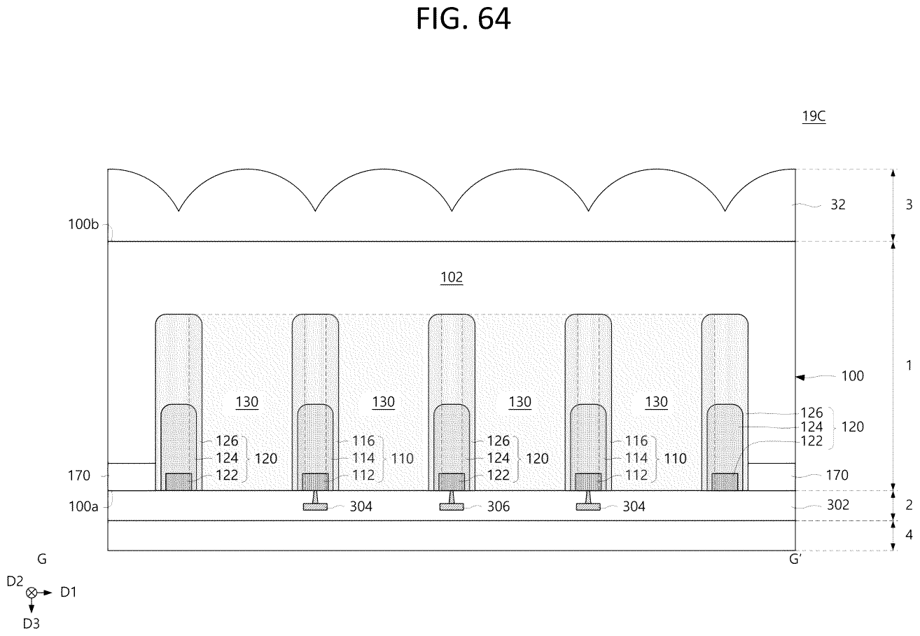

FIGS. 63 and 64 are cross-sectional views according to some example embodiments corresponding to line G-G′ in FIG. 58. For brevity of explanation, content that is substantially the same as that described with reference to FIG. 60 and that described with reference to FIG. 62B may not be described.

Referring to FIGS. 58 and 63, a photodetection array 19B may be provided. The photodetection array 19B may include a photodetection element layer 1, a connection layer 2, and a lens layer 3. The photodetection array 19B may include pixels PX arranged in two dimensions. Each of the pixels PX may include the photodetector 16B described with reference to FIG. 44. Each of the pixels PX may include the photodetection element layer 1, the connection layer 2, and the lens layer 3 described with reference to FIG. 44.

As illustrated in FIG. 62B, the second node regions 120 may be connected to each other. The pixels PX that are immediately adjacent to each other may share the second node regions 120.

Referring to FIGS. 58 and 64, a photodetection array 19C may be provided. For brevity of explanation, content that is substantially the same as that described with reference to FIG. 61 and that described with reference to FIG. 62B may not be described. The photodetection array 19C may include a photodetection element layer 1, a connection layer 2, a lens layer 3, and a control layer 4. The photodetection array 19C may include pixels PX arranged in two dimensions. Each of the pixels PX may include the photodetector 16C described with reference to FIG. 45. Each of the pixels PX may include the photodetection element layer 1, the connection layer 2, the lens layer 3, and the control layer 4 described with reference to FIG. 45.

As illustrated in FIG. 62B, the second node regions 120 may be connected to each other. Pixels PX that are immediately adjacent to each other may share the second node regions 120.

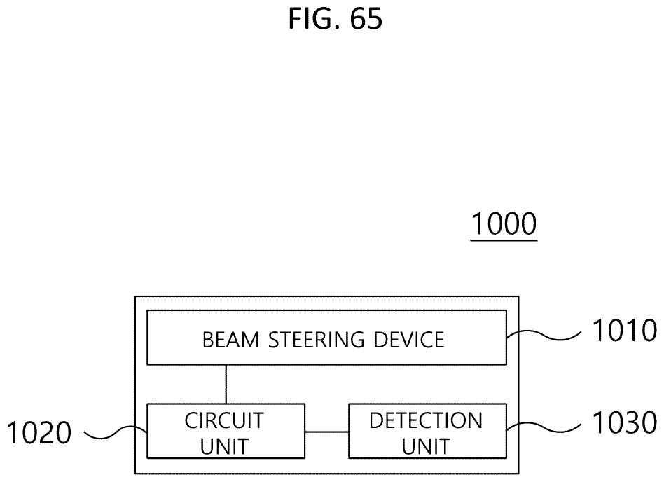

FIG. 65 is a block diagram for explaining an electronic device according to some example embodiments.

Referring to FIG. 65, an electronic device 1000 may be provided. The electronic device 1000 may radiate light toward a subject (not illustrated) and detect light reflected by the subject and returned to the electronic device 1000. The electronic device 1000 may include a beam steering device 1010. The beam steering device 1010 may adjust a direction of irradiation of light emitted to the outside of the electronic device 1000. The beam steering device 1010 may be a mechanical or a non-mechanical (semiconductor) beam steering device. The electronic device 1000 may include a light source unit within the beam steering device 1010 or may include the light source unit provided separately from the beam steering device 1010. The beam steering device 1010 may be a scanning type light emitting device. However, the light emitting device of the electronic device 1000 is not limited to the beam steering device 1010. In some other example embodiments, the electronic device 1000 may include a flash-type light emitting device instead of the beam steering device 1010 or together with the beam steering device 1010. The flash-type light-emitting device may radiate light to a region including an entire field of view at once without a scanning process.

The light steered by the beam steering device 1010 may be reflected by the subject and returned to the electronic device 1000. The electronic device 1000 may include a detection unit 1030 for detecting light reflected by the subject. The detection unit 1030 may include a plurality of photodetection elements and may further include other optical elements. A plurality of the photodetection elements may include any one of the photodetection elements 10A to 160 described above. In some example embodiments, the electronic device 1000 may further include a circuit unit 1020 connected to at least one of the beam steering device 1010 and the detection unit 1030. The circuit unit 1020 may include a calculation unit that acquires and calculates data, and may further include a driving unit and a control unit. In some example embodiments, the circuit unit 1020 may further include a power supply unit and a memory.

Although the case where the electronic device 1000 includes the beam steering device 1010 and the detection unit 1030 in one device is illustrated, the beam steering device 1010 and the detection unit 1030 are not provided as a single device. The beam steering device 1010 and the detection unit 1030 may be provided separately in a separate device. In some example embodiments, the circuit unit 1020 may not be connected to the beam steering device 1010 or the detection unit 1030 through wireless communication without being wired.

The electronic device 1000 according to some example embodiments described above may be applied to various electronic devices. In some example embodiments, the electronic device 1000 may be applied to a light detection and ranging (LiDAR) device. The LiDAR device may be a phase-shift or time-of-flight (TOF) type device. In addition, the photodetection elements 10A to 160 according to some example embodiments or the electronic device 1000 including the same may be installed in high-tech electronic devices such as smartphones, wearable devices (glasses-type devices implementing augmented reality and virtual reality, etc.), the internet of things (IoTs) devices, home appliances, tablet personal computers (PCs), personal digital assistants (PDAs), portable multimedia players (PMPs), navigation, drones, robots, unmanned vehicles, self-driving cars, and advanced driver assistance system (ADAS).

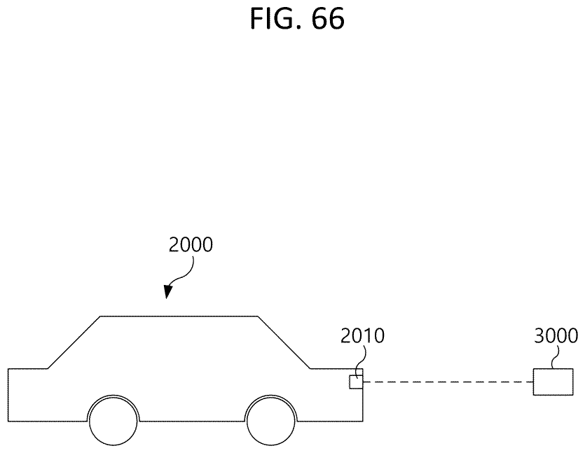

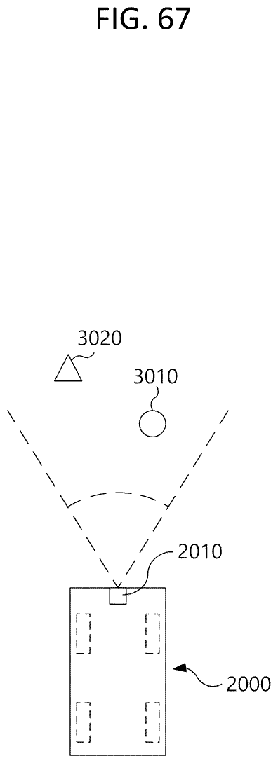

FIGS. 66 and 67 are conceptual diagrams illustrating cases in which a LiDAR device is applied to a vehicle according to some example embodiments.

Referring to FIGS. 66 and 67, a LiDAR device 2010 may be applied to a vehicle 2000. Information on a subject 3000 may be obtained using the LiDAR device 2010 applied to the vehicle 2000. The vehicle 2000 may be an automobile car with an autonomous driving function. The LiDAR device 2010 may detect an object or a person, that is, the subject 3000, in a direction in which the vehicle 2000 travels. The LiDAR device 2010 may measure a distance to the subject 3000 using information such as a time difference between a transmission signal and a detection signal. The LiDAR device 2010 may acquire information about a near subject 3010 and a distant subject 3020 within a scanning range. The LiDAR device 2010 may include the electronic device 1000 described with reference to FIG. 65. Although the LiDAR device 2010 is disposed in front of the vehicle 2000 and detects the subject 3000 in the direction in which the vehicle 2000 travels, this is not limited. In some other example embodiments, the LiDAR device 2010 may be disposed at a plurality of locations on the vehicle 2000 so as to detect all subjects 3000 around the vehicle 2000. For example, four LiDAR devices 2010 may be disposed at the frontside surface, backside surface, and both side surfaces of the vehicle 2000, respectively. In some other example embodiments, the LiDAR device 2010 may be disposed on the roof of the vehicle 2000, rotate, and detect all subjects 3000 around the vehicle 2000.

The above description of some example embodiments of the inventive concepts provides examples for explanation of the technical idea of the present disclosure. Therefore, the inventive concepts are not limited to the above embodiments. Within the technical idea of the present disclosure, various modifications and changes are possible, such as combining and implementing the above some embodiments by those skilled in the art.

What is claimed is:

1. A photodetection element comprising:
a substrate having a first surface and a second surface opposite to each other;
a first node region within the substrate and having a first conductivity type;
a second node region within the substrate spaced apart from the first node region and having a second conductivity type different from the first conductivity type; and
an avalanche multiplication region formed between the first node region and the second node region,
wherein the first node region, the avalanche multiplication region, and the second node region are arranged along a first direction parallel to the first surface.

2. The photodetection element of claim 1, wherein the second node region is configured to surround the first node region.

3. The photodetection element of claim 1, the first node region and the second node region extend along a second direction intersecting the first direction.

4. The photodetection element of claim 1,
wherein the first node region includes:
a first contact region; and
a first well provided between the first contact region and the second surface and having a doping concentration lower than that of the first contact region.

5. The photodetection element of claim 4, wherein, in the first node region extending along a second direction intersecting the first direction, a central portion of the first contact region and a central portion of the first well are arranged to overlap.

6. The photodetection element of claim 4, wherein, in the first node region extending along a second direction intersecting the first direction, the first well surrounds the first contact region and extends along the second direction.

7. The photodetection element of claim 4, wherein the first node region further includes a first deep well provided between the first well and the second surface and having a doping concentration lower than that of the first contact region.

8. The photodetection element of claim 7, wherein, in the first node region extending along a second direction intersecting the first direction, a central portion of the first contact region and a central portion of the first deep well are arranged to overlap.

9. The photodetection element of claim 7, wherein, in the first node region extending along a second direction intersecting the first direction, the first deep well surrounds the first contact region and extends along the second direction.

10. The photodetection element of claim 4,
wherein the second node region includes:
a second contact region; and
a second well provided between the second contact region and the second surface and having a doping concentration lower than that of the second contact region.

11. The photodetection element of claim 10, wherein the second node region further includes a second deep well provided between the second well and the second surface and having a doping concentration lower than that of the second contact region.

12. The photodetection element of claim 1, further comprising:
a buried well provided between the first node region and the second surface and between the second node region and the second surface, extending along the first direction, and having the second conductivity type; and
an additional avalanche multiplication region formed between the first node region and the buried well.

13. The photodetection element of claim 12, wherein the second node region and the buried well are in contact with each other.

14. The photodetection element of claim 1, further comprising:
a buried insulating layer provided between the first node region and the second surface and between the second node region and the second surface, extending along the first direction, and including an electrical insulating material.

15. A photodetector comprising a photodetection element, a connection layer and an optical element layer that transmits incident light to the photodetection element,
wherein the photodetection element includes, a substrate having a first surface and a second surface on opposite sides of each other, a first node region provided in the substrate and having a first conductivity type, a second node region spaced apart from the first node region in the substrate and having a second conductivity type different from the first conductivity type, and an avalanche multiplication region formed between the first node region and the second node region,
wherein the first node region, the avalanche multiplication region, and the second node region are arranged along a first direction parallel to the first surface,
wherein the connection layer includes conductive lines electrically connected to at least one of the first node region and the second node region.

16. The photodetection element of claim 15, wherein the optical element layer includes a plurality of lenses,
optical axes of the plurality of lenses are located within the avalanche multiplication region.

17. The photodetection element of claim 15, wherein the optical element layer includes a plurality of optical patterns,
wherein the plurality of the optical patterns diffract or scatter incident light and transmit the incident light to the avalanche multiplication region.

18. The photodetection element of claim 15, wherein the connection layer and the optical element layer are sequentially disposed on the first surface.

19. The photodetection element of claim 15, wherein the connection layer is provided on the first surface,
wherein the optical element layer is provided on the second surface.

20. An electronic device comprising a light emitting device and a photodetection element that detects incident light reflected from a subject and returned after being emitted from the light emitting device, and configured to measure a distance to the subject using time difference information between a transmission signal of the light emitting device and a detection signal of the photodetection element,
wherein the photodetection element includes:
a substrate having a first surface and a second surface provided on opposite sides of each other, a first node region provided within the substrate and having a first conductivity type, a second node region spaced apart from the first node region within the substrate and having a second conductivity type different from the first conductivity type, and an avalanche multiplication region formed between the first node region and the second node region,
wherein the first node region, the avalanche multiplication region, and the second node region are arranged along a first direction parallel to the first surface.
